(19) United States
(12) Patent Application Publication
(10) Pub. No.: US 2024/0260452 A1
(43) Pub. Date: Aug. 1, 2024

(54) LIGHT-EMITTING DOWN CONVERSION ORGANIC NANO-DOT, COMPOSITION FOR COLOR CONVERSION FILM COMPRISING THEREOF, AND CONVERSION FILM, DISPLAY DEVICE AND LIGHT EMITTING DIODE DEVICE PREPARED THEREFROM

(71) Applicant: ND-MATERIALS CORP., Seoul (KR)

(72) Inventors: Jang Hyuk KWON, Seongnam-si (KR); Mi Young Chae, Yongin-si (KR); Young Hun Jung, Seoul (KR); Bright James Walker, Seoul (KR); Ansari Rasheeda Bano Maqbool Hasan, Seoul (KR); Gawale Yogesh Kisan, Seoul (KR)

(73) Assignee: ND-MATERIALS CORP., Seoul (KR)

(21) Appl. No.: 18/461,187

(22) Filed: Sep. 5, 2023

(30) Foreign Application Priority Data
Dec. 30, 2022 (KR) 10-2022-0190645
Apr. 11, 2023 (KR) 10-2023-0047372

(51) Int. Cl. H10K 85/60; G02F 1/1335; H10K 85/20

(52) U.S. Cl. CPC H10K 85/633; G02F 1/133514; H10K 85/20; H10K 85/615; H10K 85/622; H10K 85/623; H10K 85/654; H10K 85/6572; H10K 85/6574; H10K 85/6576; H10K 85/658

(57) ABSTRACT

Provided are light-emitting down conversion organic nano-dots containing a first organic phosphor and a second organic phosphor, wherein the first organic phosphor has a molar extinction coefficient (F) of 10,000 L/mol·cm or more at a wavelength of 450 nm, and an emission spectrum of the first organic phosphor overlaps an absorption spectrum of the second organic phosphor, a composition for a color conversion film including the same, and a color conversion film, a display device, and a light-emitting diode device manufactured using the same.

### CROSS-REFERENCE TO RELATED APPLICATION

This application claims priority to and the benefit of Korean Patent Application No. 10-2022-0190645, filed on Dec. 30, 2022, and Korean Patent Application No. 10-2023-0047372, filed on Apr. 11, 2023, the disclosures of which are incorporated herein by reference in its entirety.

### BACKGROUND

### 1. Field of the Invention

The present invention relates to light-emitting down conversion (DC) organic nano-dots, a composition for a color conversion film including the same, and a color conversion film, a display device, and a light-emitting diode device manufactured using the same.

### 2. Discussion of Related Art

In order to make white light using a light-emitting diode (LED) as a light source, a method in which a blue LED is used as a light source and light emitted from the blue LED is converted into white light using a color conversion film formed of phosphors, organic dyes, quantum dots (QDs), and the like is mainly used. In this case, a material of the color conversion film should have a wide full width at half maximum (FWHM) to have a high color rendering index and should have high heat resistance to withstand heat of the LED. In comparison, since a material of a color conversion film used in a display should have high color purity unlike the LED for a light source, fluorescence, phosphorescence, QDs, and the like showing light emission properties with a small FWHM are mainly used.

A method in which a blue LED and a yellow phosphor, which are most widely used in LEDs, are used has a disadvantage in that it has a high correlated color temperature because a color rendering index is low and the yellow phosphor emits a small amount of red light. When organic dyes are used in a color conversion layer, there is a problem in that quenching occurs and photochemical stability is lowered due to the properties of aggregation during light emission.

QDs using inorganic materials have advantages of high photoluminescence quantum yield (PLQY), fast response time, and high reliability, whereas the QDs have disadvantages of being very vulnerable to moisture, having poor heat resistance lower than 100° C. so that they are difficult to use as a color conversion film for a LED, and using heavy metals such as cadmium, arsenic, and lead. Specifically, heavy metals such as lead, cadmium, mercury, chromium, arsenic, and the like have high accumulation in the body and are emerging as a major public health problem. Heavy metals absorbed into the body are accumulated in the hair and organs of the body through the blood, and the residence time of heavy metals in the body is relatively short in blood or urine, but the residence time of heavy metals in the body is relatively long in hair. Generally, the accumulation of heavy metals in vivo is achieved through a serial food chain, and the concentration in the body of the predator is higher than that of the prey. In particular, cadmium, which is used as a fluorescent substance, can cause serious damage to the stomach, lungs, and bones.

In order to apply organic materials or organic nanoparticles to display devices and the like, the organic materials or organic nanoparticles cannot be used alone and should be prepared and used in the form of a film. Films manufactured using organic materials directly have lower light stability than films manufactured using organic nanoparticles. In order to manufacture a film using organic nanoparticles, it is necessary to satisfy conditions such as maintaining the properties of organic nanoparticles, having high dispersion in a resin, having no degradation of properties even when exposed to incident light for a long time, having excellent room temperature stability, and the like.

### RELATED ART DOCUMENTS

### Patent Documents

(Patent Document 1) Korean Patent Registration No. 10-2081481
(Patent Document 2) Korean Laid-open Patent Application No. 10-2020-0105407

### SUMMARY OF THE INVENTION

The present invention is directed to providing light-emitting down conversion organic nano-dots obtained from a light-emitting organic material that has excellent color conversion efficiency and thermal stability and does not use heavy metals, a composition for a color conversion film including the same, and a color conversion film, a display device, and a light-emitting diode device manufactured using the same.

One aspect of the present invention provides light-emitting down conversion organic nano-dots containing a first organic phosphor and a second organic phosphor, wherein the first organic phosphor has a molar extinction coefficient (ε) of 10,000 L/mol·cm or more at a wavelength of 450 nm, and an emission spectrum of the first organic phosphor overlaps an absorption spectrum of the second organic phosphor.

A Forster radius (R_{O}) between the first and second organic phosphors may be 7.0 nm of less.

A weight ratio of the first and second organic phosphors may range from 5.0:5.0 to 9.5:0.5.

The light-emitting down conversion organic nano-dots may have an average particle size of 100 to 170 nm and a standard deviation of particle sizes of 500 nm or less.

The light-emitting down conversion organic nano-dots may have core-shell structure in which the first and second organic phosphors are surrounded by a surfactant.

The surfactant may be one or more selected from the group consisting of an anionic surfactant, a cationic surfactant, an amphoteric surfactant, and a nonionic surfactant.

A photoluminescence quantum yield (PLQY) of the first organic phosphor may be 50% or more.

The first organic phosphor may include one or more selected from the group consisting of compounds BB-1 to BB-11, BD-1 to BD-9, BM-1 to BM-12, BPer-1 to BPer-20, and BPyr-1 to BPyr-11 below:

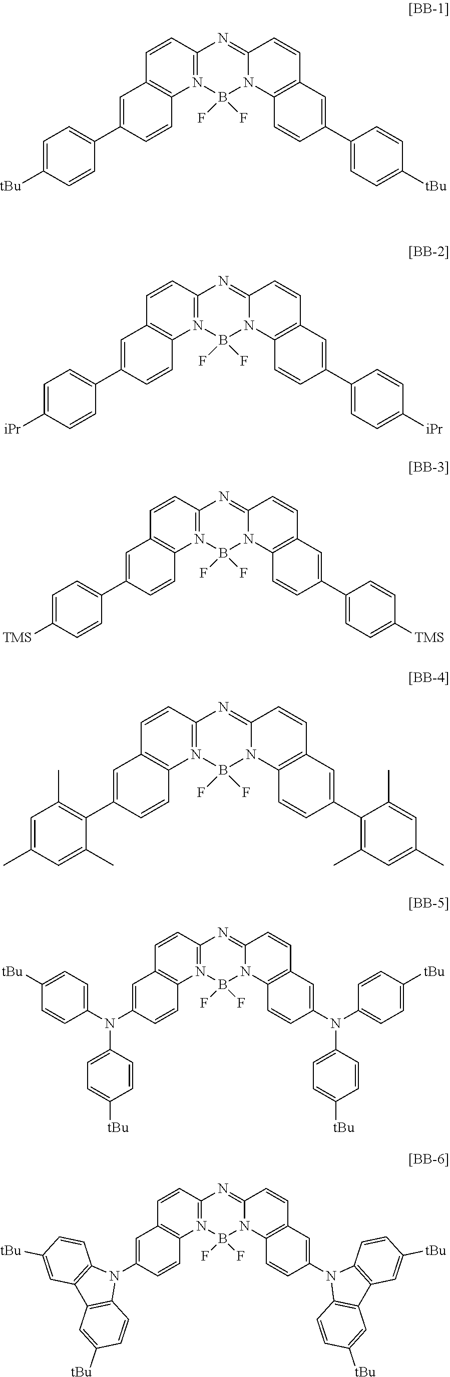

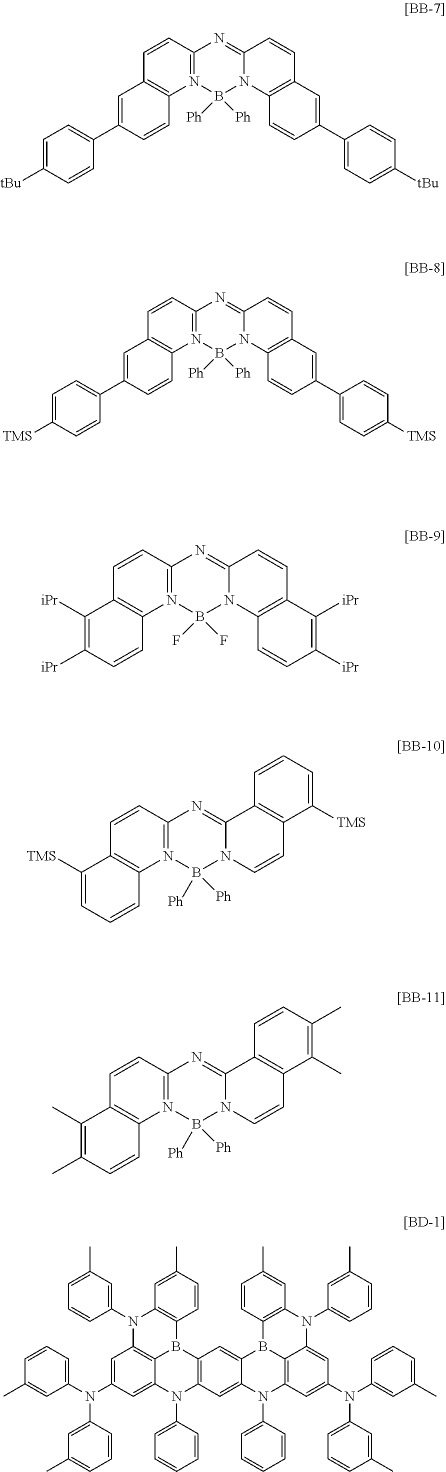

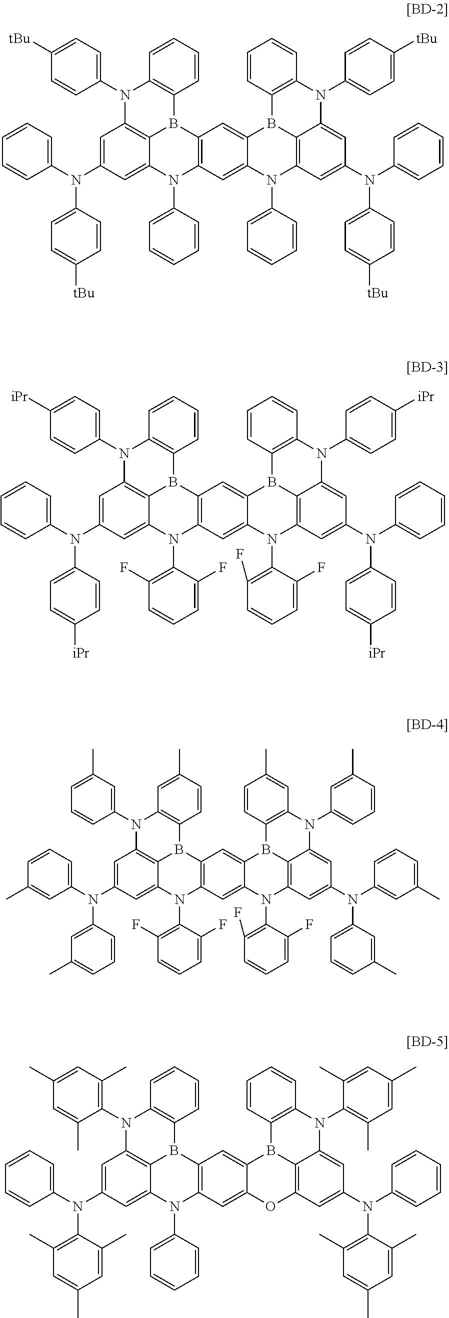

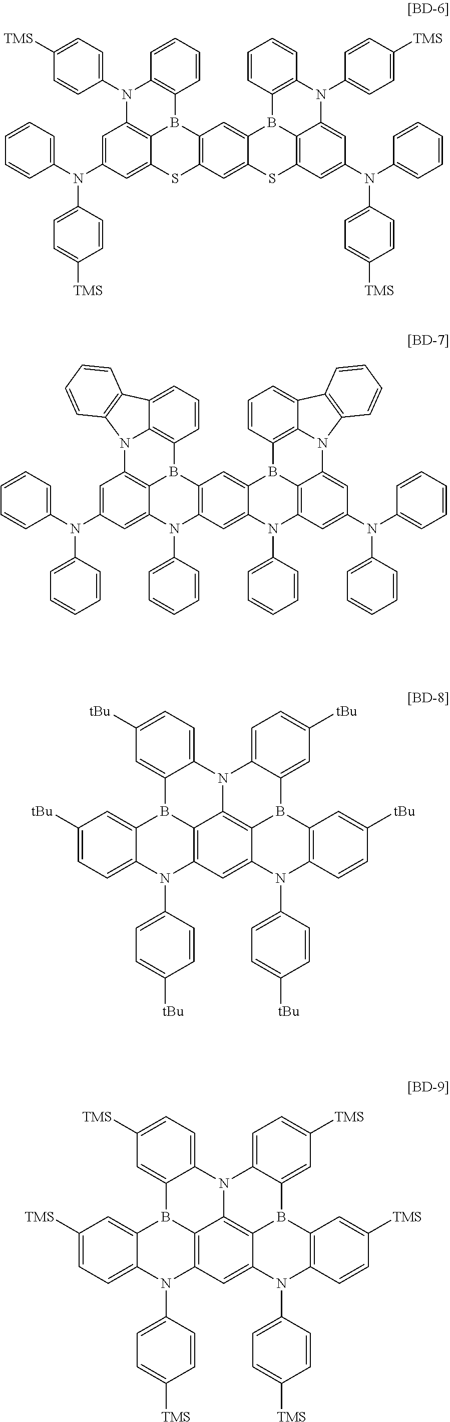

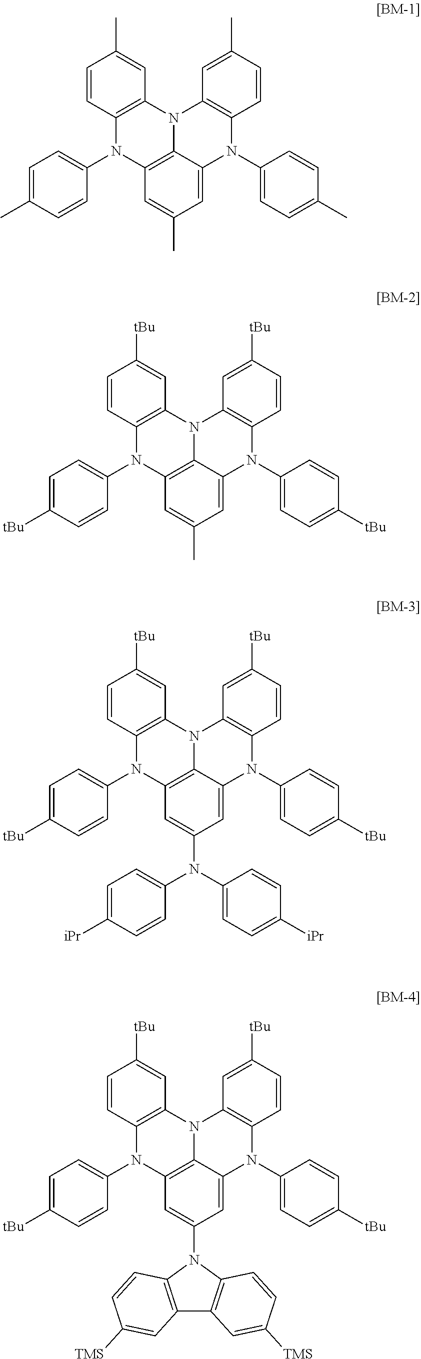

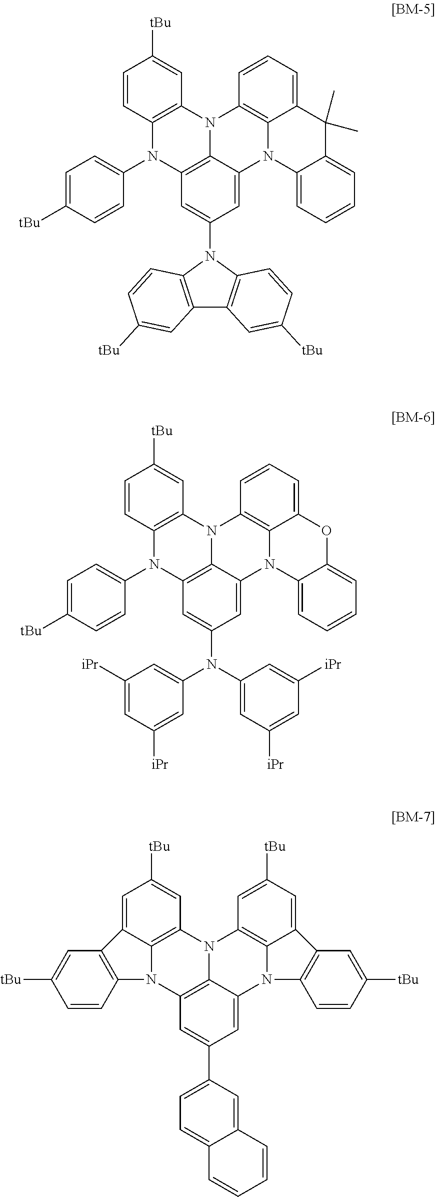 [SMILES: CC(C)(C)c1ccc(N2c3ccc(C(C)(C)C)cc3N3c4cccc5c4N(c4ccccc4C5(C)C)c4cc(-n5c6ccc(C(C)(C)C)cc6c6cc(C(C)(C)C)ccc65)cc2c43)cc1 ; CC(C)c1cc(C(C)C)cc(N(c2cc(C(C)C)cc(C(C)C)c2)c2cc3c4c(c2)n(-c2ccc(C(C)(C)C)cc2)c2ccc(C(C)(C)C)cc2n-4c2cccc4oc5ccccc5n3-c42)c1 ; CC(C)(C)c1ccc2c(c1)c1cc(C(C)(C)C)cc3c1n2c1cc(-c2ccc4ccccc4c2)cc2c1-n3c1cc(C(C)(C)C)cc3c4cc(C(C)(C)C)ccc4n2c31]

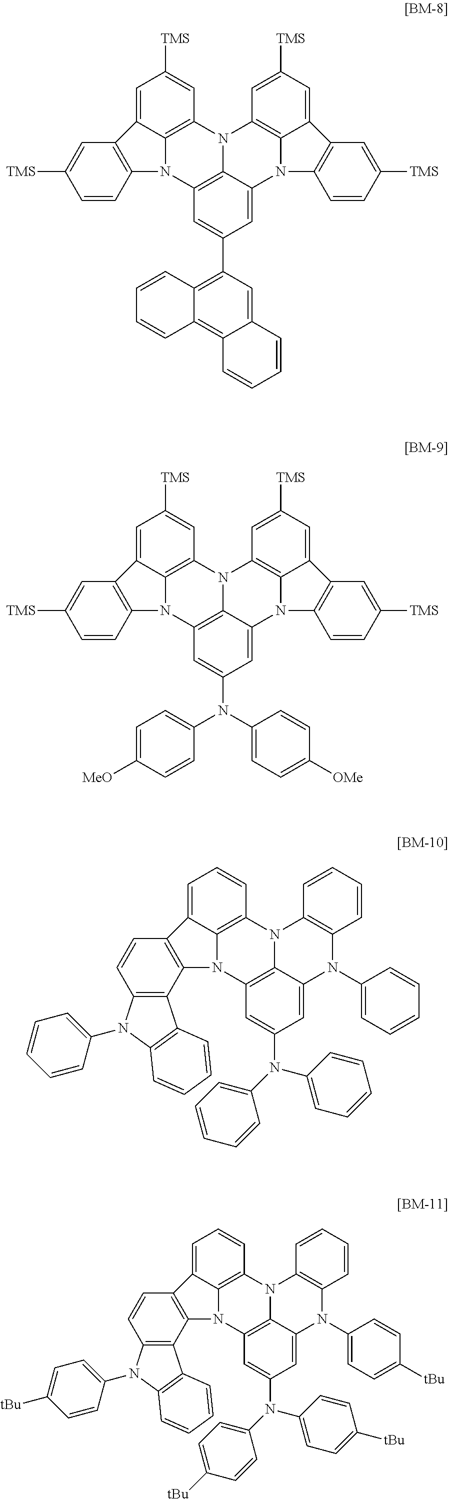

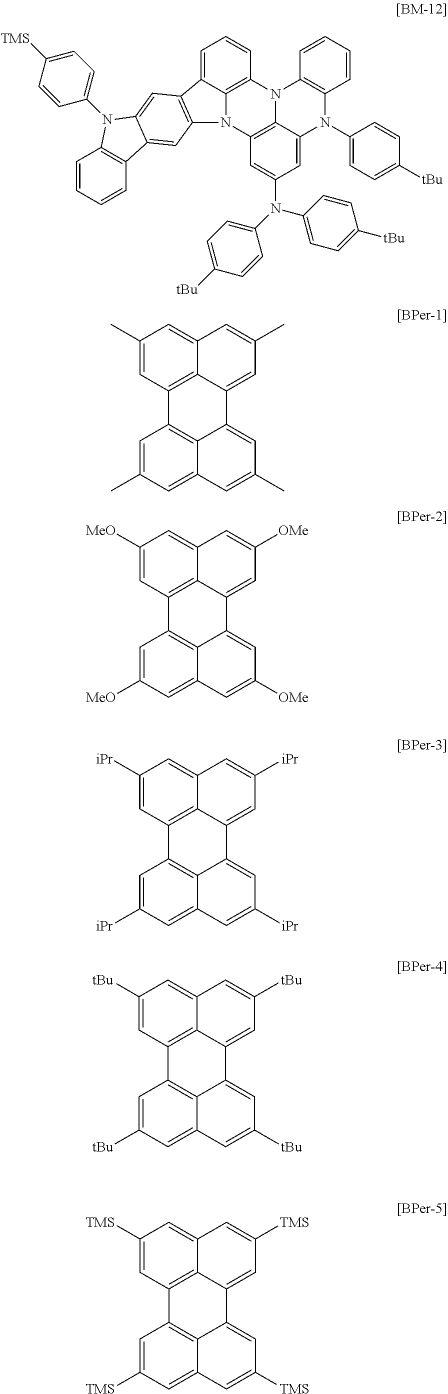

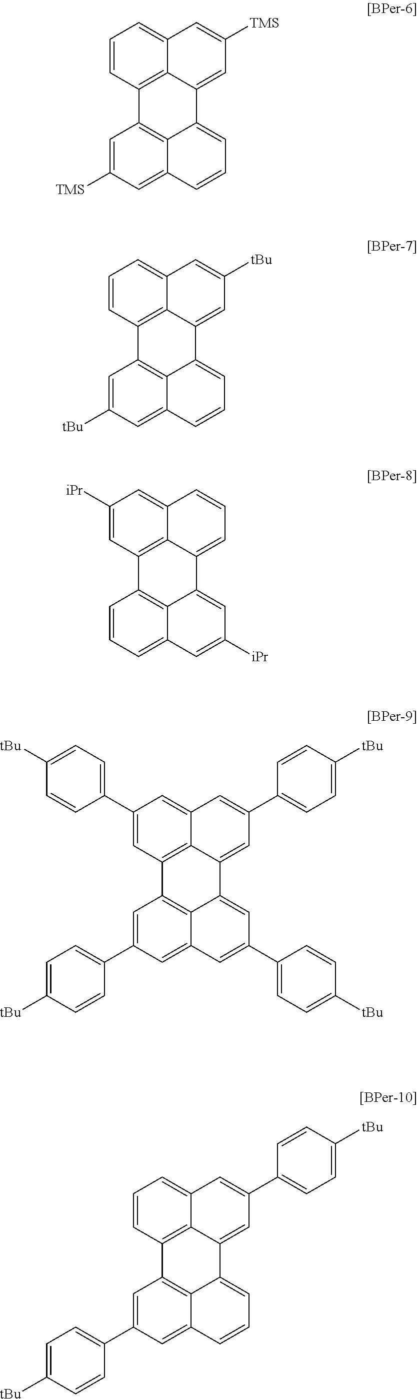

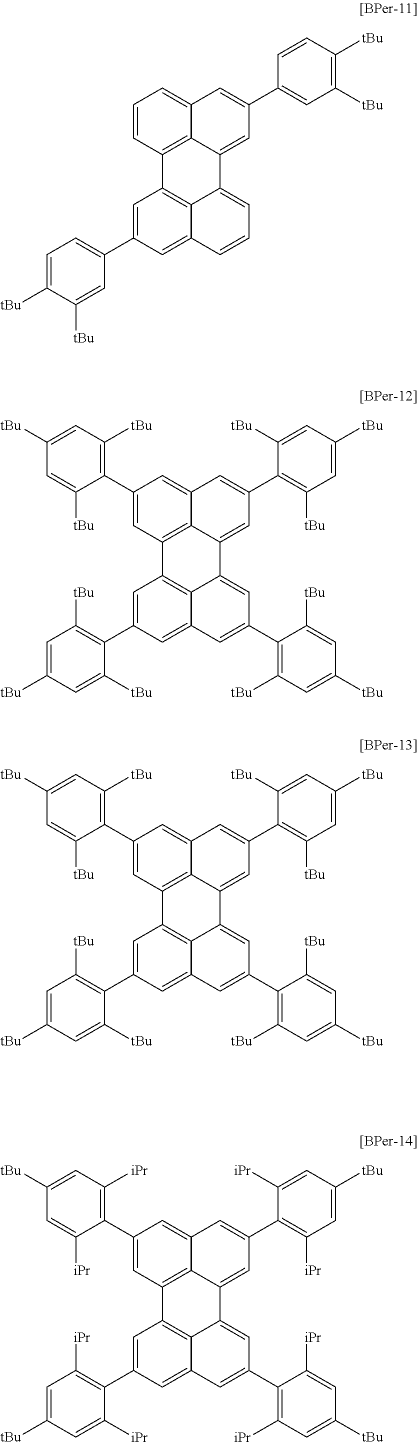

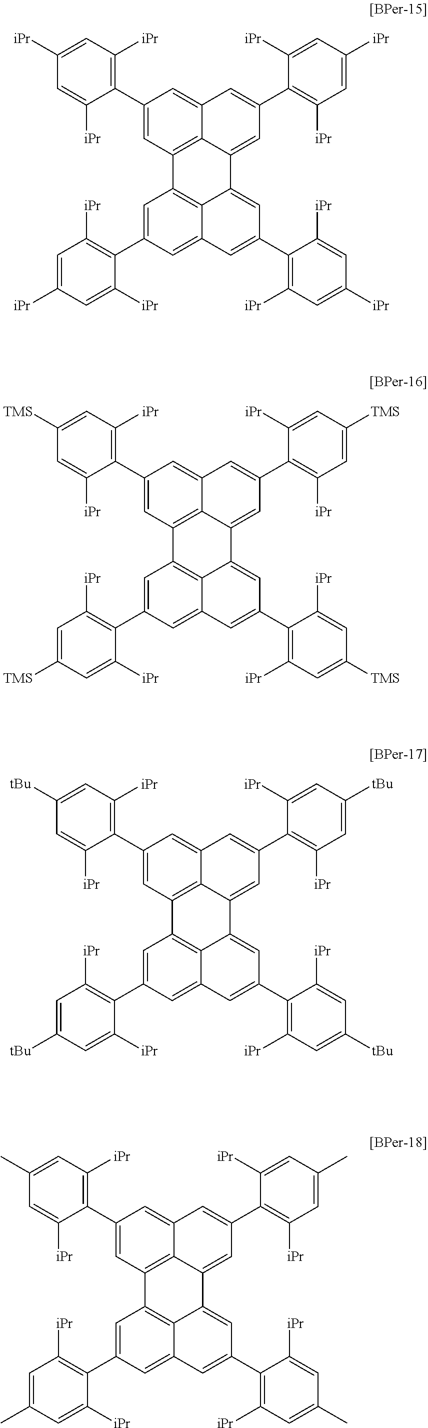

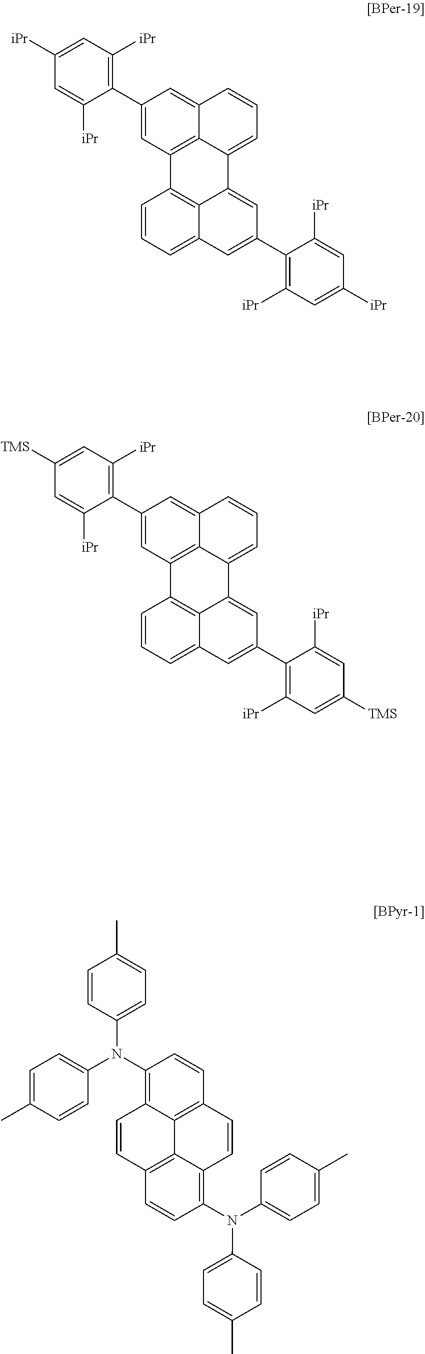

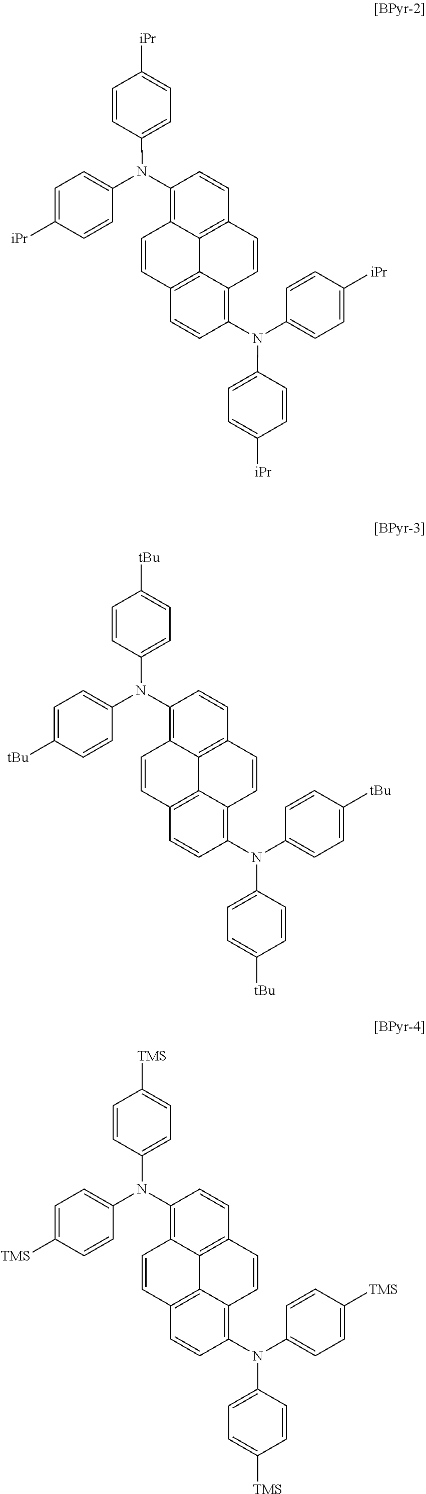 [SMILES: CC(C)c1ccc(N(c2ccc(C(C)C)cc2)c2ccc3ccc4c(N(c5ccc(C(C)C)cc5)c5ccc(C(C)C)cc5)ccc5ccc2c3c54)cc1 ; CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1 ; C[Si](C)(C)c1ccc(N(c2ccc([Si](C)(C)C)cc2)c2ccc3ccc4c(N(c5ccc([Si](C)(C)C)cc5)c5ccc([Si](C)(C)C)cc5)ccc5ccc2c3c54)cc1]

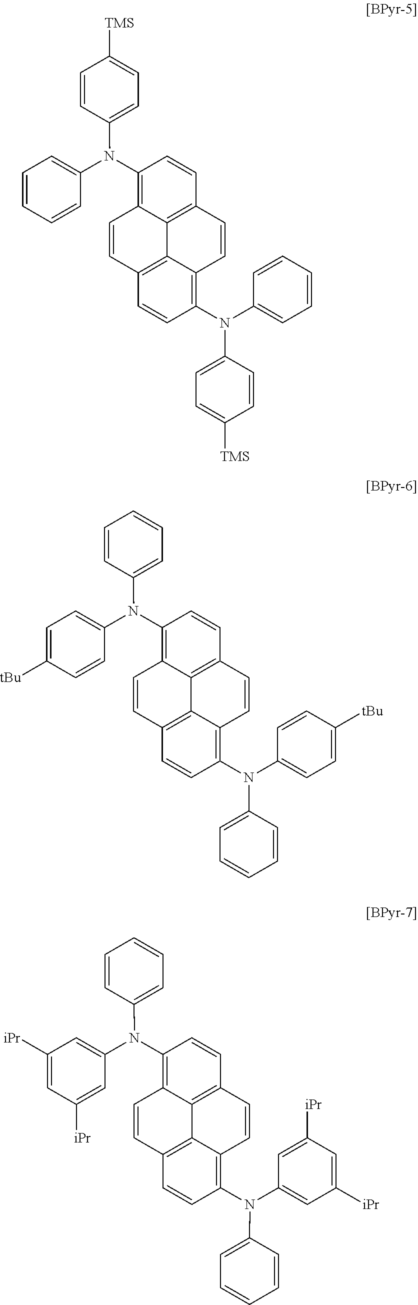 [SMILES: C[Si](C)(C)c1ccc(N(c2ccccc2)c2ccc3ccc4c(N(c5ccccc5)c5ccc([Si](C)(C)C)cc5)ccc5ccc2c3c54)cc1 ; CC(C)(C)c1ccc(N(c2ccccc2)c2ccc3ccc4c(N(c5ccccc5)c5ccc(C(C)(C)C)cc5)ccc5ccc2c3c54)cc1 ; CC(C)c1cc(C(C)C)cc(N(c2ccccc2)c2ccc3ccc4c(N(c5ccccc5)c5cc(C(C)C)cc(C(C)C)c5)ccc5ccc2c3c54)c1]

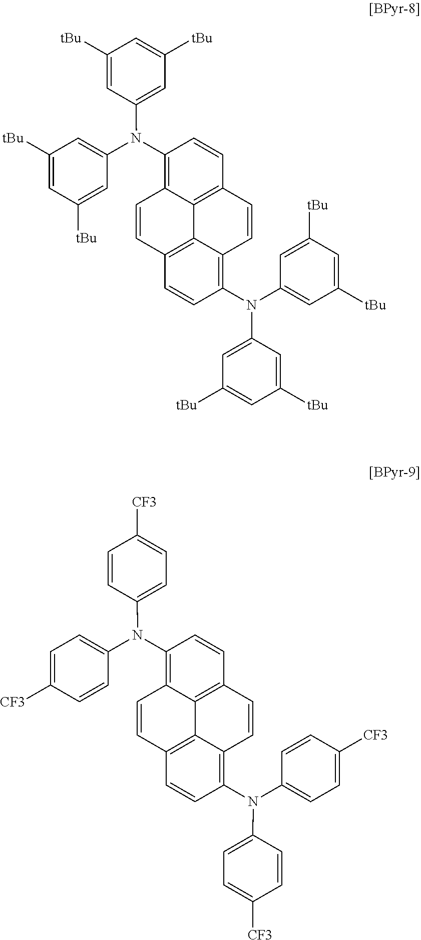 [SMILES: CC(C)(C)c1cc(N(c2cc(C(C)(C)C)cc(C(C)(C)C)c2)c2ccc3ccc4c(N(c5cc(C(C)(C)C)cc(C(C)(C)C)c5)c5cc(C(C)(C)C)cc(C(C)(C)C)c5)ccc5ccc2c3c54)cc(C(C)(C)C)c1 ; FC(F)(F)c1ccc(N(c2ccc(C(F)(F)F)cc2)c2ccc3ccc4c(N(c5ccc(C(F)(F)F)cc5)c5ccc(C(F)(F)F)cc5)ccc5ccc2c3c54)cc1]

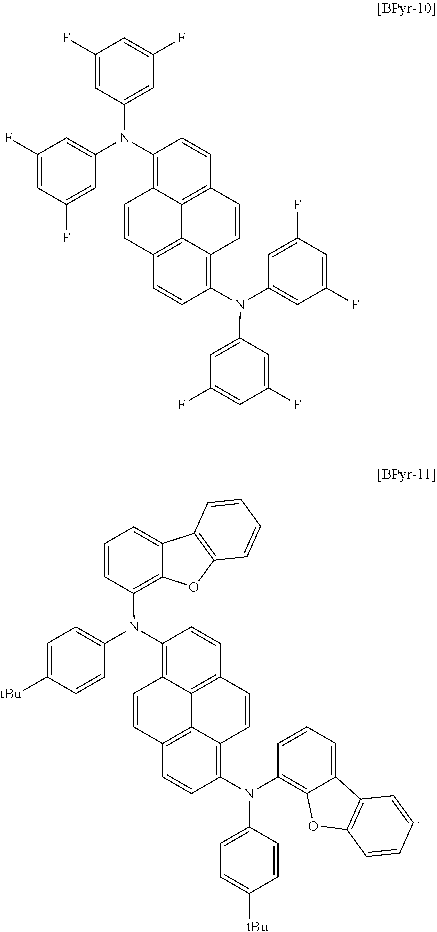 [SMILES: Fc1cc(F)cc(N(c2cc(F)cc(F)c2)c2ccc3ccc4c(N(c5cc(F)cc(F)c5)c5cc(F)cc(F)c5)ccc5ccc2c3c54)c1 ; CC(C)(C)c1ccc(N(c2ccc3ccc4c(N(c5ccc(C(C)(C)C)cc5)c5cccc6c5oc5ccccc56)ccc5ccc2c3c54)c2cccc3c2oc2ccccc23)cc1]

The second organic phosphor may be a delayed fluorescence material.

The delayed fluorescence material may include a compound represented by Chemical Formula 1 below:

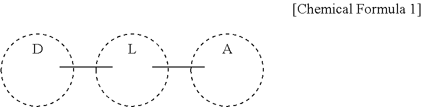

(In Chemical Formula 1 above,

L is any one selected from the group consisting of an aryl group, an arylene group, and a carbon-nitrogen single bond,

when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms,

when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group,

when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms).

The compound represented by Chemical Formula 1 above may be one or more selected from the group consisting of compounds T-1 to T-28 below:

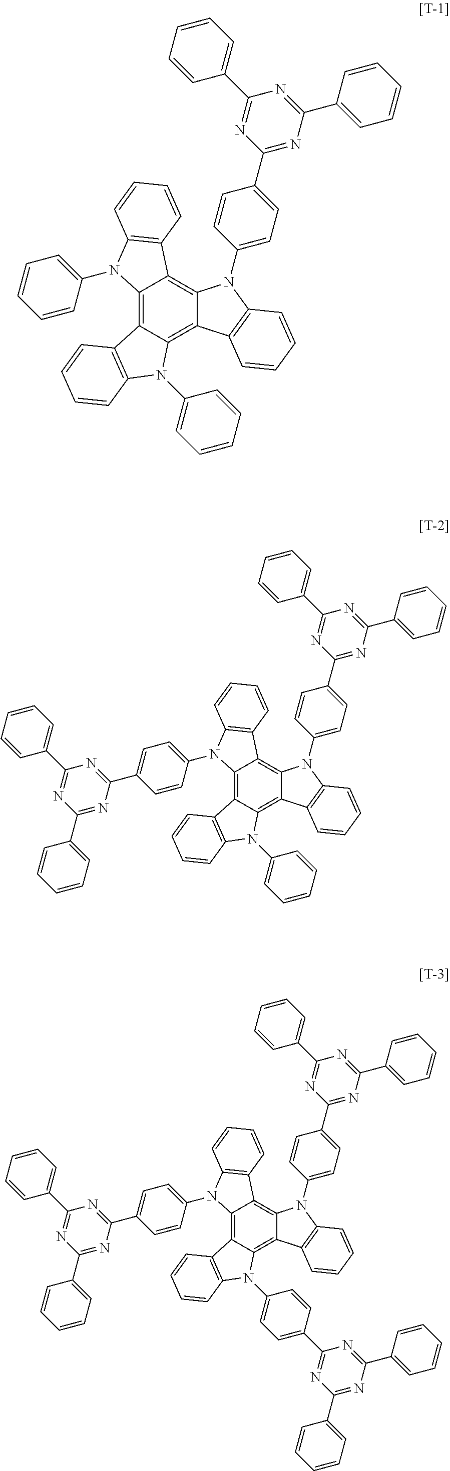 [SMILES: c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1 ; c1ccc(-c2nc(-c3ccccc3)nc(-c3ccc(-n4c5ccccc5c5c6c(c7ccccc7n6-c6ccccc6)c6c(c7ccccc7n6-c6ccc(-c7nc(-c8ccccc8)nc(-c8ccccc8)n7)cc6)c54)cc3)n2)cc1 ; c1ccc(-c2nc(-c3ccccc3)nc(-c3ccc(-n4c5ccccc5c5c4c4c6ccccc6n(-c6ccc(-c7nc(-c8ccccc8)nc(-c8ccccc8)n7)cc6)c4c4c6ccccc6n(-c6ccc(-c7nc(-c8ccccc8)nc(-c8ccccc8)n7)cc6)c54)cc3)n2)cc1]

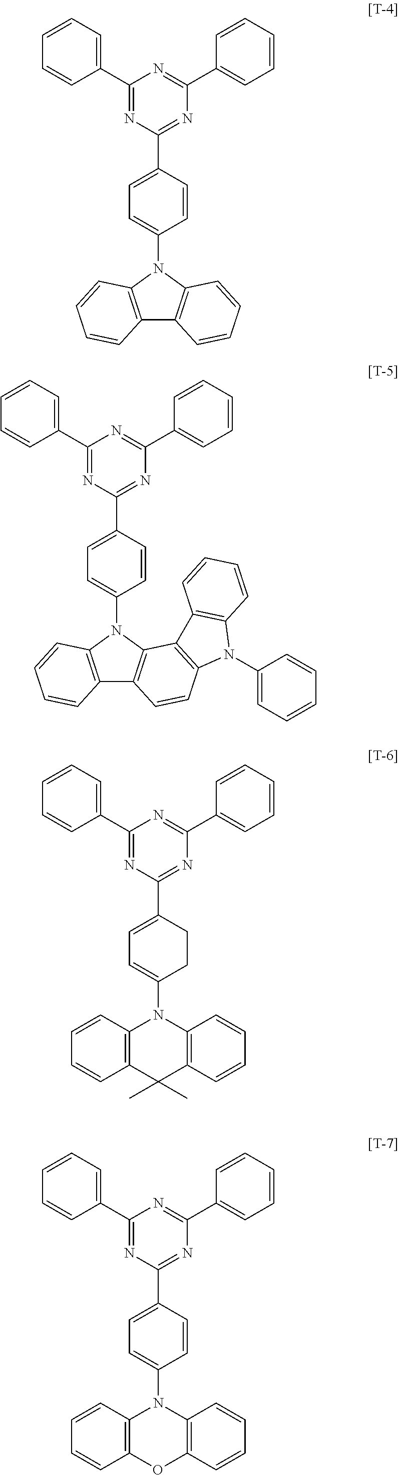

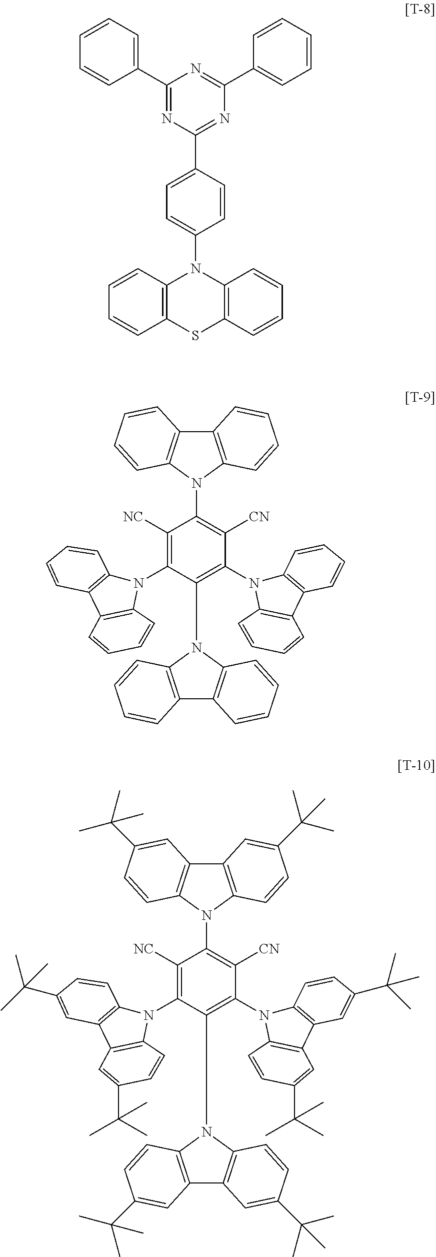 [SMILES: c1ccc(-c2nc(-c3ccccc3)nc(-c3ccc(N4c5ccccc5Sc5ccccc54)cc3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(-n2c3ccc(C(C)(C)C)cc3c3cc(C(C)(C)C)ccc32)c1C#N]

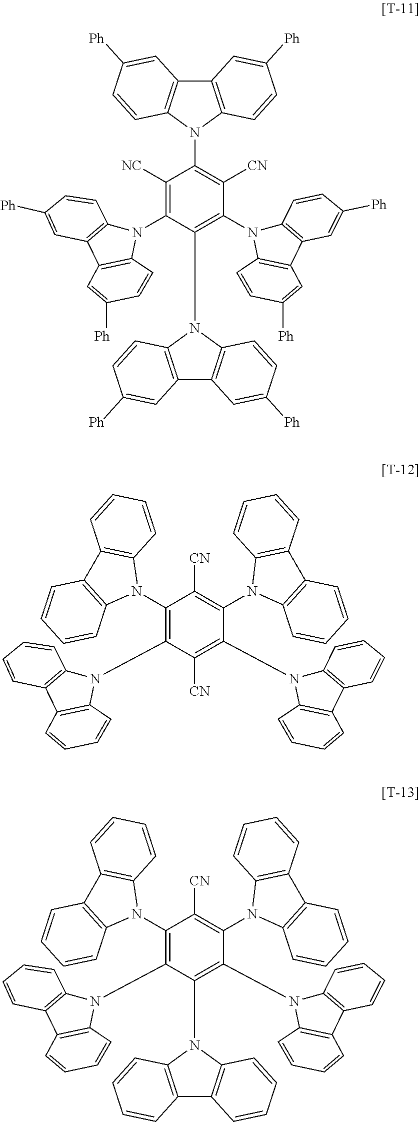 [SMILES: N#Cc1c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccccc3c3ccccc32)c(-n2c3ccccc3c3ccccc32)c(-n2c3ccccc3c3ccccc32)c(-n2c3ccccc3c3ccccc32)c1-n1c2ccccc2c2ccccc21]

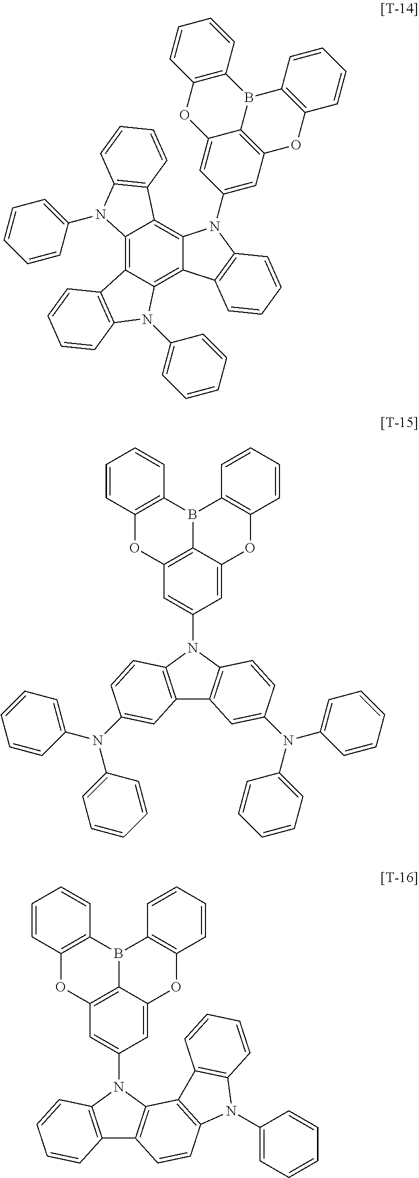 [SMILES: c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1 ; c1ccc(N(c2ccccc2)c2ccc3c(c2)c2cc(N(c4ccccc4)c4ccccc4)ccc2n3-c2cc3c4c(c2)Oc2ccccc2B4c2ccccc2O3)cc1 ; c1ccc(-n2c3ccccc3c3c2ccc2c4ccccc4n(-c4cc5c6c(c4)Oc4ccccc4B6c4ccccc4O5)c23)cc1]

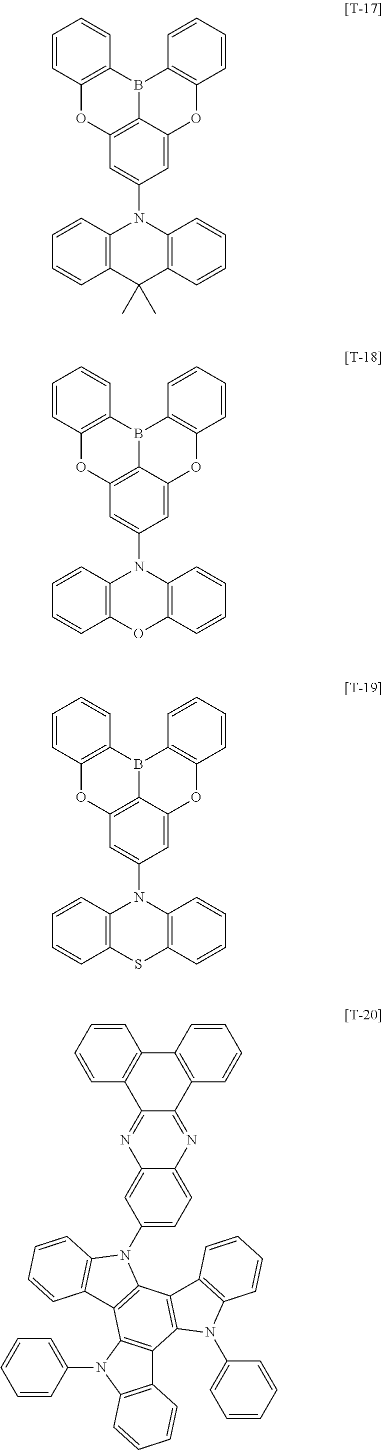 [SMILES: CC1(C)c2ccccc2N(c2cc3c4c(c2)Oc2ccccc2B4c2ccccc2O3)c2ccccc21 ; c1ccc2c(c1)Oc1cc(N3c4ccccc4Oc4ccccc43)cc3c1B2c1ccccc1O3 ; c1ccc2c(c1)Oc1cc(N3c4ccccc4Sc4ccccc43)cc3c1B2c1ccccc1O3 ; c1ccc(-n2c3ccccc3c3c2c2c4ccccc4n(-c4ccc5nc6c7ccccc7c7ccccc7c6nc5c4)c2c2c4ccccc4n(-c4ccccc4)c32)cc1]

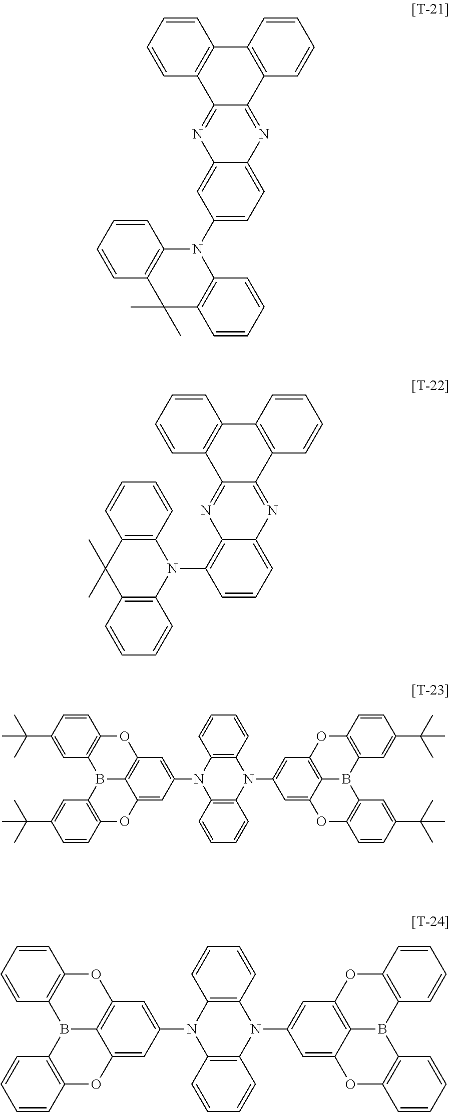 [SMILES: CC1(C)c2ccccc2N(c2ccc3nc4c5ccccc5c5ccccc5c4nc3c2)c2ccccc21 ; CC1(C)c2ccccc2N(c2cccc3nc4c5ccccc5c5ccccc5c4nc23)c2ccccc21 ; CC(C)(C)c1ccc2c(c1)B1c3cc(C(C)(C)C)ccc3Oc3cc(N4c5ccccc5N(c5cc6c7c(c5)Oc5ccc(C(C)(C)C)cc5B7c5cc(C(C)(C)C)ccc5O6)c5ccccc54)cc(c31)O2 ; c1ccc2c(c1)Oc1cc(N3c4ccccc4N(c4cc5c6c(c4)Oc4ccccc4B6c4ccccc4O5)c4ccccc43)cc3c1B2c1ccccc1O3]

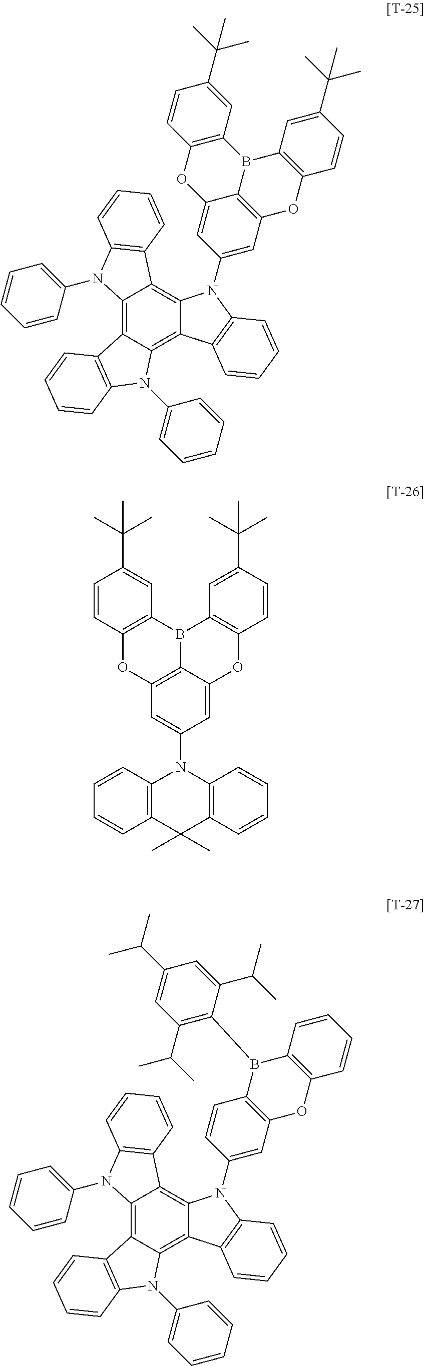 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; CC(C)(C)c1ccc2c(c1)B1c3cc(C(C)(C)C)ccc3Oc3cc(N4c5ccccc5C(C)(C)c5ccccc54)cc(c31)O2 ; CC(C)c1cc(C(C)C)c(B2c3ccccc3Oc3cc(-n4c5ccccc5c5c6c(c7ccccc7n6-c6ccccc6)c6c(c7ccccc7n6-c6ccccc6)c54)ccc32)c(C(C)C)c1]

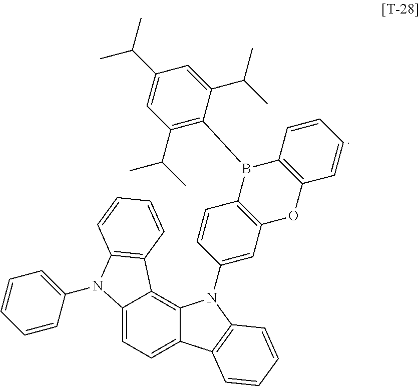 [SMILES: CC(C)c1cc(C(C)C)c(B2c3ccccc3Oc3cc(-n4c5ccccc5c5ccc6c(c7ccccc7n6-c6ccccc6)c54)ccc32)c(C(C)C)c1]

The second organic phosphor may include a boron compound represented by Chemical Formula 2 below:

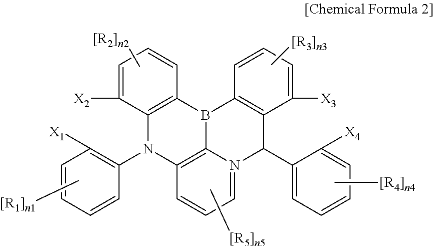

(In Chemical Formula 2 above,

R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,

X₁ to X₄ are each independently hydrogen, hydroxyl group or a substituted or unsubstituted alkyl group,

n1 and n4 are each independently an integer of 1 to 4,

n2, n3 and n5 are each independently an integer of 1 to 3,

if n1 to n5 are 2 or more, the structures in the brackets, are the same or different, respectively,

R₁ to R₅ and X₁ to X₄ may bond to adjacent substituents to form a substituted or unsubstituted ring).

The boron compound represented by Chemical Formula 2 above may be one or more selected from the group consisting of compounds D-1 to D-30 below:

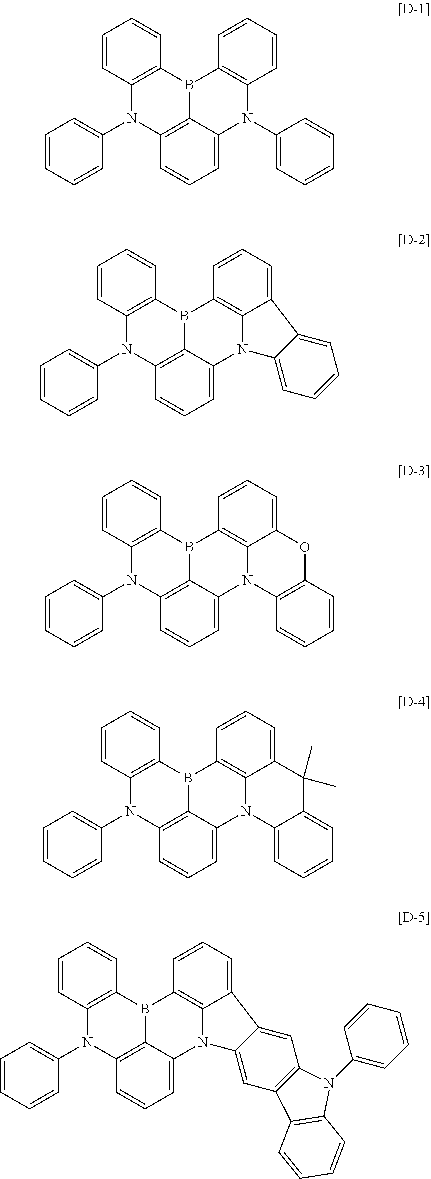 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4c2cccc4-n2c4cc5c6ccccc6n(-c6ccccc6)c5cc4c4cccc3c42)cc1]

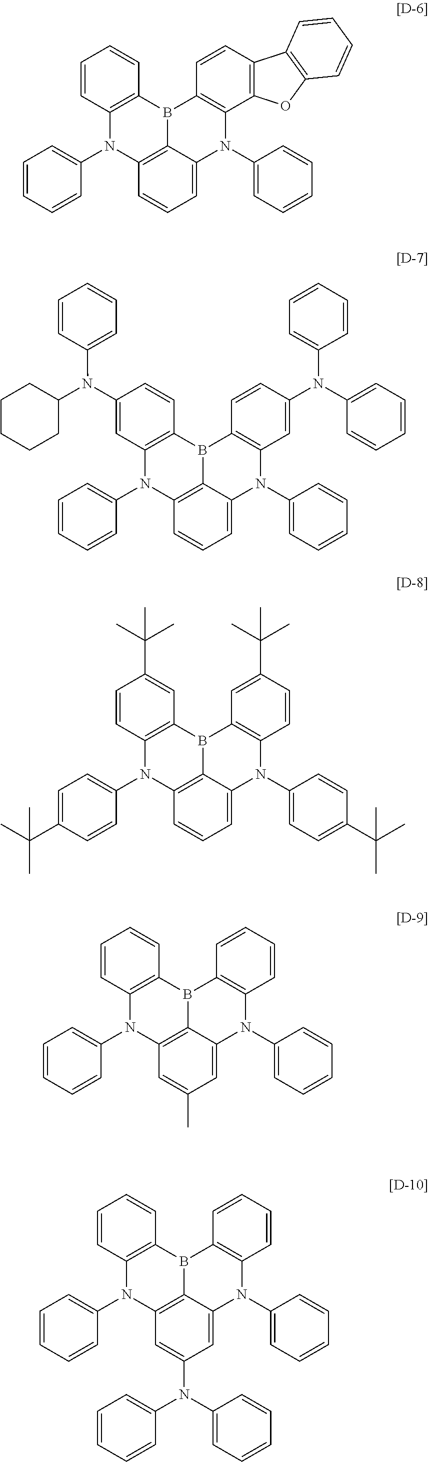 [SMILES: c1ccc(N2c3ccccc3B3c4ccc5c(oc6ccccc65)c4N(c4ccccc4)c4cccc2c43)cc1 ; c1ccc(N(c2ccccc2)c2ccc3c(c2)N(c2ccccc2)c2cccc4c2B3c2ccc(N(c3ccccc3)C3CCCCC3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1cc2c3c(c1)N(c1ccccc1)c1ccccc1B3c1ccccc1N2c1ccccc1 ; c1ccc(N(c2ccccc2)c2cc3c4c(c2)N(c2ccccc2)c2ccccc2B4c2ccccc2N3c2ccccc2)cc1]

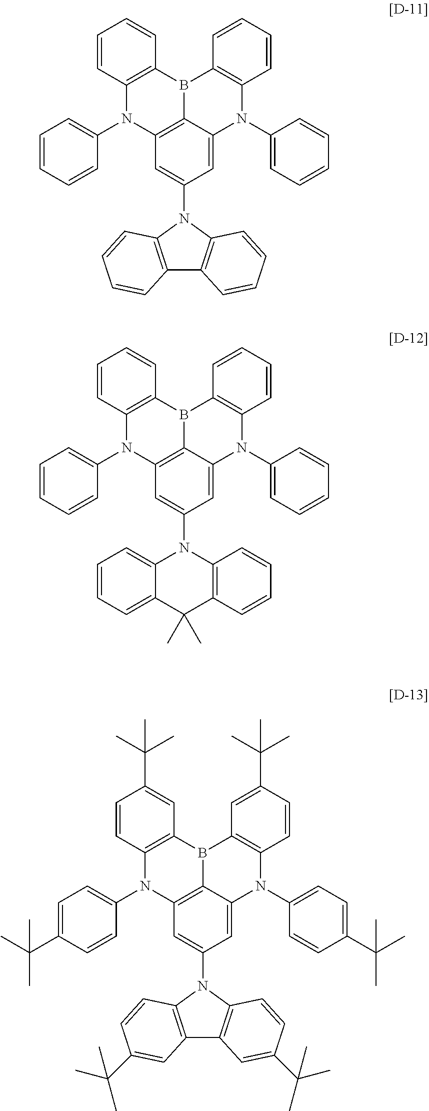 [SMILES: c1ccc(N2c3ccccc3B3c4ccccc4N(c4ccccc4)c4cc(-n5c6ccccc6c6ccccc65)cc2c43)cc1 ; CC1(C)c2ccccc2N(c2cc3c4c(c2)N(c2ccccc2)c2ccccc2B4c2ccccc2N3c2ccccc2)c2ccccc21 ; CC(C)(C)c1ccc(N2c3ccc(C(C)(C)C)cc3B3c4cc(C(C)(C)C)ccc4N(c4ccc(C(C)(C)C)cc4)c4cc(-n5c6ccc(C(C)(C)C)cc6c6cc(C(C)(C)C)ccc65)cc2c43)cc1]

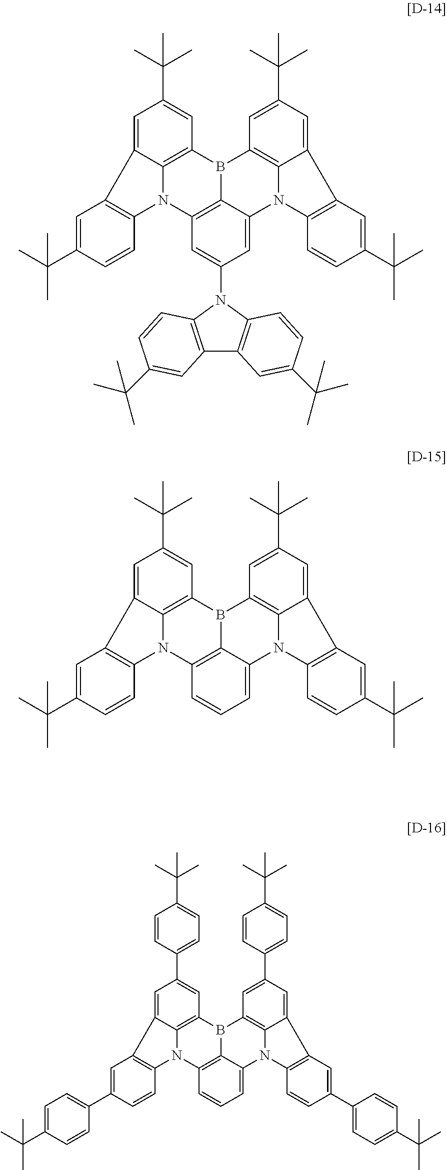

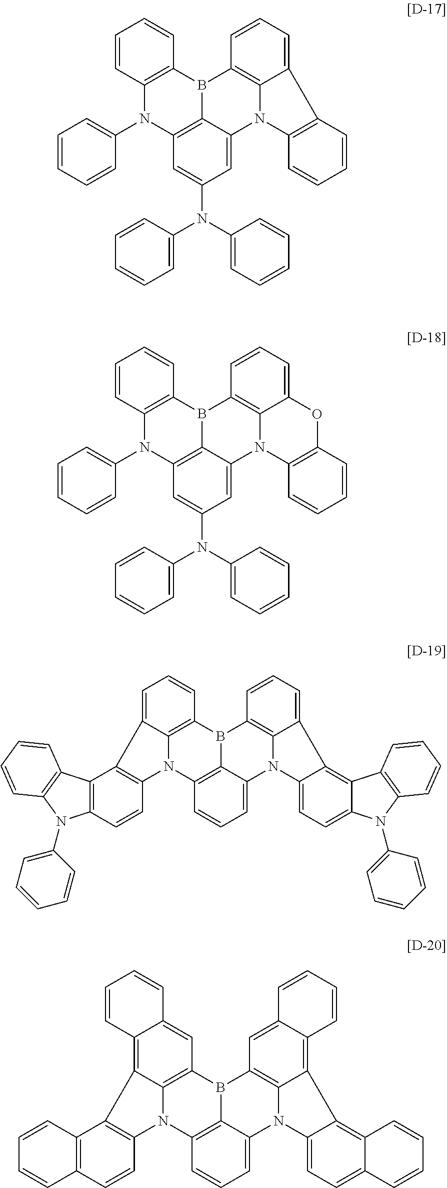 [SMILES: c1ccc(N(c2ccccc2)c2cc3c4c(c2)-n2c5ccccc5c5cccc(c52)B4c2ccccc2N3c2ccccc2)cc1 ; c1ccc(N(c2ccccc2)c2cc3c4c(c2)N2c5ccccc5Oc5cccc(c52)B4c2ccccc2N3c2ccccc2)cc1 ; c1ccc(-n2c3ccccc3c3c4c5cccc6c5n(c4ccc32)-c2cccc3c2B6c2cccc4c5c6c7ccccc7n(-c7ccccc7)c6ccc5n-3c24)cc1 ; c1cc2c3c(c1)-n1c4ccc5ccccc5c4c4c5ccccc5cc(c41)B3c1cc3ccccc3c3c4c5ccccc5ccc4n-2c13]

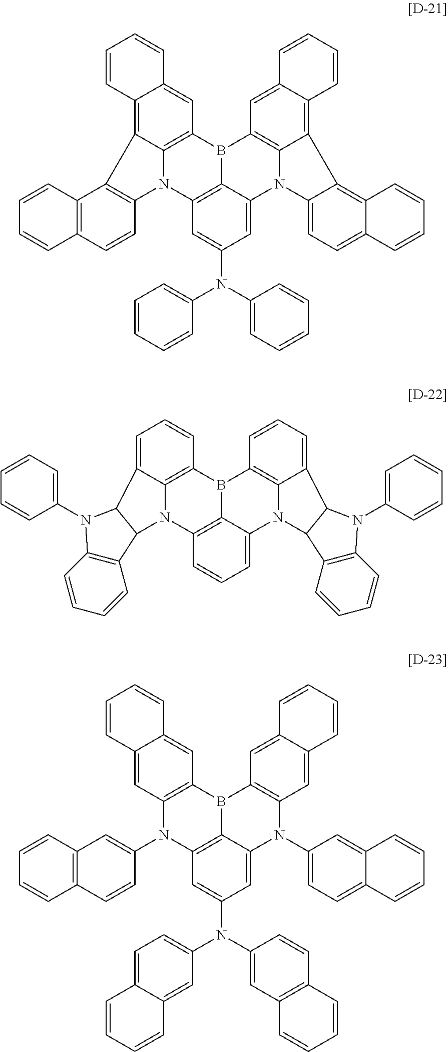 [SMILES: c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1 ; c1ccc(N2c3ccccc3C3C2c2cccc4c2N3c2cccc3c2B4c2cccc4c2N3C2c3ccccc3N(c3ccccc3)C42)cc1 ; c1ccc2cc(N(c3cc4c5c(c3)N(c3ccc6ccccc6c3)c3cc6ccccc6cc3B5c3cc5ccccc5cc3N4c3ccc4ccccc4c3)c3ccc4ccccc4c3)ccc2c1]

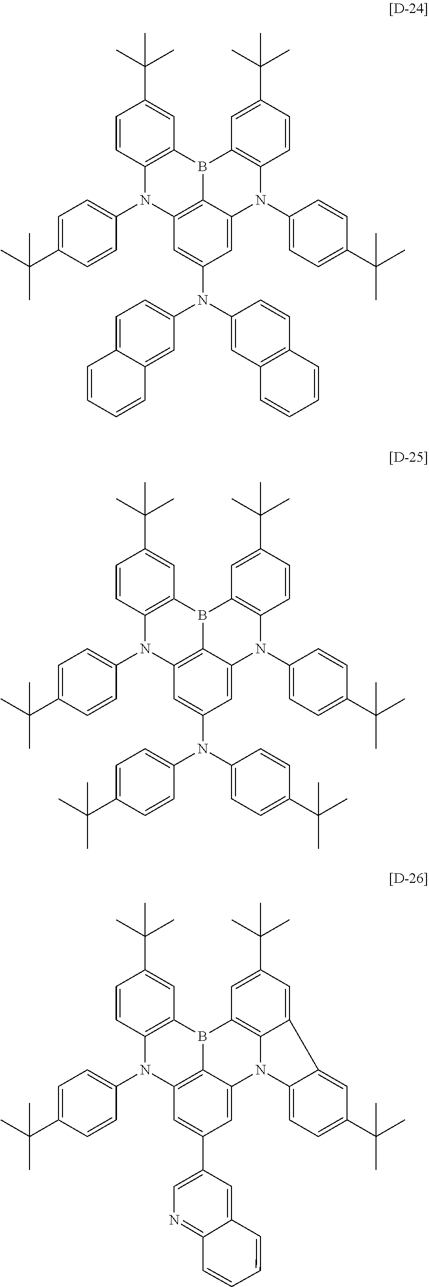

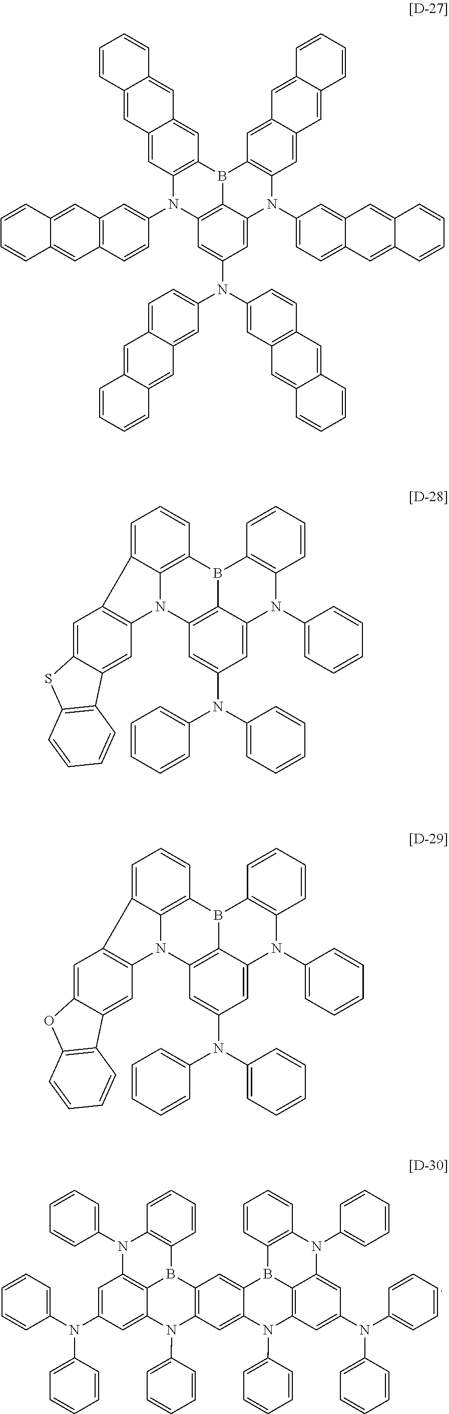 [SMILES: c1ccc2cc3cc(N(c4cc5c6c(c4)N(c4ccc7cc8ccccc8cc7c4)c4cc7cc8ccccc8cc7cc4B6c4cc6cc7ccccc7cc6cc4N5c4ccc5cc6ccccc6cc5c4)c4ccc5cc6ccccc6cc5c4)ccc3cc2c1 ; c1ccc(N(c2ccccc2)c2cc3c4c(c2)-n2c5cc6c(cc5c5cccc(c52)B4c2ccccc2N3c2ccccc2)sc2ccccc26)cc1 ; c1ccc(N(c2ccccc2)c2cc3c4c(c2)-n2c5cc6c(cc5c5cccc(c52)B4c2ccccc2N3c2ccccc2)oc2ccccc26)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

The second organic phosphor may include a boron compound represented by Chemical Formula 3 below:

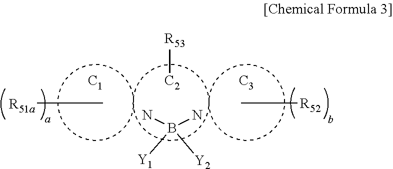

(In Chemical Formula 3 above,

C₁ to C₃ each have a five-membered or six-membered ring structure,

R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group,

R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,

Y₁ and Y₂ are each independently a fluorine group or an alkoxy group, a and b are each independently an integer of 1 to 4,

if a and b are 2 or more, the structures in the brackets, are the same or different, respectively,

R₅₁ and R₅₂ may bond to adjacent substituents to form a substituted or unsubstituted ring).

The boron compound represented by Chemical Formula 3 above may be one or more selected from the group consisting of compounds B-1 to B-51 below:

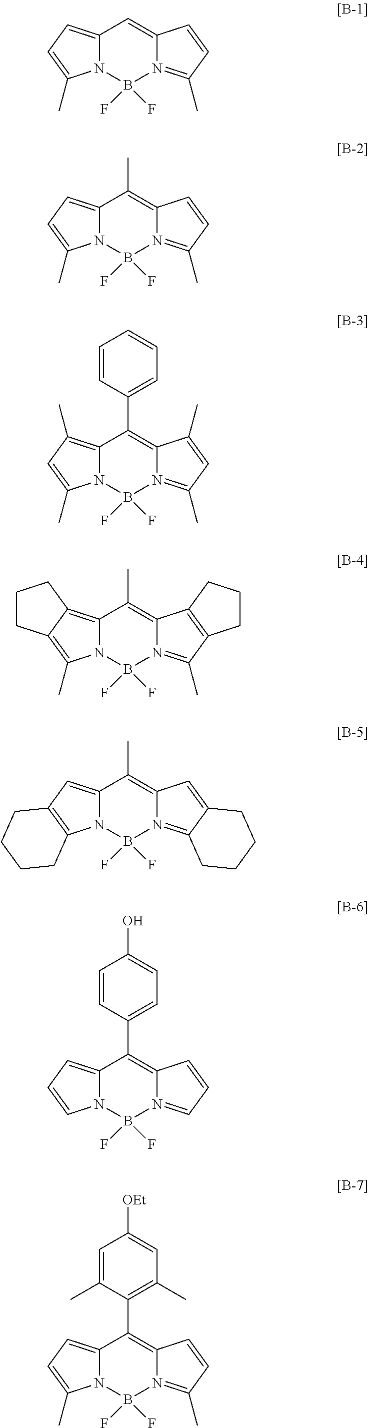

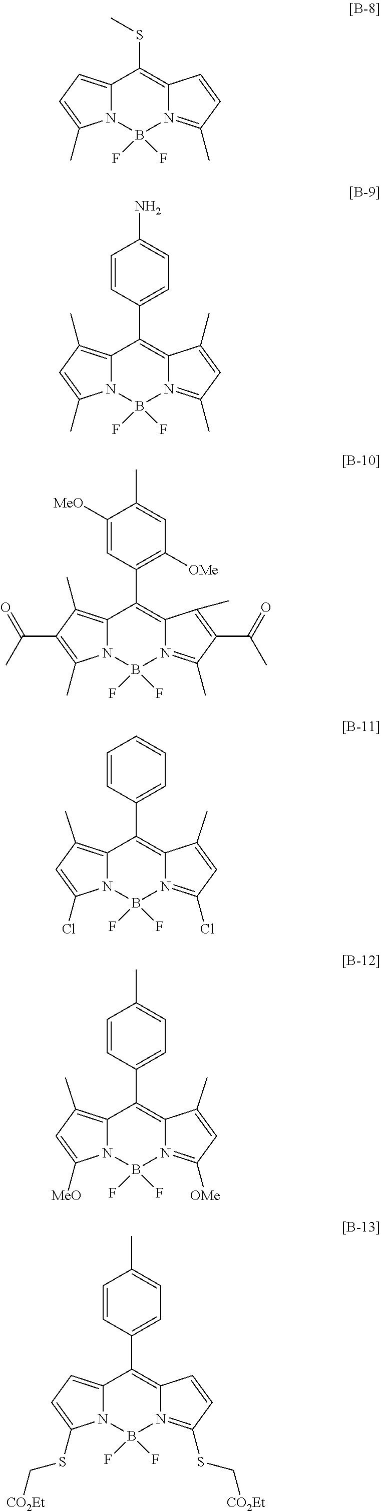

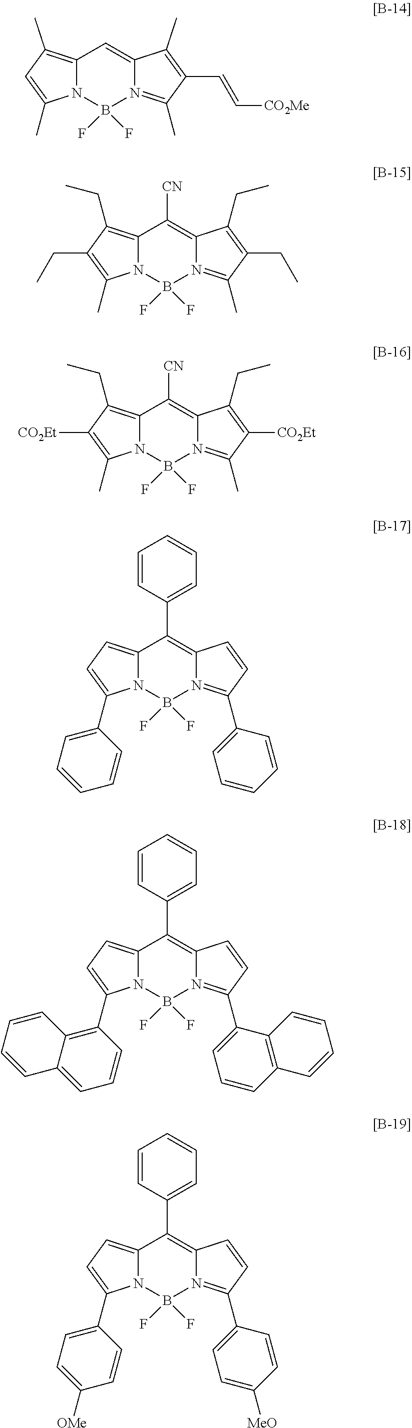

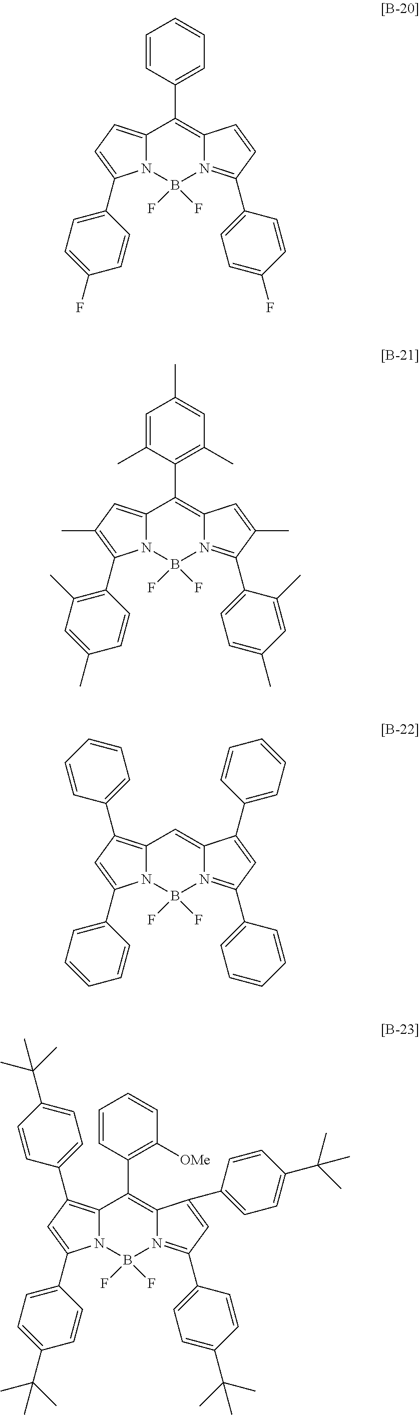

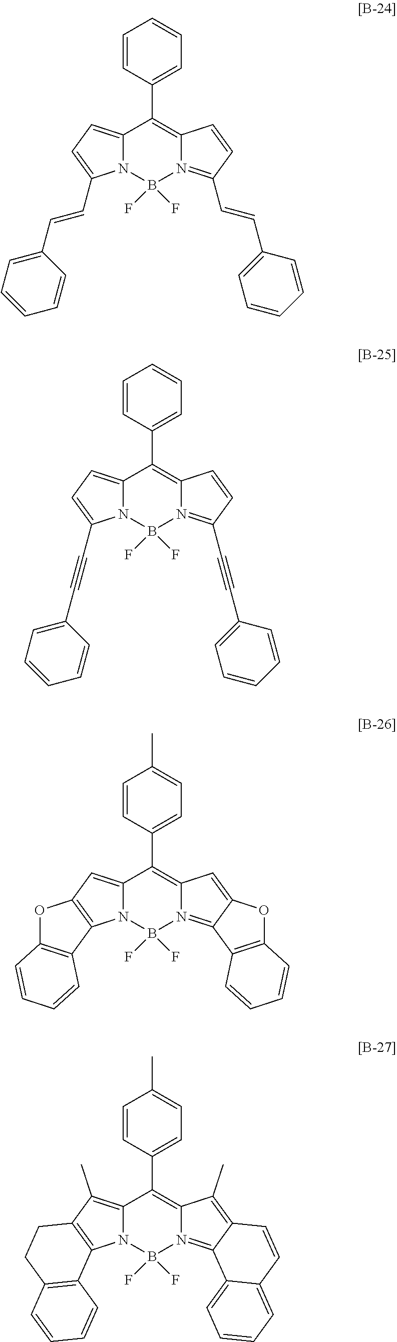

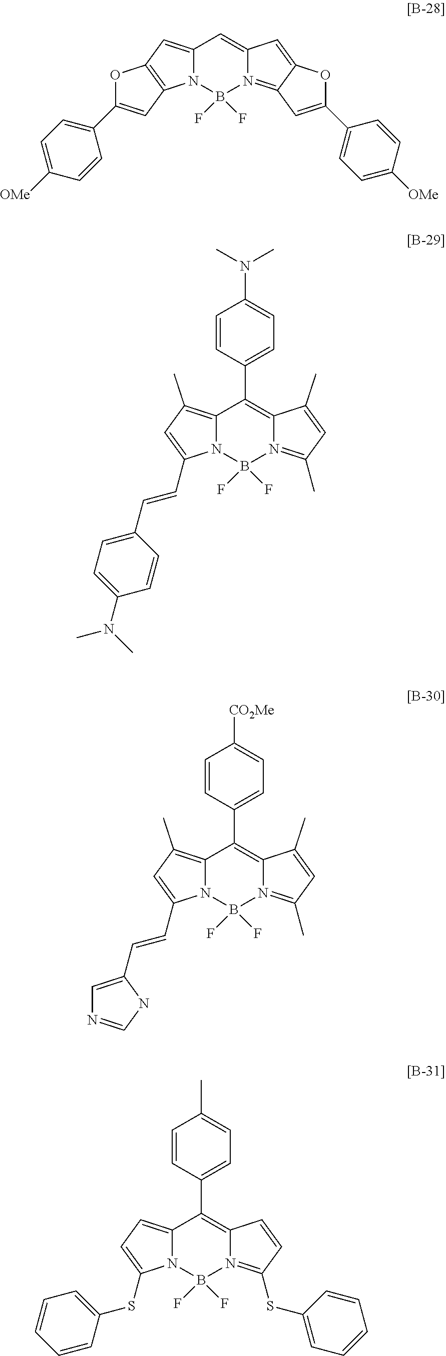

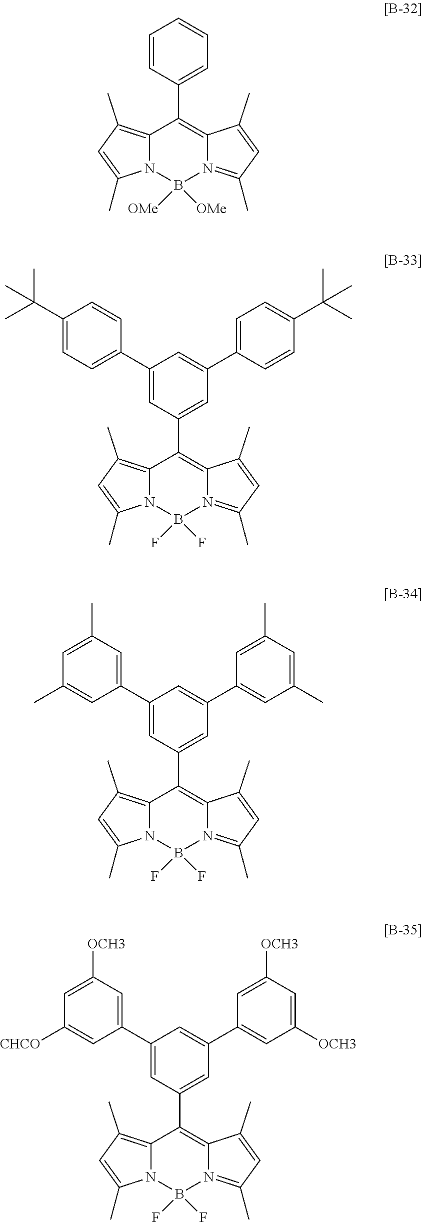

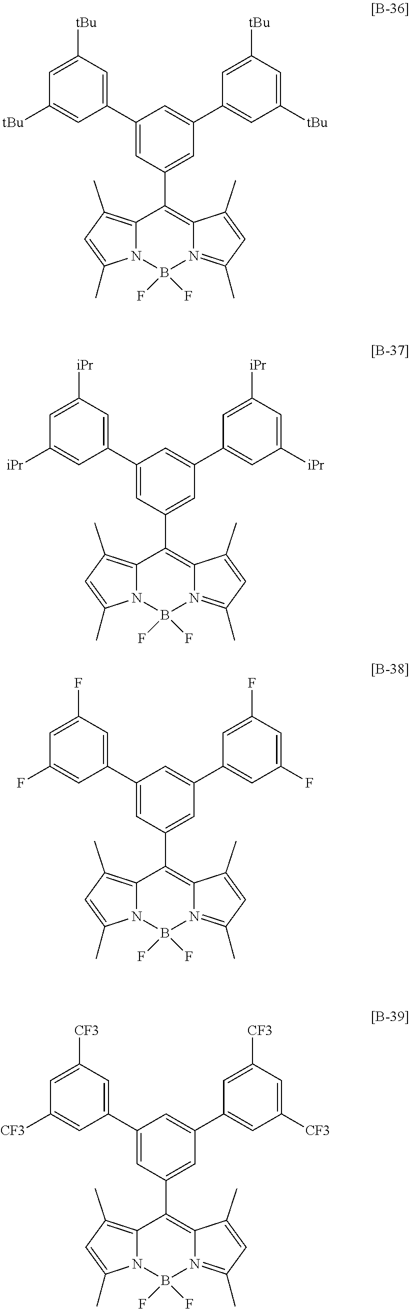

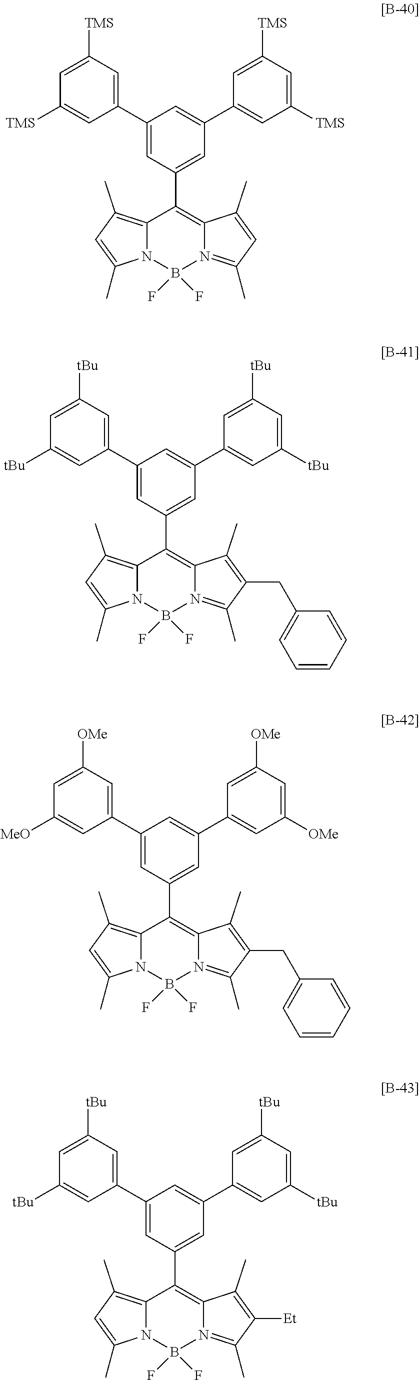

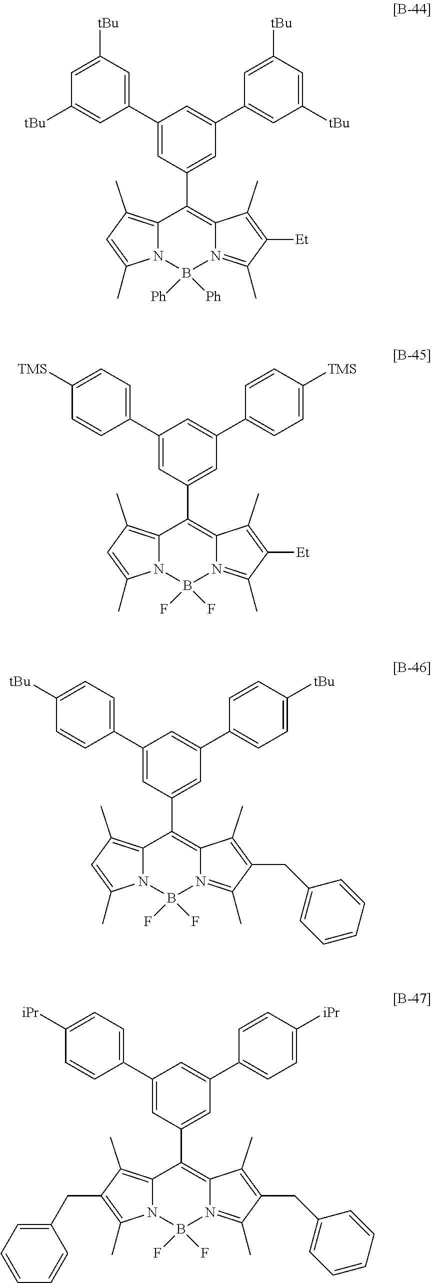

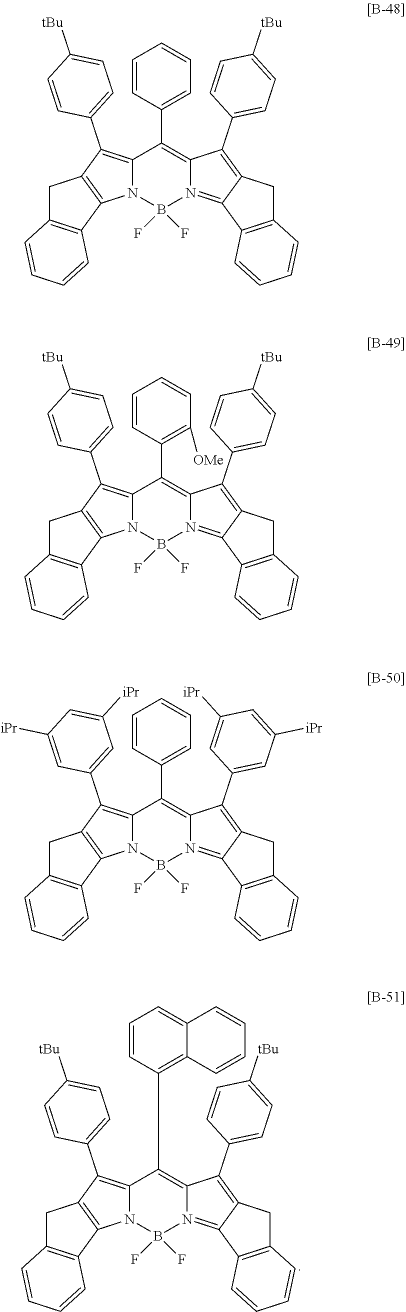

Another aspect of the present invention provides a composition for a color conversion film, containing the light-emitting down conversion organic nano-dots and a water-soluble polymer resin.

The composition for a color conversion film may include 1 to 20 parts by weight of the light-emitting down conversion organic nano-dots based on 100 parts by weight of the water-soluble polymer resin.

Still another aspect of the present invention provides a color conversion film manufactured using the composition for a color conversion film.

Yet another aspect of the present invention provides a display device or a light-emitting diode device including the color conversion film.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIGS. 1A to 1C are a graph showing normalized photoluminescence intensity spectra for a 4tBuMB solution, a 4tBuMB red organic nano-dot (ROND) solution, and a Per-4tBuMB down conversion-red organic nano-dot (DC-ROND) solution, respectively, and FIGS. 2A to 2C are a graph showing normalized photoluminescence intensity spectra for a tPhBODIPY solution, a tPhBODIPY green organic nano-dot (GOND) solution, and a Per-tPhBODIPY down conversion-green organic nano-dot (DC-GOND) solution, respectively;

FIG. 3A is a graph showing normalized photoluminescence intensity spectra of color conversion films according to Manufacturing Examples 2-1 and 2-2, and FIG. 3B is a graph showing normalized photoluminescence intensity spectra of color conversion films according to Manufacturing Examples 2-3 and 2-4;

FIG. 4A is a graph showing an absorption spectrum of the color conversion film according to Manufacturing Example 2-2, and FIG. 4B is a graph showing a photoluminescence intensity spectrum of the color conversion film according to Manufacturing Example 2-2;

FIG. 5A is a graph showing an absorption spectrum of the color conversion film according to Manufacturing Example 2-4, and FIG. 5B is a graph showing a photoluminescence intensity spectrum of the color conversion film according to Manufacturing Example 2-4;

FIG. 6A to 6D are a graph showing the radiant power of color conversion films according to Manufacturing Examples 3-1 to 3-4; and

FIG. 7A to 7C are a graph showing the radiant power of color conversion films according to Manufacturing Examples 6-1 and 6-2, and FIG. 7D is a photograph obtained by observing a photoluminescence and down conversion-green and red organic nano-dot (DC-GROND) color conversion film of a DC-GROND solution according to Manufacturing Example 6-1 in an ultraviolet (UV) lamp.

### DETAILED DESCRIPTION OF EXEMPLARY EMBODIMENTS

Prior to the detailed description of the present invention, terms and words used in this specification and claims should not be interpreted as limited to commonly used meanings or meanings in dictionaries and should be interpreted with meanings and concepts which are consistent with the technological scope of the invention based on the principle that the inventors have appropriately defined concepts of terms in order to describe the invention in the best way. Therefore, since the embodiments described in this specification and configurations illustrated in drawings are only exemplary embodiments and do not represent the overall technological scope of the invention, it should be understood that the invention covers various equivalents, modifications, and substitutions at the time of filing of this application.

Throughout this specification, when a certain part “includes” a certain component, it means that other components may be further included not excluding the other components unless otherwise stated. Further, throughout this specification, the singular forms include the plural forms unless the context clearly indicates otherwise.

When ranges of numerical values are set forth herein, the values have the precision of significant digits provided according to the standard rules in chemistry for significant digits unless a specific range is stated otherwise. For example, the number includes a range 5.0 to 14.9, and the number 10.0 includes a range 9.50 to 10.49.

### Light-Emitting Down Conversion Organic Nano-Dots

According to one aspect of the present invention, light-emitting down conversion organic nano-dots containing first and second organic phosphors are provided. Here, the first organic phosphor may be a blue or bluish-green phosphor, and the second organic phosphor may be a green or red phosphor.

When a green or red phosphor is used alone as an organic phosphor, photoluminescence quantum yield (PLQY) may be degraded due to a certain level of self-quenching behavior and color conversion efficiency (CCE) may be degraded due to low light absorption in a blue region. However, in the present invention, a blue or bluish-green phosphor and a green or red phosphor are used in combination, and thus excellent PLQY and CCE may be secured at the same time.

A ratio (weight ratio) of the first and second organic phosphors may range from 5.0:5.0 to 9.5:0.5. When the ratio is less than 5:5, it may be difficult to secure desired levels of PLQY and CCE, and excessive absorption of ambient light may cause a decrease in bright-room contrast ratio (CR). Conversely, when the ratio is greater than 9.5:0.5, a blue light reduction rate and a color conversion rate to green or red may be too low.

An average particle size of the light-emitting down conversion organic nano-dots may be 100 to 170 nm, preferably, 110 to 160 nm, and more preferably, 120 to 150 nm.

A standard deviation of the particle sizes of the light-emitting down conversion organic nano-dots may be 500 nm or less, preferably, 450 nm or less, more preferably, 400 nm or less, still more preferably, 350 nm or less, even more preferably, 300 nm or less, and most preferably, 280 nm or less.

A color conversion film using the light-emitting down conversion organic nano-dots having the average particle size and the standard deviation of the particle sizes within the ranges described above has excellent CCE, ultraviolet (UV) stability, room temperature stability, and the like.

### First Organic Phosphor

The first organic phosphor may be a blue or bluish-green phosphor, and various phosphors having a molar extinction coefficient (F) of 10,000 L/mol·cm or more at a wavelength of 450 nm that are already known in the art to which the present invention pertains may be used as the first organic phosphor.

The PLQY of the first organic phosphor may be 50% or more, preferably, 60% or more, and more preferably, 70% or more. When the PLQY is 50% or less, it may be difficult to secure a color conversion rate to a desired level of longer wavelength.

Here, the PLQY of the first organic phosphor is a value measured using an integrating sphere built into JASCO-FP 8500 equipment for a solution in which the first organic phosphor is dissolved in a minimum amount of THF and then dispersed in deionized water.

The first organic phosphor may include, for example, one or more selected from the group consisting of compounds BB-1 to BB-11, BD-1 to BD-9, BM-1 to BM-12, BPer-1 to BPer-20, and BPyr-1 to BPyr-11 below, but the present invention is not limited thereto.

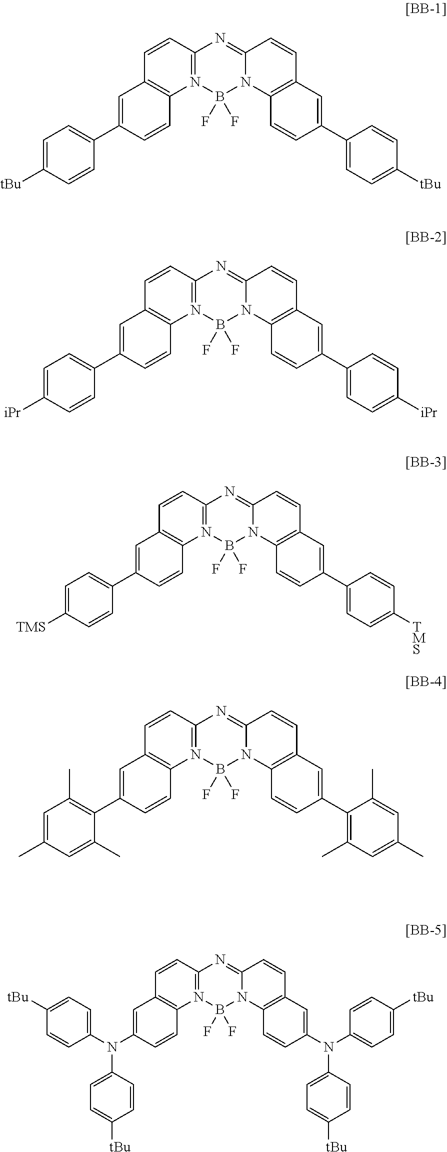

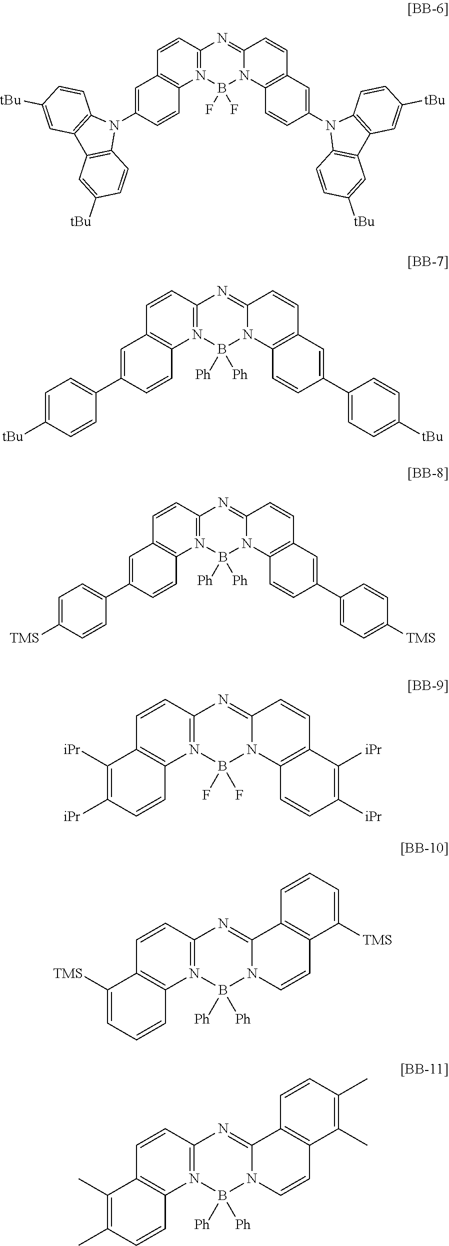

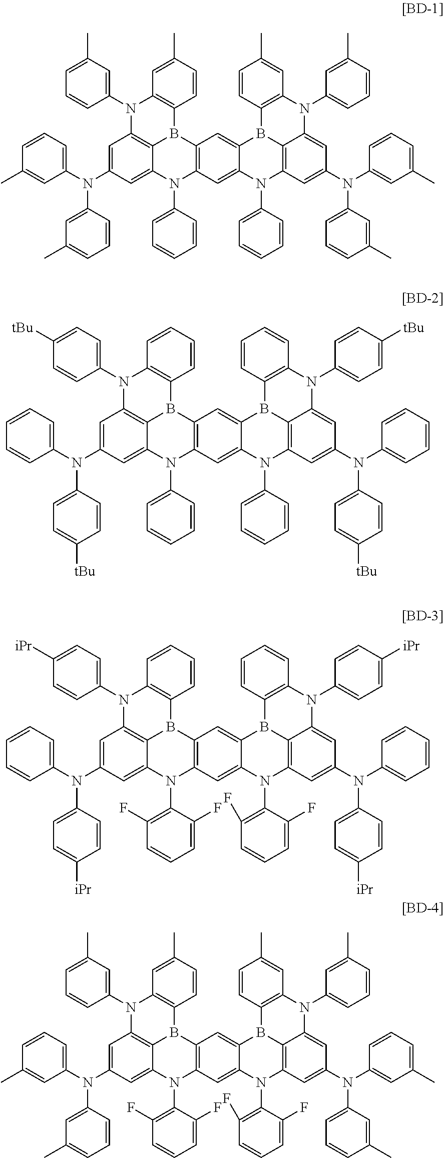

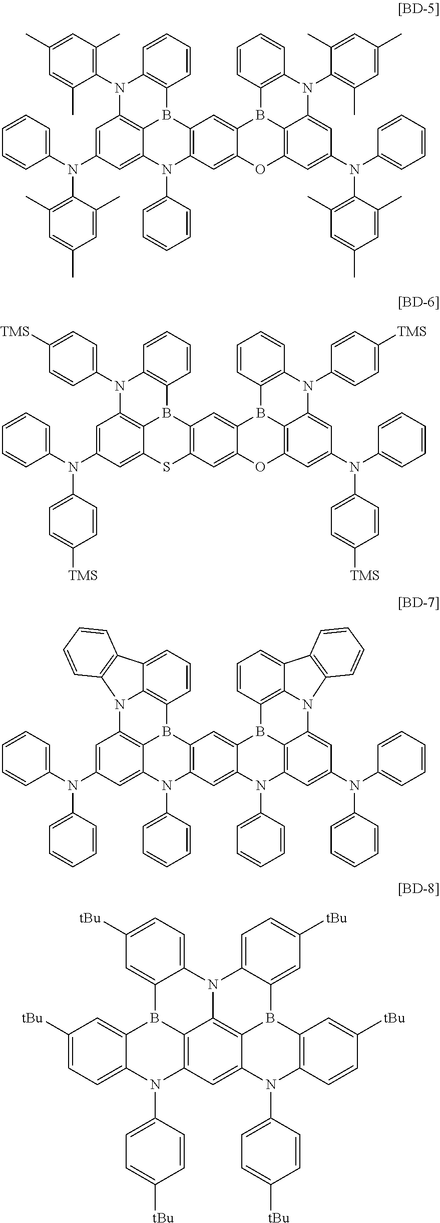

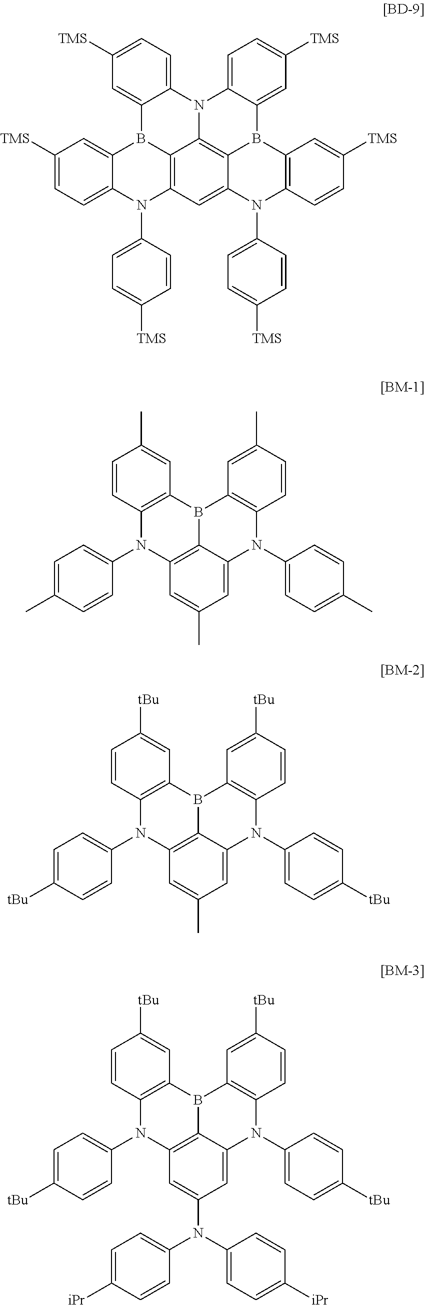

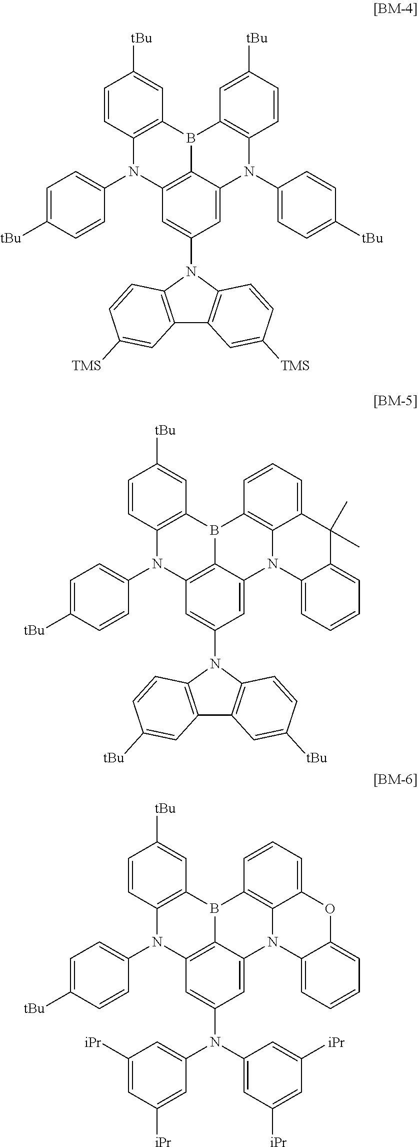 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6ccc([Si](C)(C)C)cc6c6cc([Si](C)(C)C)ccc65)cc2c43)cc1 ; CC(C)(C)c1ccc(N2c3ccc(C(C)(C)C)cc3B3c4cccc5c4N(c4ccccc4C5(C)C)c4cc(-n5c6ccc(C(C)(C)C)cc6c6cc(C(C)(C)C)ccc65)cc2c43)cc1 ; CC(C)c1cc(C(C)C)cc(N(c2cc(C(C)C)cc(C(C)C)c2)c2cc3c4c(c2)N2c5ccccc5Oc5cccc(c52)B4c2cc(C(C)(C)C)ccc2N3c2ccc(C(C)(C)C)cc2)c1]

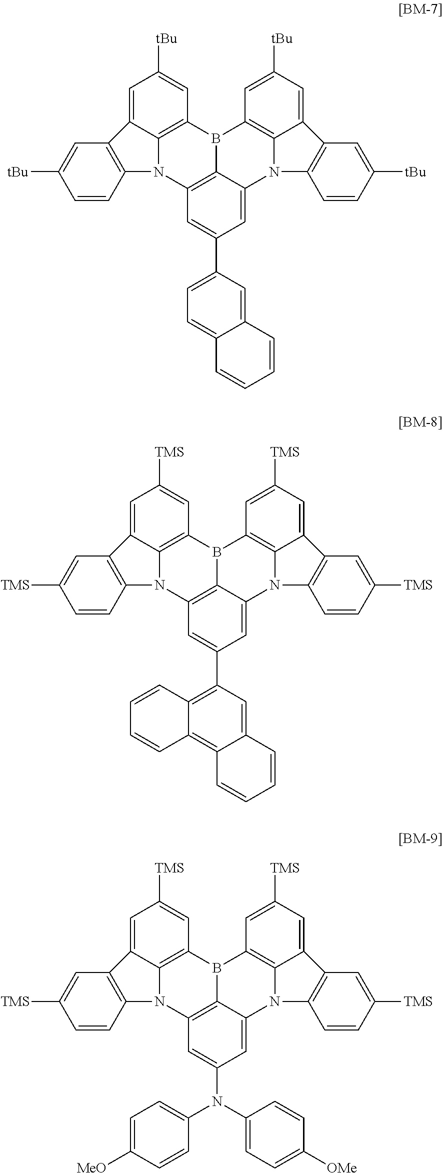 [SMILES: CC(C)(C)c1ccc2c(c1)c1cc(C(C)(C)C)cc3c1n2-c1cc(-c2ccc4ccccc4c2)cc2c1B3c1cc(C(C)(C)C)cc3c4cc(C(C)(C)C)ccc4n-2c13 ; C[Si](C)(C)c1ccc2c(c1)c1cc([Si](C)(C)C)cc3c1n2-c1cc(-c2cc4ccccc4c4ccccc24)cc2c1B3c1cc([Si](C)(C)C)cc3c4cc([Si](C)(C)C)ccc4n-2c13 ; COc1ccc(N(c2ccc(OC)cc2)c2cc3c4c(c2)-n2c5ccc([Si](C)(C)C)cc5c5cc([Si](C)(C)C)cc(c52)B4c2cc([Si](C)(C)C)cc4c5cc([Si](C)(C)C)ccc5n-3c24)cc1]

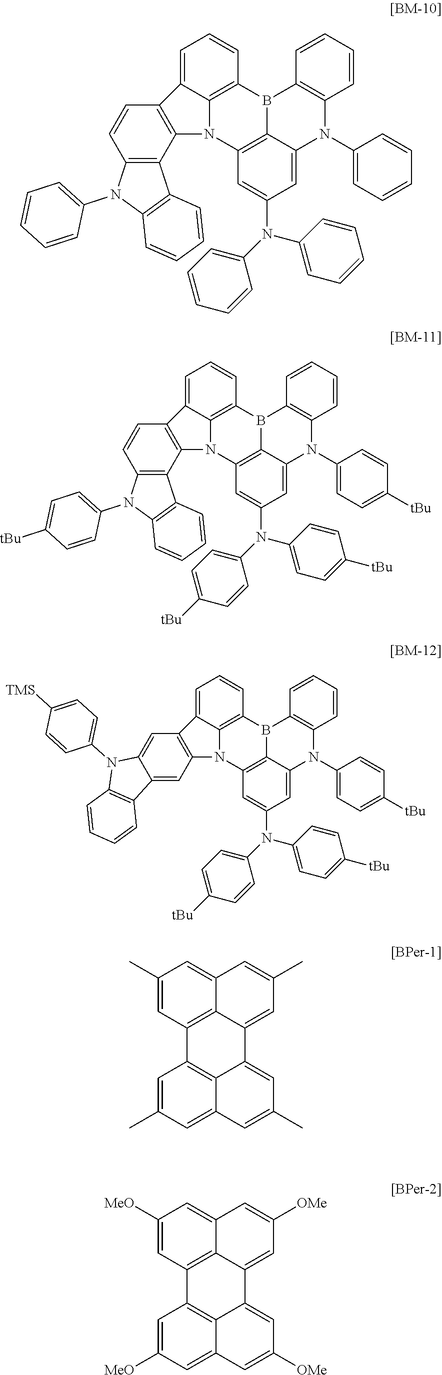

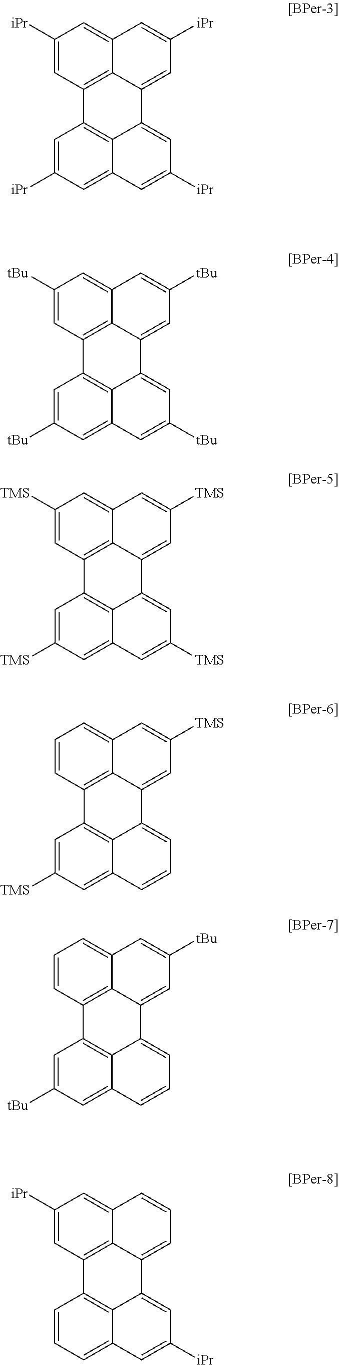

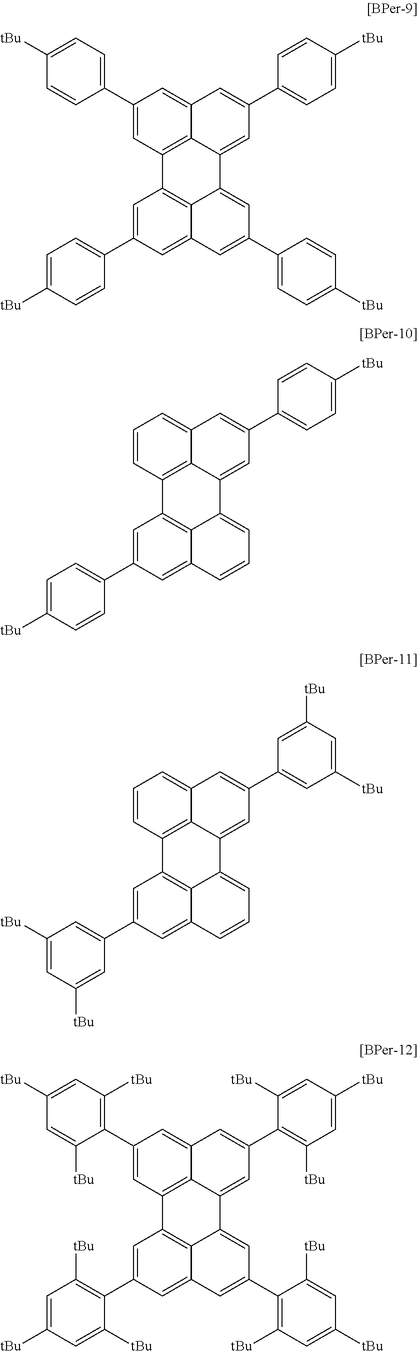

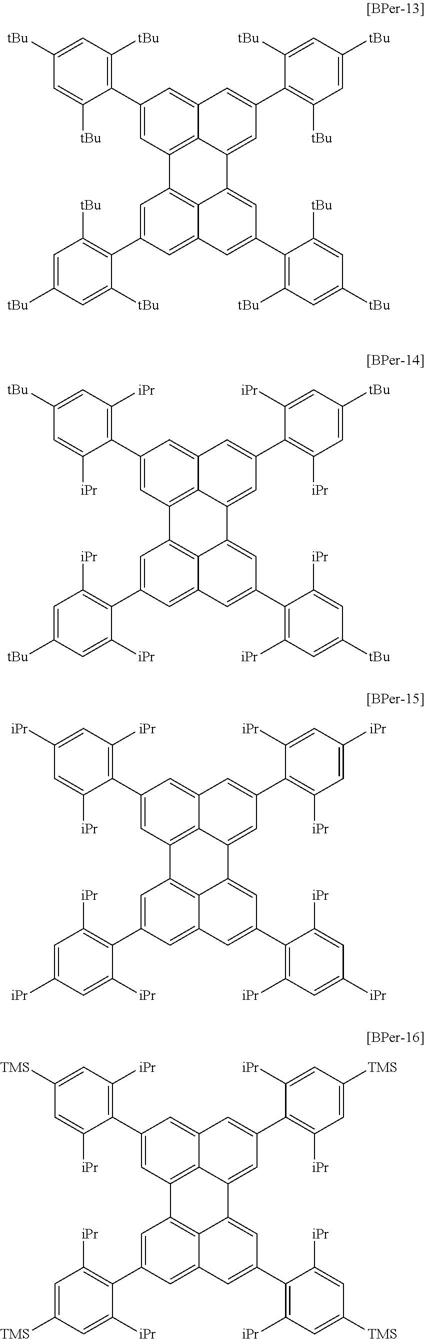

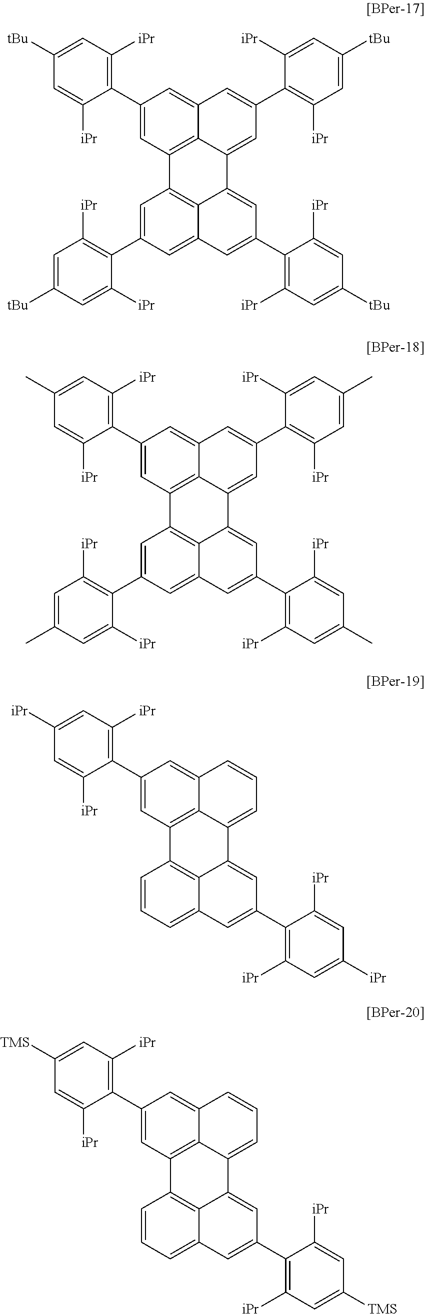

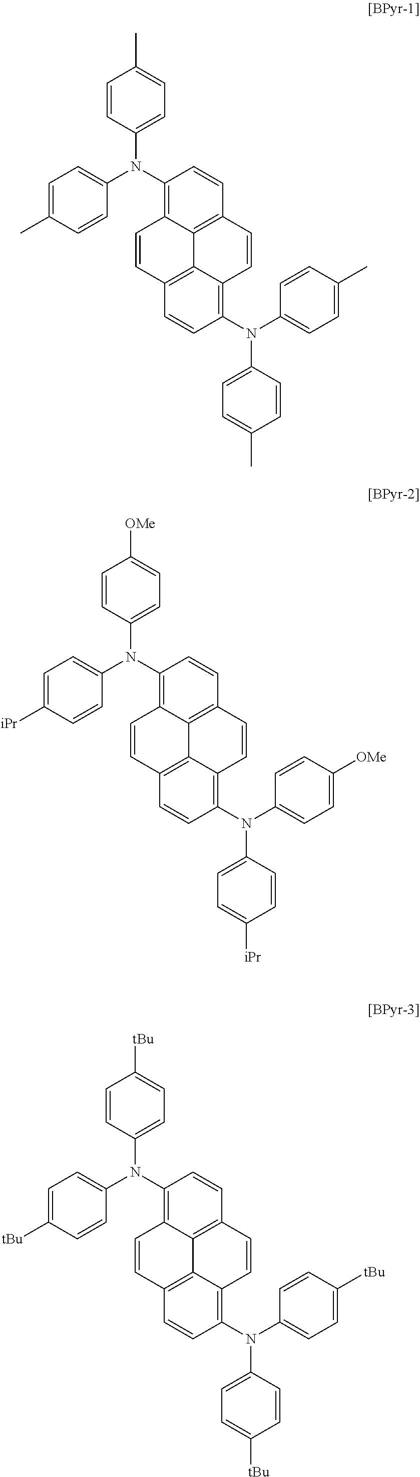

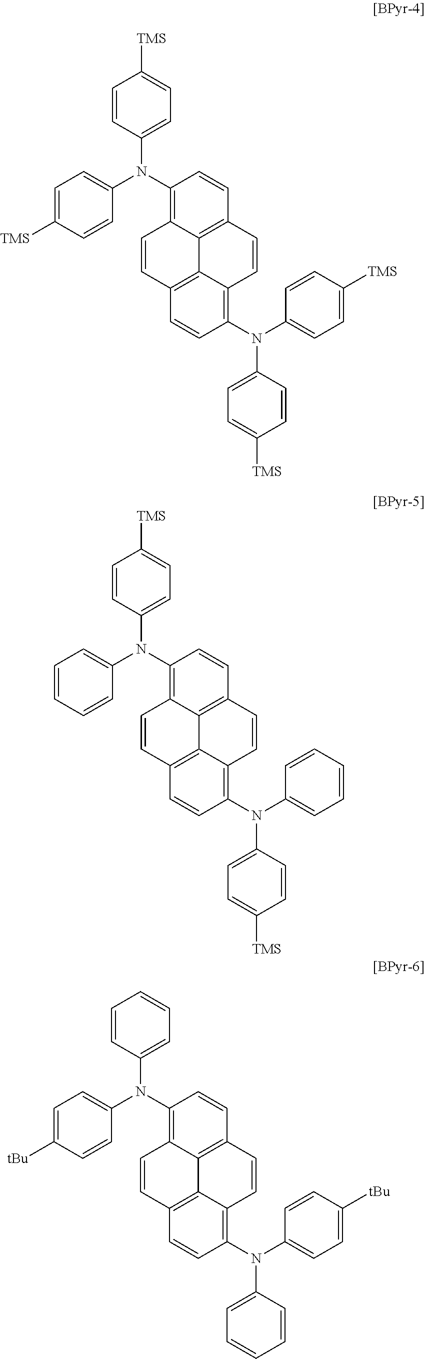 [SMILES: C[Si](C)(C)c1ccc(N(c2ccc([Si](C)(C)C)cc2)c2ccc3ccc4c(N(c5ccc([Si](C)(C)C)cc5)c5ccc([Si](C)(C)C)cc5)ccc5ccc2c3c54)cc1 ; C[Si](C)(C)c1ccc(N(c2ccccc2)c2ccc3ccc4c(N(c5ccccc5)c5ccc([Si](C)(C)C)cc5)ccc5ccc2c3c54)cc1 ; CC(C)(C)c1ccc(N(c2ccccc2)c2ccc3ccc4c(N(c5ccccc5)c5ccc(C(C)(C)C)cc5)ccc5ccc2c3c54)cc1]

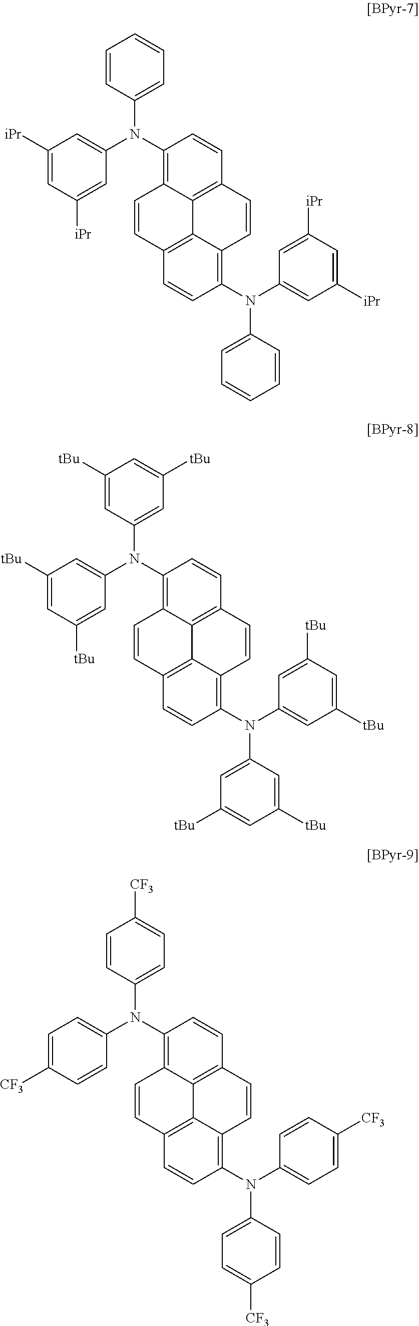 [SMILES: CC(C)c1cc(C(C)C)cc(N(c2ccccc2)c2ccc3ccc4c(N(c5ccccc5)c5cc(C(C)C)cc(C(C)C)c5)ccc5ccc2c3c54)c1 ; CC(C)(C)c1cc(N(c2cc(C(C)(C)C)cc(C(C)(C)C)c2)c2ccc3ccc4c(N(c5cc(C(C)(C)C)cc(C(C)(C)C)c5)c5cc(C(C)(C)C)cc(C(C)(C)C)c5)ccc5ccc2c3c54)cc(C(C)(C)C)c1 ; FC(F)(F)c1ccc(N(c2ccc(C(F)(F)F)cc2)c2ccc3ccc4c(N(c5ccc(C(F)(F)F)cc5)c5ccc(C(F)(F)F)cc5)ccc5ccc2c3c54)cc1]

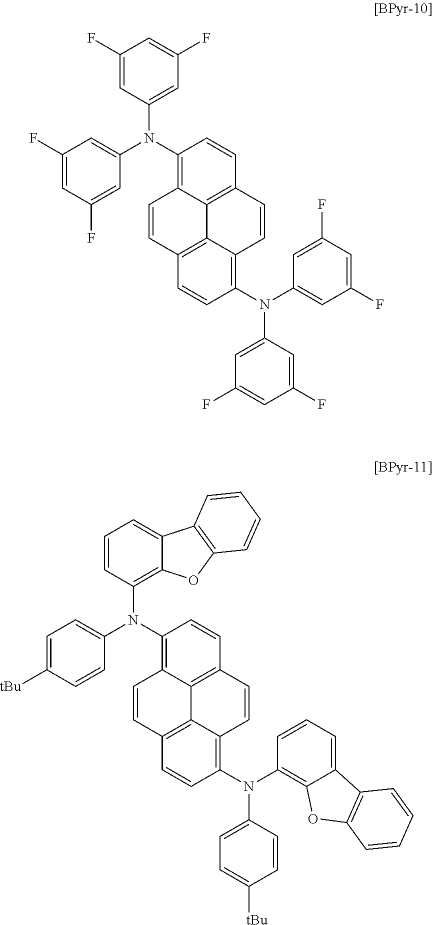 [SMILES: Fc1cc(F)cc(N(c2cc(F)cc(F)c2)c2ccc3ccc4c(N(c5cc(F)cc(F)c5)c5cc(F)cc(F)c5)ccc5ccc2c3c54)c1 ; CC(C)(C)c1ccc(N(c2ccc3ccc4c(N(c5ccc(C(C)(C)C)cc5)c5cccc6c5oc5ccccc56)ccc5ccc2c3c54)c2cccc3c2oc2ccccc23)cc1]

### Second Organic Phosphor

The second organic phosphor may be a green or red phosphor, and various phosphors that are already known in the art to which the present invention pertains, in which an emission spectrum of the first organic phosphor overlaps an absorption spectrum of the second organic phosphor, may be used as the second organic phosphor.

A Förster radius (R_{O}) between the first and second organic phosphors may be 7.0 nm or less, preferably, 6.0 nm or less, more preferably, 5.0 nm or less, and still more preferably, 4.5 nm or less. When the Forster radius is excessively large, energy transfer between the first and second organic phosphors may be significantly degraded.

The Förster radius is a maximum distance at which energy transfer can occur between the first and second organic phosphors, and is defined by Equation 1 below.

$${R}_{0}^{6} = \frac{20.7}{128 {π}^{5} {N}_{A}} \frac{{κ}^{2} {Q}_{D}}{{n}^{4}} J \qquad [ Equation 1 ]$$

(In Equation 1 above, NA denotes Avogadro's constant, κ² denotes a dipole orientation factor, Q_{D} denotes the PLQY of the first organic phosphor, n denotes a refractive index of a medium, J denotes a spectral overlap integral defined by Equation 2 below, and the difference of κ² and n values depending on organic materials are small and can be ignored.)

$$J = \frac{\int {f}_{D} ( λ ) {ϵ}_{A} ( λ ) {λ}^{4} d λ}{\int {f}_{D} ( λ ) d λ} = \int \overline{{f}_{D}} ( λ ) {ϵ}_{A} ( λ ) {λ}^{4} d λ \qquad [ Equation 2 ]$$

(In Equation 2 above, λ denotes a wavelength, f_{D}(λ) denotes the normalized emission intensity of the emission spectrum of the first organic phosphor, and ε_{A} denotes a molar extinction coefficient of the second organic phosphor.)

Meanwhile, the Forster radius may also be obtained by Forster resonance energy transfer (FRET) efficiency E defined by Equation 3 below.

$$E = \frac{1}{1 + {( r / {R}_{0} )}^{6}} \qquad [ Equation 3 ]$$

(In Equation 3 above, r denotes a distance between the first and second organic phosphors.)

In the case of applying the light-emitting down conversion organic nano-dots to the use of a light-emitting diode (LED), since the light-emitting down conversion organic nano-dots should have a wide full width at half maximum (FWHM), it is preferable to use a delayed fluorescence material as the second organic phosphor.

The delayed fluorescence material is a material capable of increasing internal quantum efficiency, and it is preferable to use a thermally activated delayed fluorescence (TADF) material, which is a material that emits fluorescence by moving particles of three triplet excitons, which are particles that are annihilated by heat or vibration, to a level of a singlet exciton using heat.

The delayed fluorescence material having such properties is not particularly limited, and for example, a compound represented by Chemical Formula 1 below may be used.

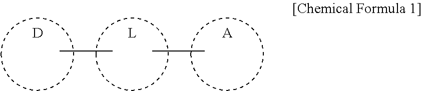

(In Chemical Formula 1 above, L is any one selected from the group consisting of an aryl group, an arylene group, and a carbon-nitrogen single bond, when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms, when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group, when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms).

The compound represented by Chemical Formula 1 above may be represented by, e.g., one of Chemical Formula 1A to Chemical Formula 1D below:

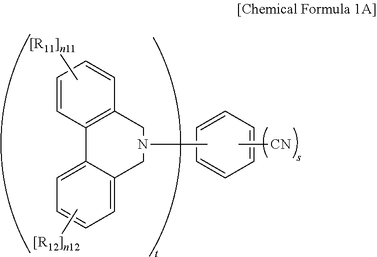

(in Chemical Formula 1A, R₁₁ and R₁₂ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, s is an integer of 1 or 2, t is an integer of 4 or 5, n11 and n12 are each independently an integer of 1 to 4, and if n11 and n12 are 2 or more, the structures in the brackets, are the same or different, respectively, R₁₁ and R₁₂ may bond to adjacent substituents to form a substituted or unsubstituted ring).

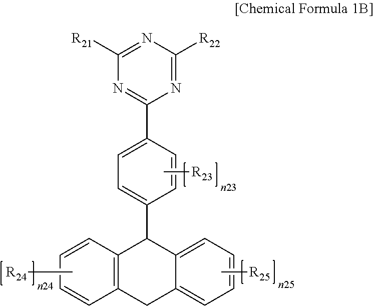

(in Chemical Formula 1B, X is a single bond, CR₂₆R₂₇, NR₂₈, O or S, R₂₁ to R₂₈ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, n23 to n25 are each independently an integer of 1 to 4, if n23 to n25 are 2 or more, the structures in the brackets, are the same or different, respectively, and R₂₃ to R₂₈ may bond to adjacent substituents to form a substituted or unsubstituted ring).

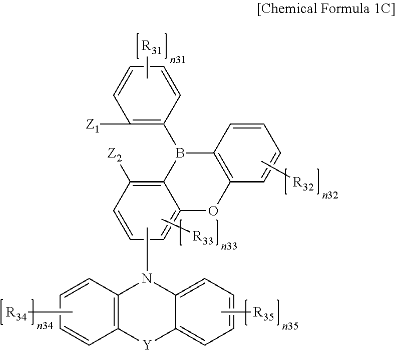

(in Chemical Formula 1C, Y is a single bond, CR₃₆R₃₇, NR₃₈, O or S, R₃₁ to R₃₈ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, Z₁ and Z₂ each independently correspond to at least one selected from the group consisting of hydrogen, a hydroxyl group, and a substituted or unsubstituted alkyl group, or are combined with each other to form a ring, n31, n32, n34 and n35 are each independently an integer of 1 to 4, n33 is an integer of 1 to 2, if n31 to n35 are 2 or more, the structures in the brackets, are the same or different, respectively, and R₃₁ to R₃₈ may bond to adjacent substituents to form a substituted or unsubstituted ring).

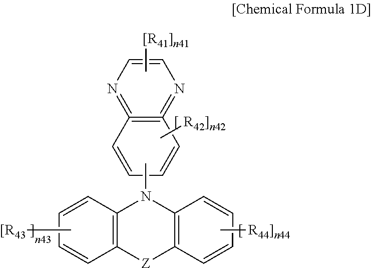

(in Chemical Formula 1D, Z is a single bond, CR₄₅R₄₆, NR₄₇, O or S, R₄₁ to R₄₇ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, n41 is an integer of 1 to 2, n42 is an integer of 1 to 3, n43 and n44 are each independently an integer of 1 to 4, if n41 to n44 are 2 or more, the structures in the brackets, are the same or different, respectively, and R₄₁ to R₄₇ may bond to adjacent substituents to form a substituted or unsubstituted ring).

The compound represented by Chemical Formula 1 above may be, for example, one or more selected from the group consisting of compounds T-1 to T-28 below, but the present invention is not limited thereto.

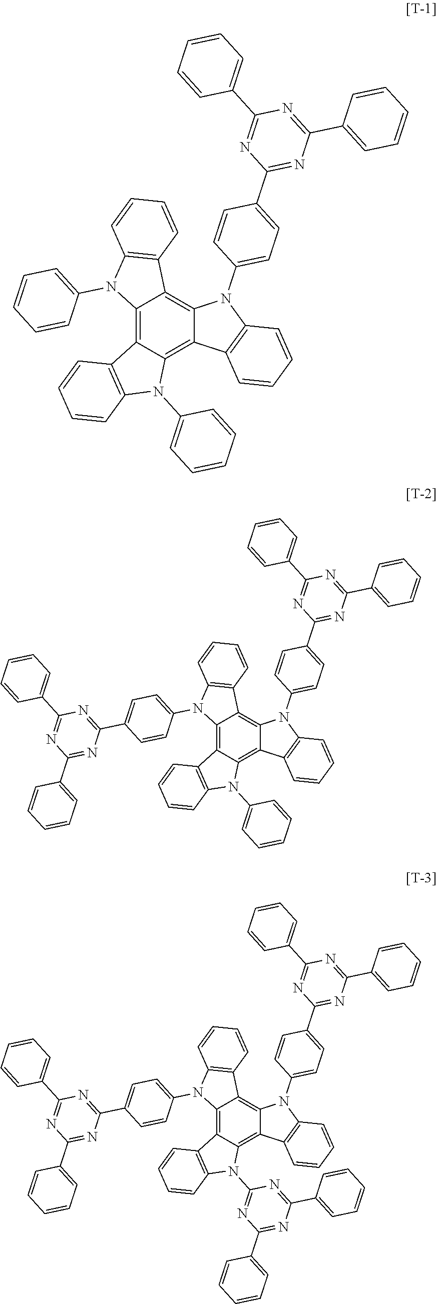 [SMILES: c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1 ; c1ccc(-c2nc(-c3ccccc3)nc(-c3ccc(-n4c5ccccc5c5c6c(c7ccccc7n6-c6ccccc6)c6c(c7ccccc7n6-c6ccc(-c7nc(-c8ccccc8)nc(-c8ccccc8)n7)cc6)c54)cc3)n2)cc1 ; c1ccc(-c2nc(-c3ccccc3)nc(-c3ccc(-n4c5ccccc5c5c4c4c6ccccc6n(-c6nc(-c7ccccc7)nc(-c7ccccc7)n6)c4c4c6ccccc6n(-c6ccc(-c7nc(-c8ccccc8)nc(-c8ccccc8)n7)cc6)c54)cc3)n2)cc1]

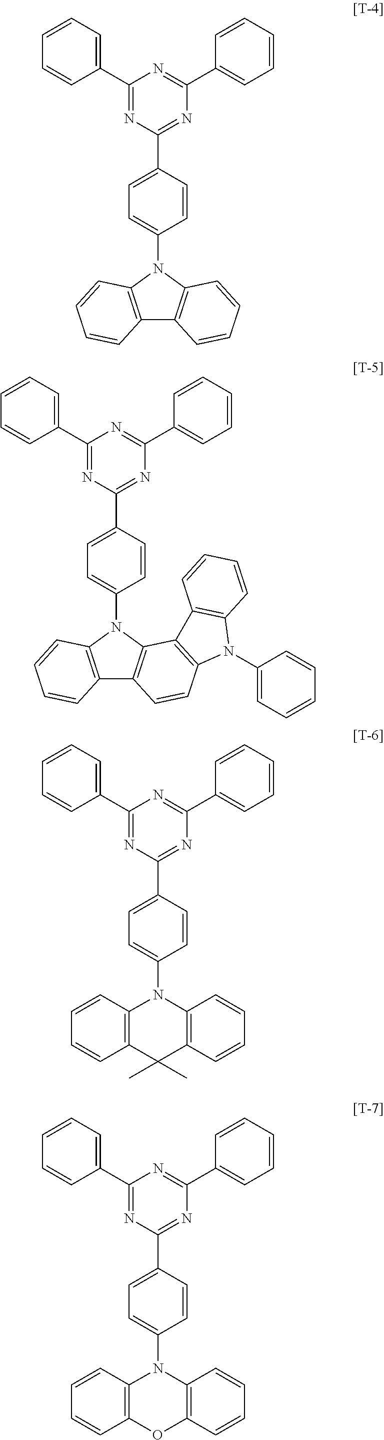

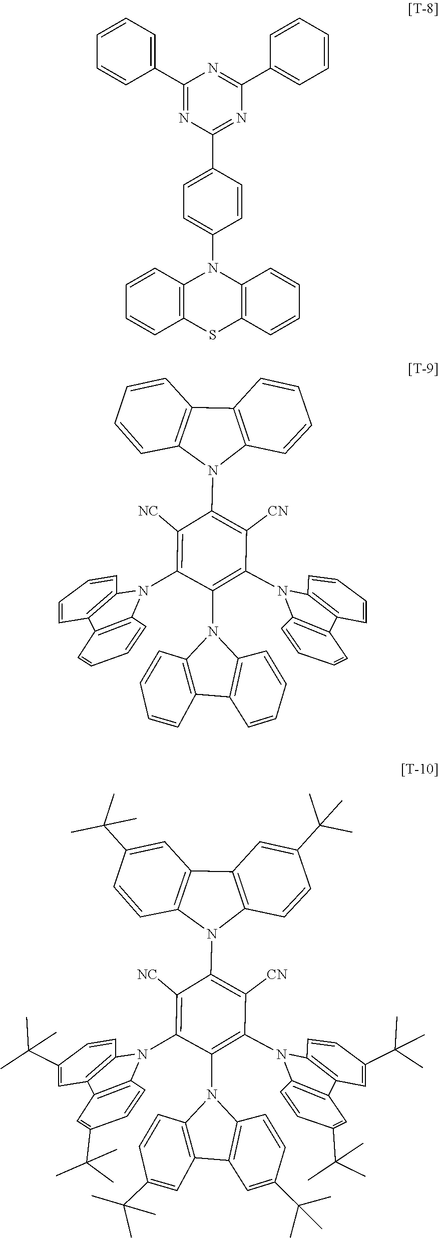

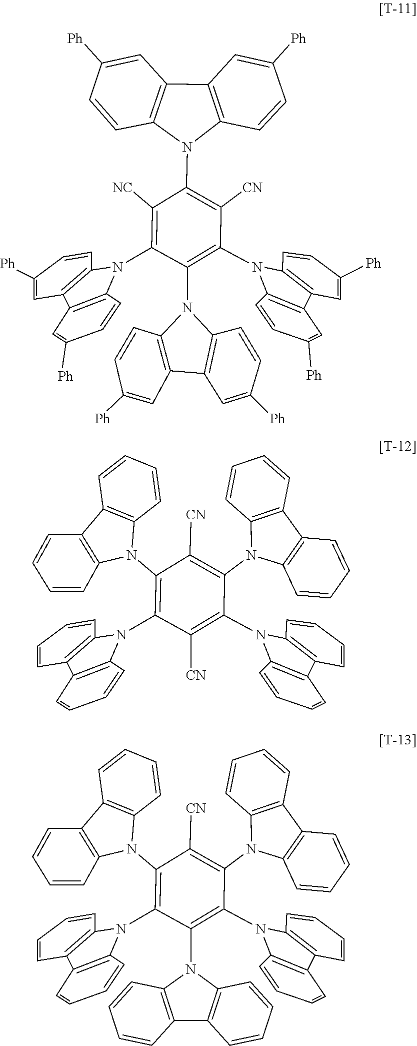

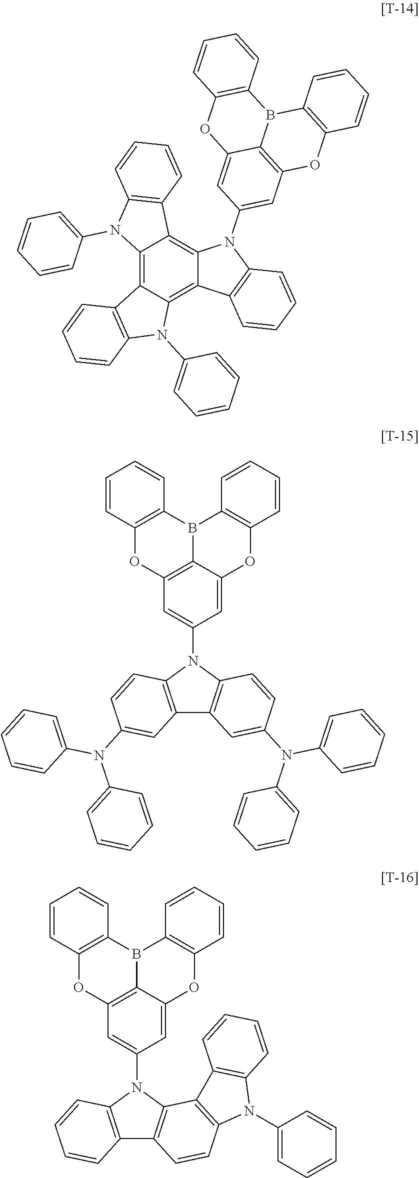 [SMILES: c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1 ; c1ccc(N(c2ccccc2)c2ccc3c(c2)c2cc(N(c4ccccc4)c4ccccc4)ccc2n3-c2cc3c4c(c2)Oc2ccccc2B4c2ccccc2O3)cc1 ; c1ccc(-n2c3ccccc3c3c2ccc2c4ccccc4n(-c4cc5c6c(c4)Oc4ccccc4B6c4ccccc4O5)c23)cc1]

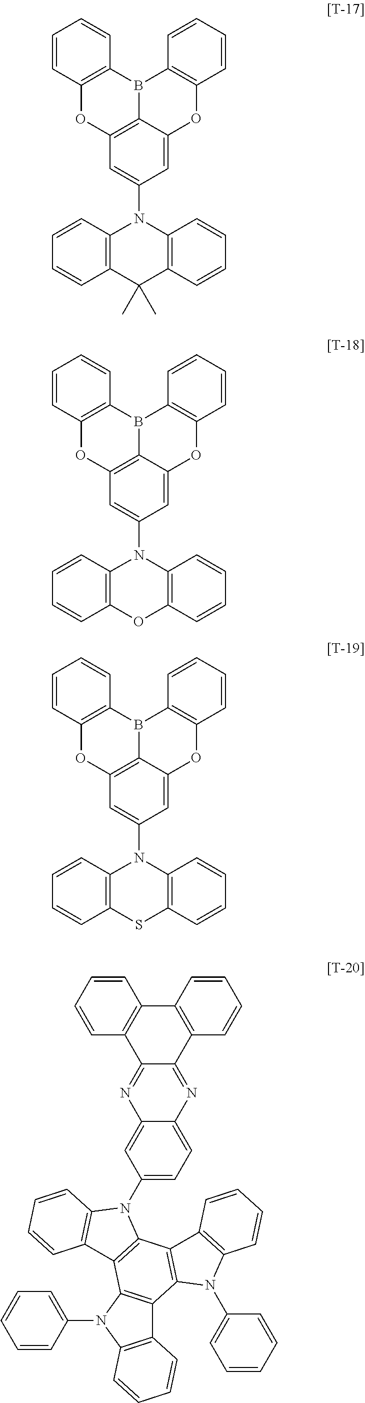

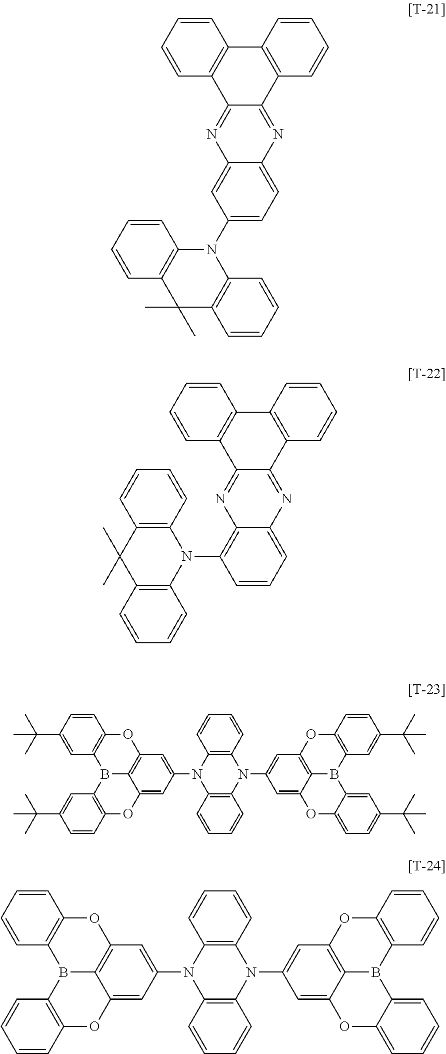 [SMILES: CC1(C)c2ccccc2N(c2ccc3nc4c5ccccc5c5ccccc5c4nc3c2)c2ccccc21 ; CC1(C)c2ccccc2N(c2cccc3nc4c5ccccc5c5ccccc5c4nc23)c2ccccc21 ; CC(C)(C)c1ccc2c(c1)B1c3cc(C(C)(C)C)ccc3Oc3cc(N4c5ccccc5N(c5cc6c7c(c5)Oc5ccc(C(C)(C)C)cc5B7c5cc(C(C)(C)C)ccc5O6)c5ccccc54)cc(c31)O2 ; c1ccc2c(c1)Oc1cc(N3c4ccccc4N(c4cc5c6c(c4)Oc4ccccc4B6c4ccccc4O5)c4ccccc43)cc3c1B2c1ccccc1O3]

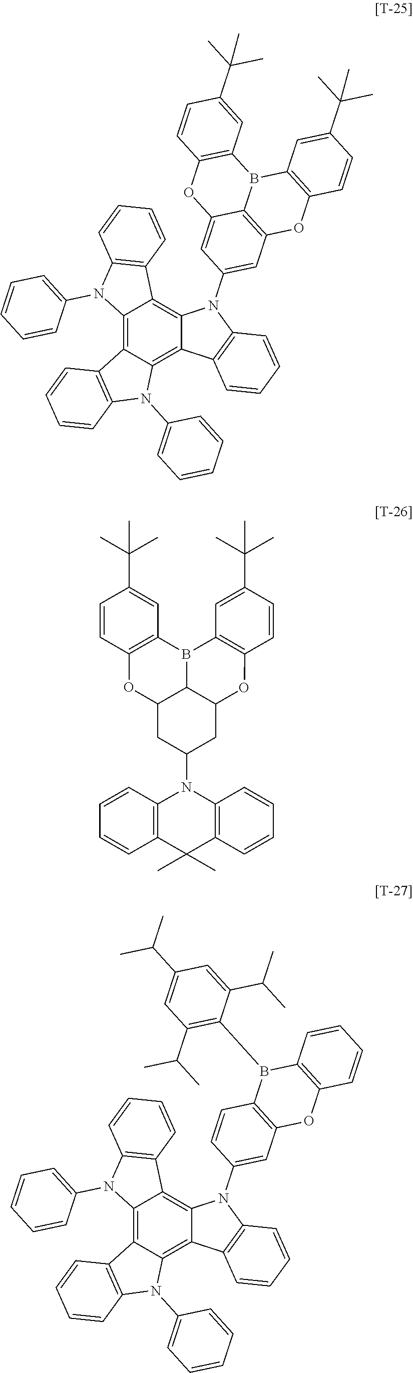

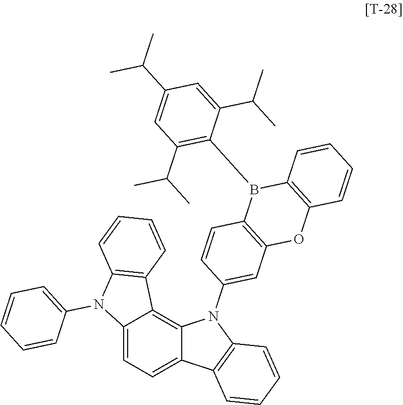 [SMILES: CC(C)c1cc(C(C)C)c(CB2c3ccccc3Oc3cc(-n4c5ccccc5c5ccc6c(c7ccccc7n6-c6ccccc6)c54)ccc32)c(C(C)C)c1]

In the case of applying the light-emitting down conversion organic nano-dots to the use of a display, the light-emitting down conversion organic nano-dots should have high color purity, and thus it is preferable to use a boron compound having a narrow FWHM as the second organic phosphor.

A boron compound suitable for use in a display is not particularly limited, and may be, for example, a boron compound represented by Chemical Formula 2 below.

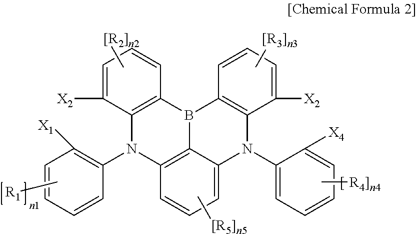

(In Chemical Formula 2 above, R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, X₁ to X₄ are each independently hydrogen, hydroxyl group or a substituted or unsubstituted alkyl group, n1 and n4 are each independently an integer of 1 to 4, n2, n3 and n5 are each independently an integer of 1 to 3, if n1 to n5 are 2 or more, the structures in the brackets, are the same or different, respectively, and R₁ to R₅ and X₁ to X₄ may bond to adjacent substituents to form a substituted or unsubstituted ring).

The boron compound represented by Chemical Formula 2 above may be, for example, one or more selected from the group consisting of compounds D-1 to D-30 below, but the present invention is not limited thereto.

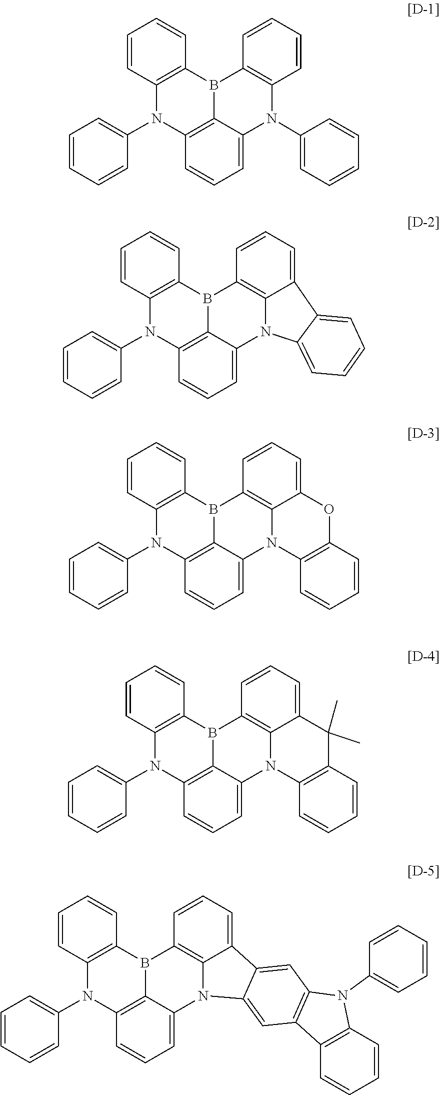 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4c2cccc4-n2c4cc5c6ccccc6n(-c6ccccc6)c5cc4c4cccc3c42)cc1]

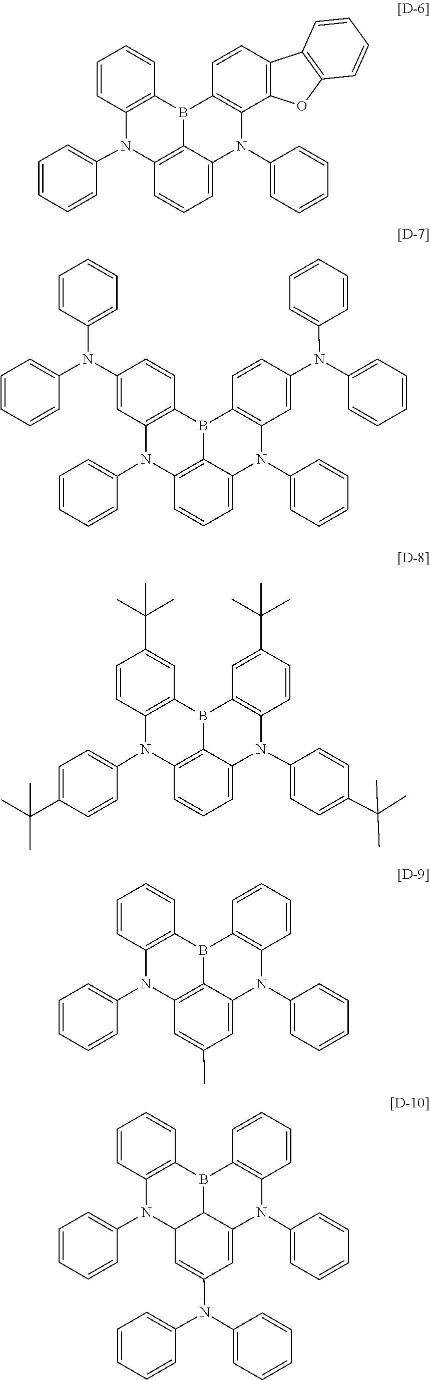 [SMILES: c1ccc(N2c3ccccc3B3c4ccc5c(oc6ccccc65)c4N(c4ccccc4)c4cccc2c43)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1cc2c3c(c1)N(c1ccccc1)c1ccccc1B3c1ccccc1N2c1ccccc1 ; C1=C(N(c2ccccc2)c2ccccc2)C=C2C3B(c4ccccc4N2c2ccccc2)c2ccccc2N(c2ccccc2)C13]

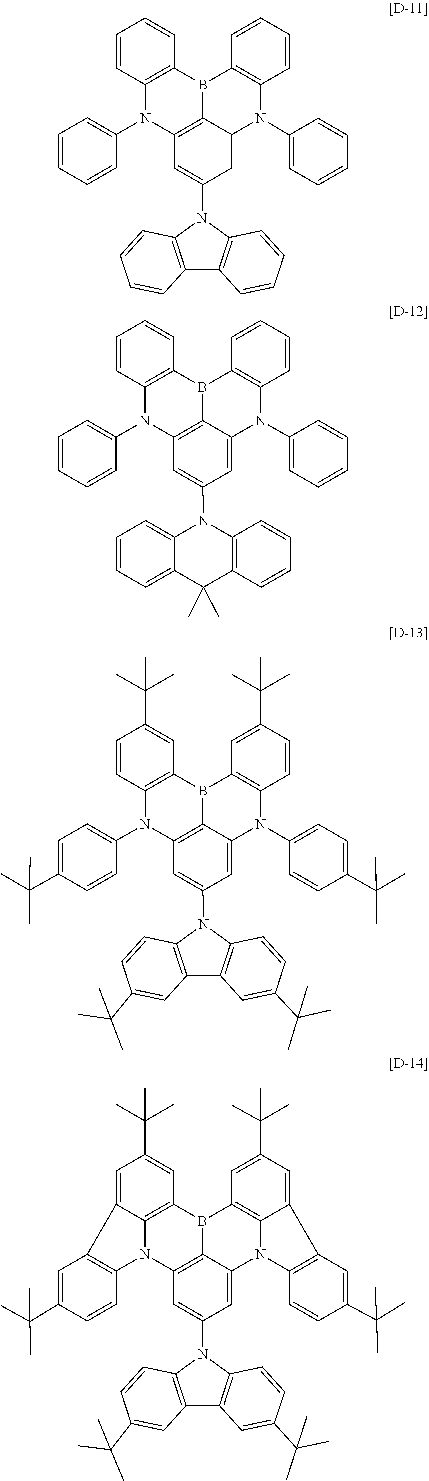

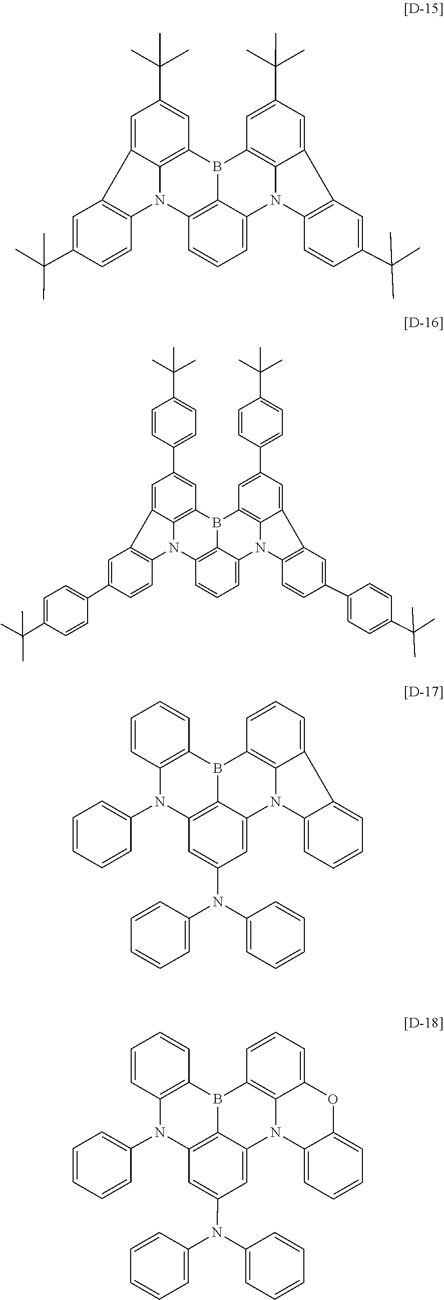

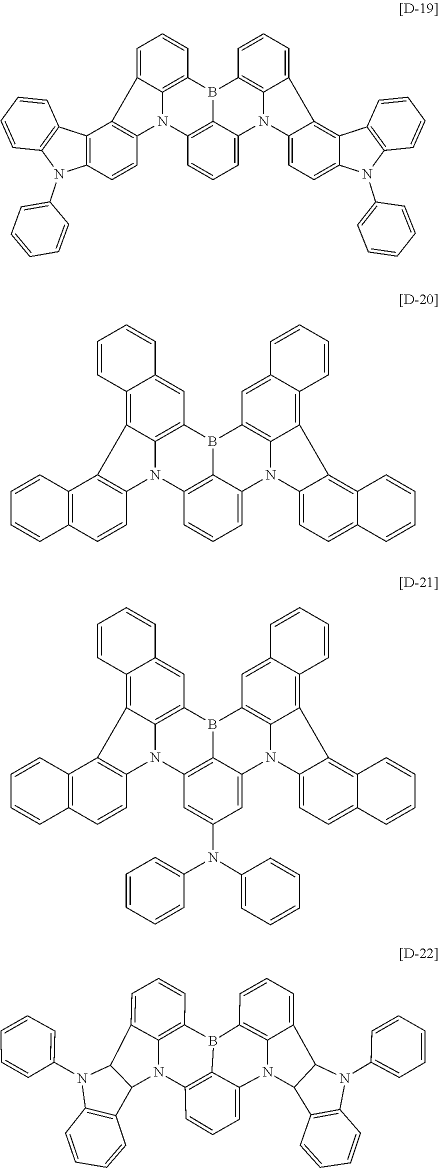 [SMILES: c1ccc(-n2c3ccccc3c3c4c5cccc6c5n(c4ccc32)-c2cccc3c2B6c2cccc4c5c6c7ccccc7n(-c7ccccc7)c6ccc5n-3c24)cc1 ; c1cc2c3c(c1)-n1c4ccc5ccccc5c4c4c5ccccc5cc(c41)B3c1cc3ccccc3c3c4c5ccccc5ccc4n-2c13 ; c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1 ; c1ccc(N2c3ccccc3C3C2c2cccc4c2N3c2cccc3c2B4c2cccc4c2N3C2c3ccccc3N(c3ccccc3)C42)cc1]

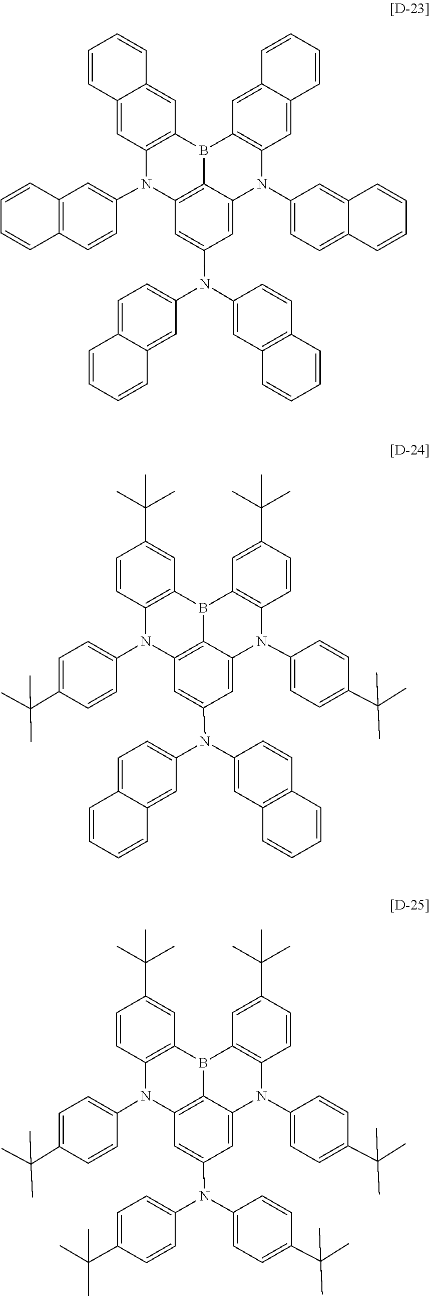

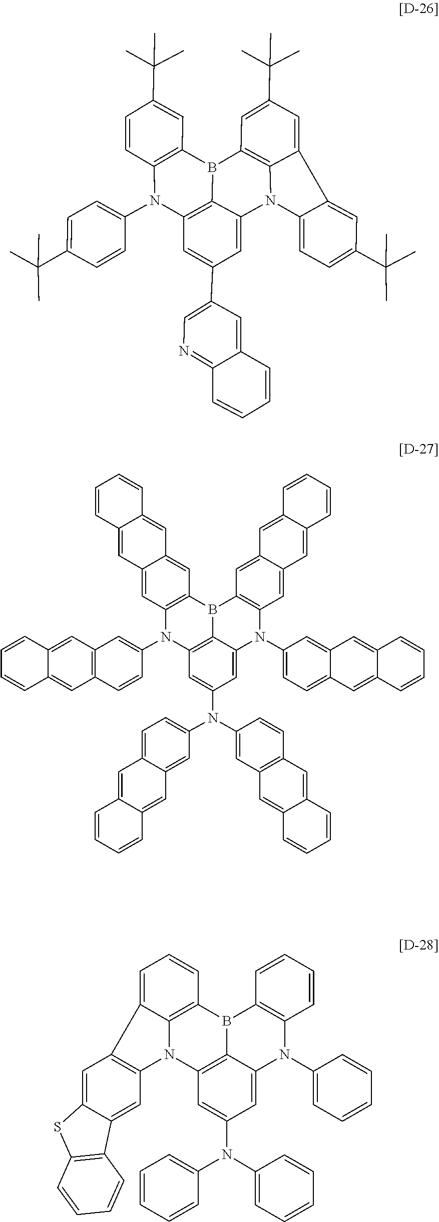 [SMILES: CC(C)(C)c1ccc(N2c3ccc(C(C)(C)C)cc3B3c4c2cc(-c2cnc5ccccc5c2)cc4-n2c4ccc(C(C)(C)C)cc4c4cc(C(C)(C)C)cc3c42)cc1 ; c1ccc2cc3cc(N(c4cc5c6c(c4)N(c4ccc7cc8ccccc8cc7c4)c4cc7cc8ccccc8cc7cc4B6c4cc6cc7ccccc7cc6cc4N5c4ccc5cc6ccccc6cc5c4)c4ccc5cc6ccccc6cc5c4)ccc3cc2c1 ; c1ccc(N(c2ccccc2)c2cc3c4c(c2)-n2c5cc6c(cc5c5cccc(c52)B4c2ccccc2N3c2ccccc2)sc2ccccc26)cc1]

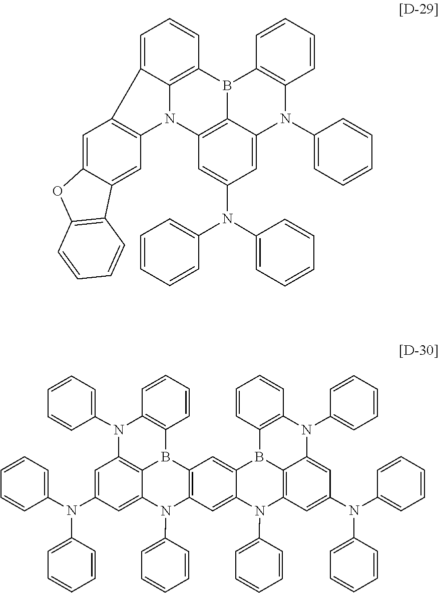 [SMILES: c1ccc(N(c2ccccc2)c2cc3c4c(c2)-n2c5cc6c(cc5c5cccc(c52)B4c2ccccc2N3c2ccccc2)oc2ccccc26)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

Further, a boron compound suitable for use in a display may be, for example, a boron compound represented by Chemical Formula 3 below.

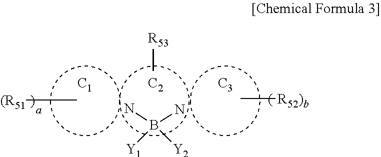

(In Chemical Formula 3 above, C₁ to C₃ each have a five-membered or six-membered ring structure, R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group, Y₁ and Y₂ are each independently a fluorine group or an alkoxy group, a and b are each independently an integer of 1 to 4, if a and b are 2 or more, the structures in the brackets, are the same or different, respectively, R₅₁ and R₅₂ may bond to adjacent substituents to form a substituted or unsubstituted ring).

The boron compound represented by Chemical Formula 3 above may be represented by, e.g., Chemical Formula 3A below:

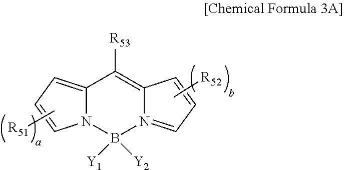

(in Chemical Formula 3A, R₅₁ to R₅₃, Y₁ and Y₂ may be defined the same as those described above, a and b are each independently an integer of 1 to 3).

The boron compound represented by Chemical Formula 3 above may be, for example, one or more selected from the group consisting of compounds B-1 to B-51 below, but the present invention is not limited thereto.

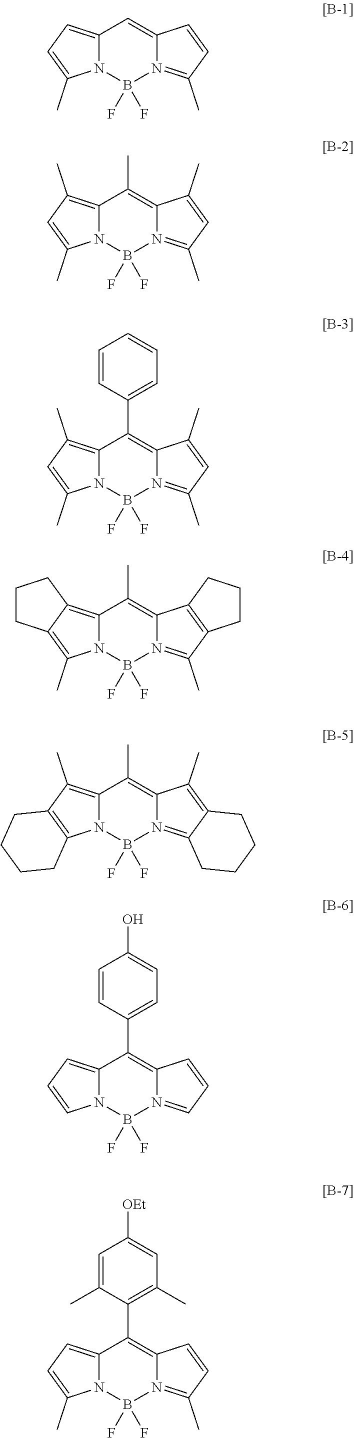

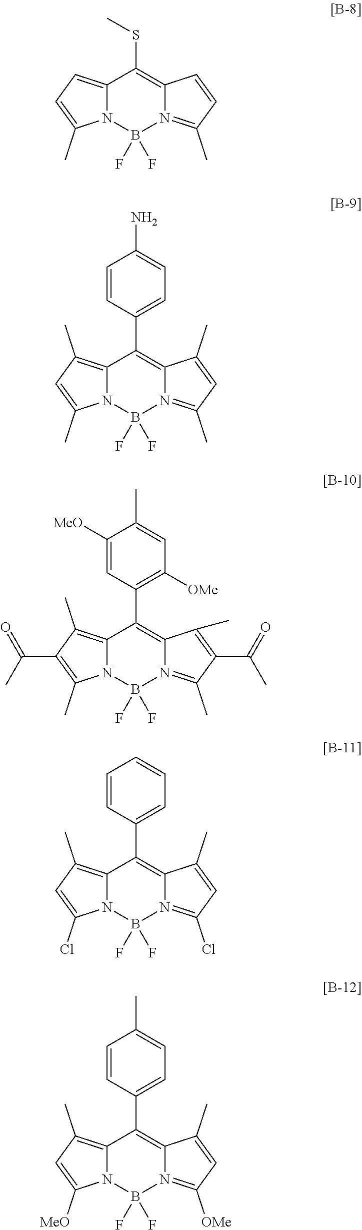

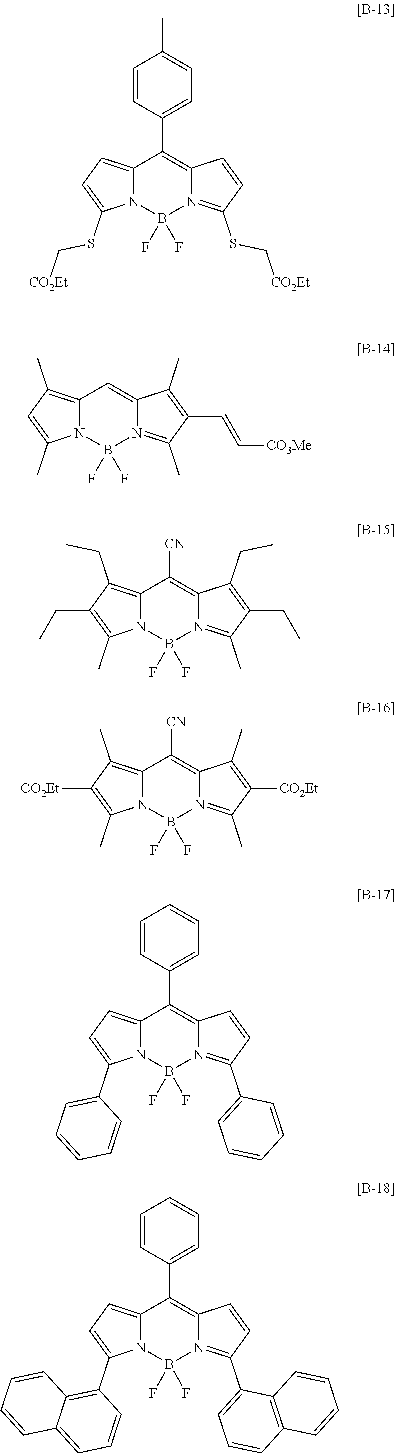

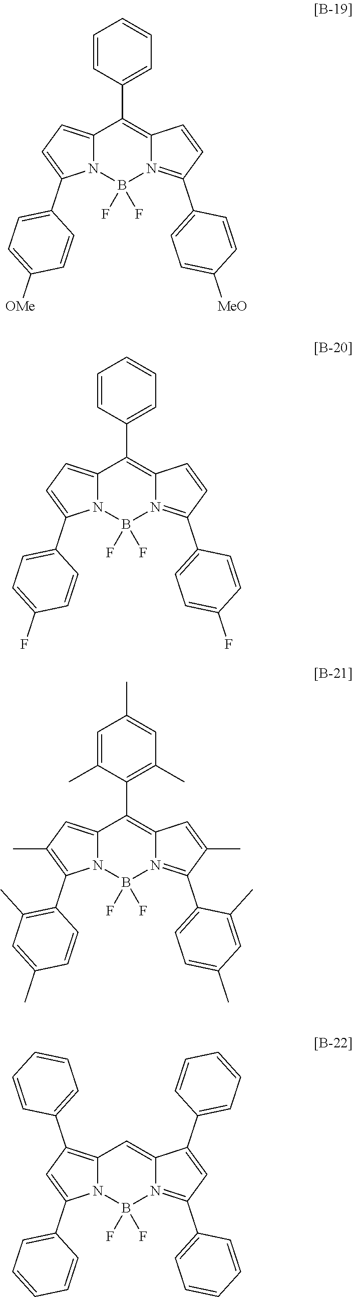

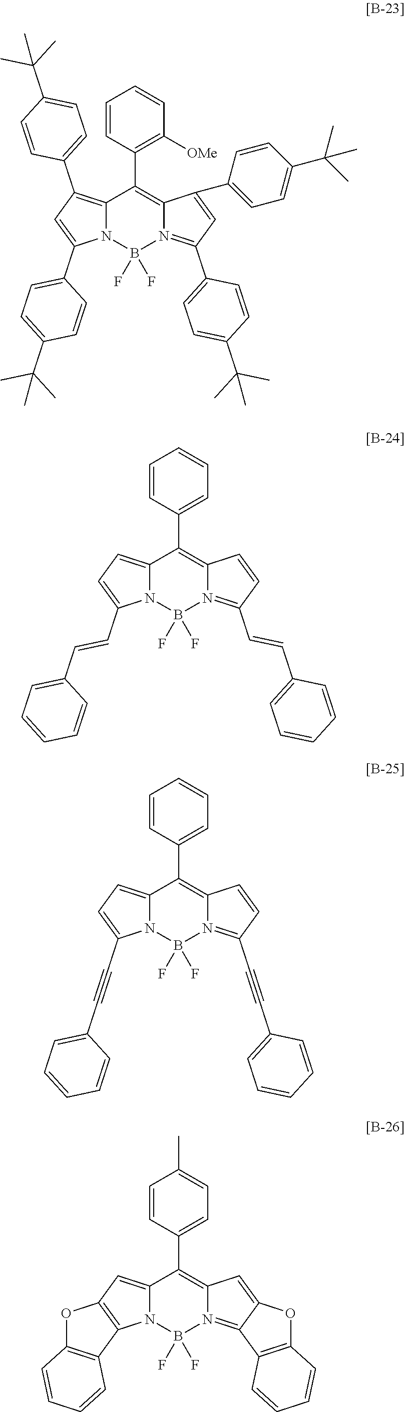

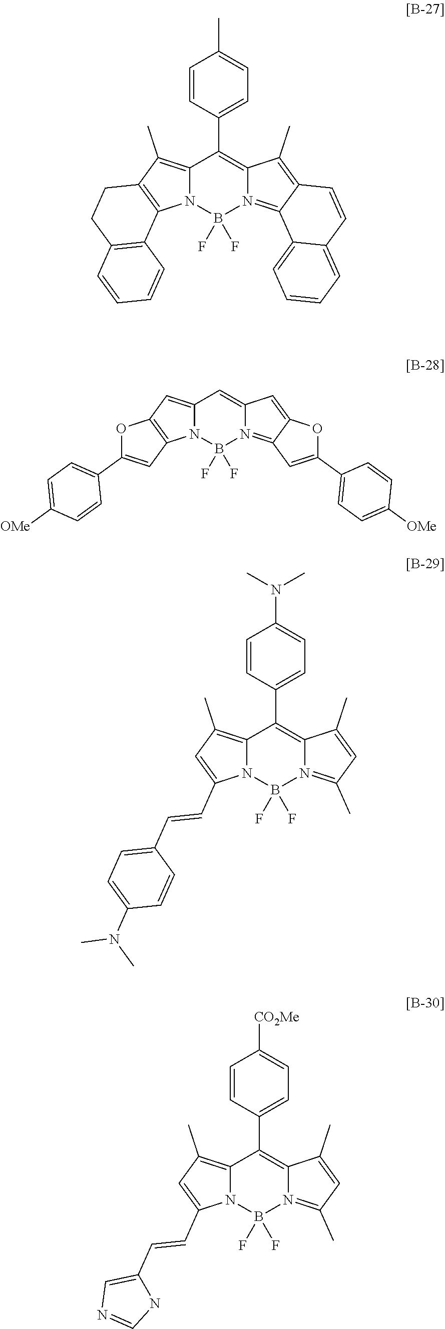

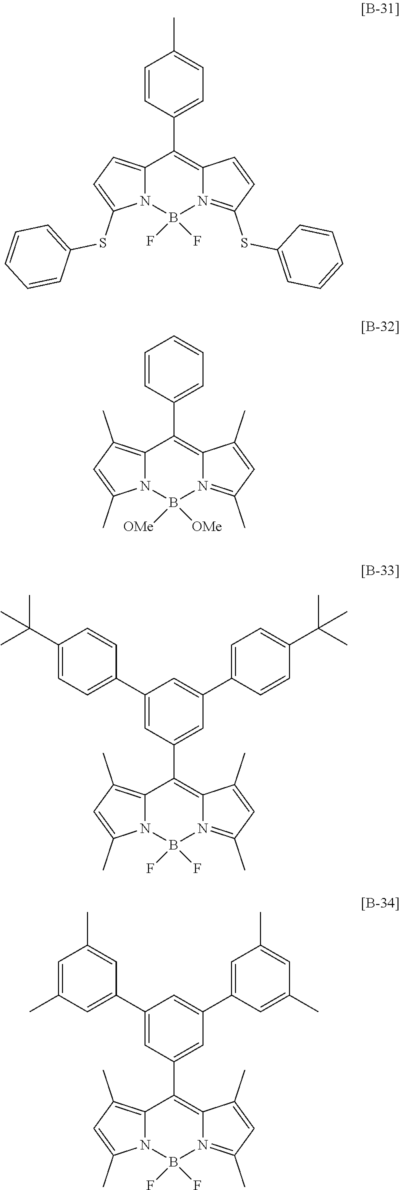

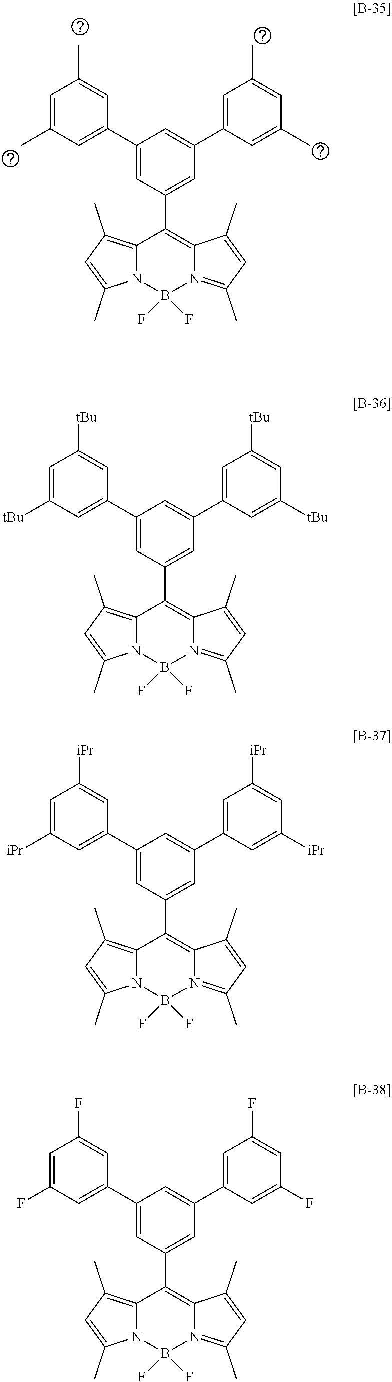

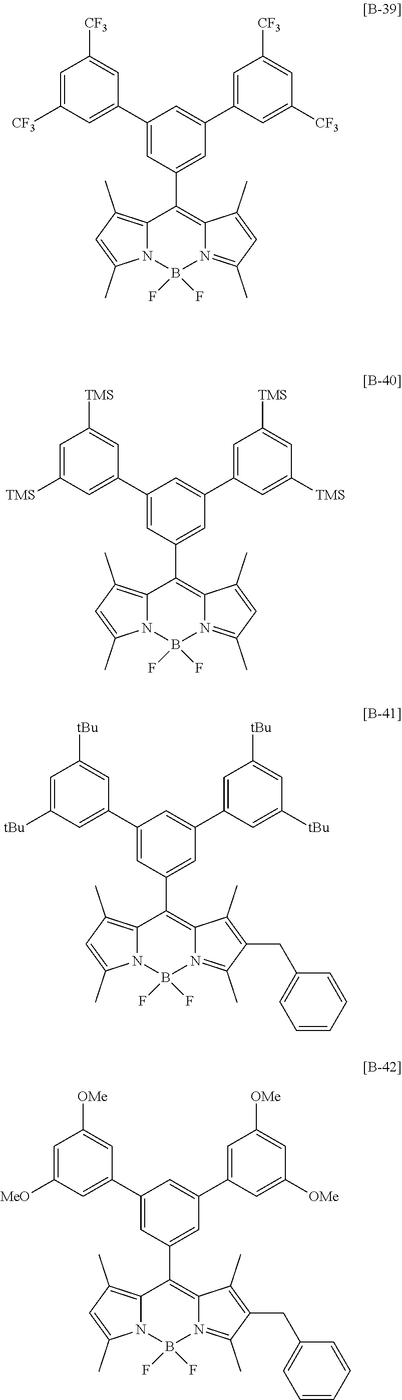

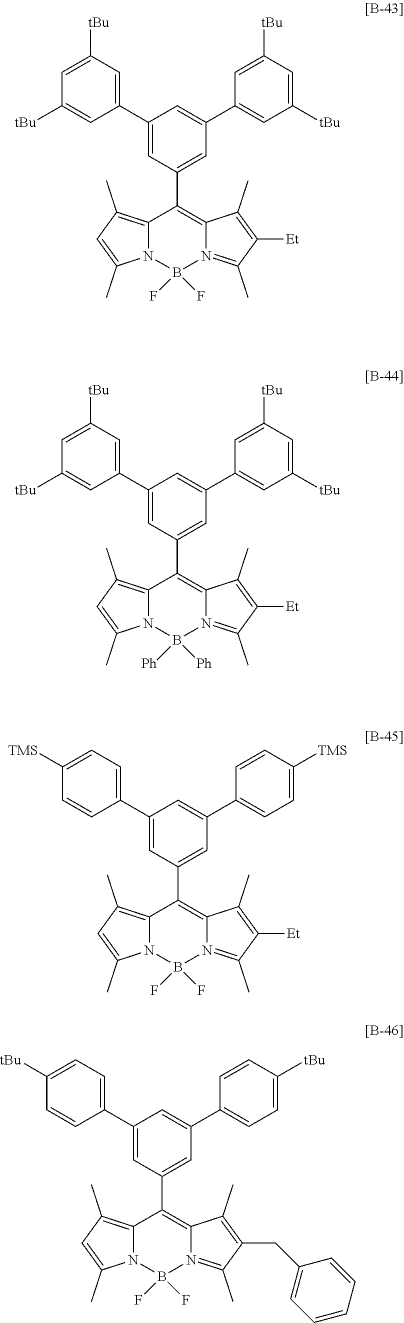

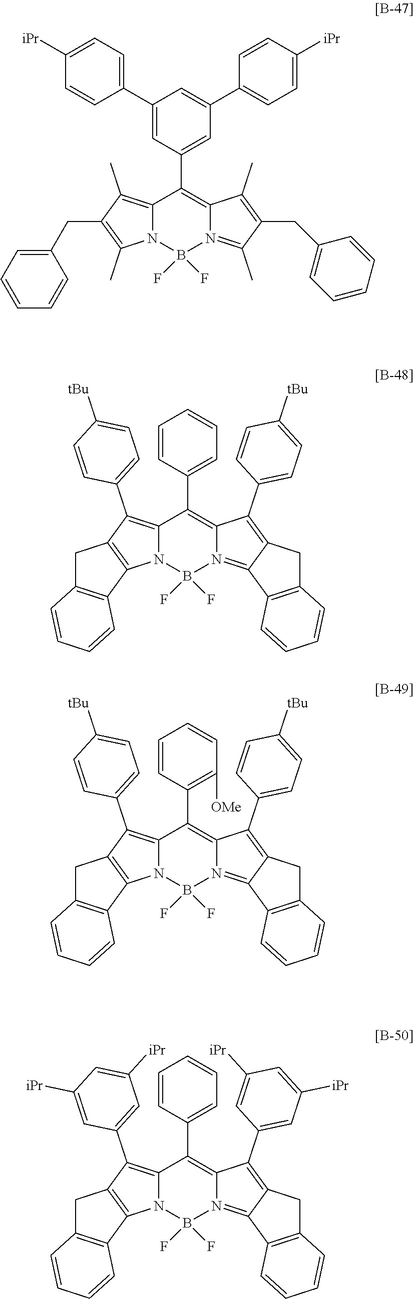

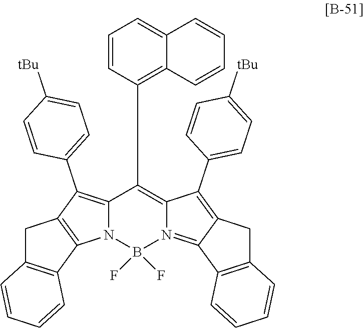

The light-emitting down conversion organic nano-dots may have a core-shell structure in which the first and second organic phosphors are surrounded by a surfactant, and in this case, the shape and size of the organic nano-dots may become uniform, thereby improving the yield of the organic nano-dots, and the size of the light-emitting down conversion organic nano-dots may be easily adjusted by adjusting the concentration of the surfactant, thereby improving the properties of the color conversion film, but the present invention is not limited thereto.

The surfactant may be one or more selected from the group consisting of an anionic surfactant, a cationic surfactant, an amphoteric surfactant, and a nonionic surfactant, but the present invention is not limited thereto.

The anionic surfactant is a surfactant whose hydrophilic group stands out as an anion when dissolved in water, and the hydrophilic group of the anionic surfactant may be one or more selected from the group consisting of carboxylates, sulfates, sulfonates, and phosphates, but the present invention is not limited thereto.

The cationic surfactant is a surfactant whose hydrophilic group stands out as a cation when dissolved in water, and may include a nitrogen atom having a positive charge, and specifically, may be tetrabutylammonium oleate (TBAOleate), but the present invention is not limited thereto.

The amphoteric surfactant is a surfactant having properties of an anionic surfactant in an alkaline range and properties of a cationic surfactant in an acidic range when dissolved in water.

The nonionic surfactant is a surfactant having a hydrophilic group that is not ionized when dissolved in water, and is a surfactant that does not exhibit electric charges even when dissolved in water and may be, for example, Triton X100 having a hydrophilic polyethylene oxide chain and a lipophilic or hydrophobic aromatic hydrocarbon group, but the present invention is not limited thereto.

In the present invention, a method of preparing the light-emitting down conversion organic nano-dots is not particularly limited and, for example, the light-emitting down conversion organic nano-dots may be prepared using the method including an operation S1 of mixing first and second organic phosphors and a surfactant and preparing a first mixture, an operation S2 of adding an anti-solvent for the first and second organic phosphors to the first mixture and preparing a dispersion, and an operation S3 of dialyzing the dispersion and drying the dialyzed dispersion.

### Operation S1

The description of the first and second organic phosphors and the surfactant constituting the first mixture in operation S1 is as described above.

In operation S1, a mixing ratio (molar ratio) of the first and second organic phosphors and the surfactant may be 1:20 to 1:1,000, preferably, 1:200 to 1:800, and more preferably, 1:400 to 1:600, but the present invention is not limited thereto. When the mixing ratio (molar ratio) of the first and second organic phosphors and the surfactant satisfies the above range, uniform light-emitting down conversion organic nano-dots having a small particle size may be obtained.

When the concentration of the surfactant exceeds a critical micelle concentration, a hydrophobic portion of the surfactant surrounds the first and second organic phosphors to form micelles, and the micelles are dispersed in the solvent.

This makes the shape and size of the light-emitting down conversion organic nano-dots uniform, thereby improving the yield of the light-emitting down conversion organic nano-dots. Meanwhile, since the particle size of the light-emitting down conversion organic nano-dots may be adjusted by adjusting the concentration of the surfactant, the properties of the color conversion film may be further improved.

### Operation S2

The anti-solvent added in operation S2 may be one or more selected from the group consisting of an aqueous solvent, an alcohol-based solvent, a ketone-based solvent, an ether-based solvent, a sulfoxide-based solvent, and an ester-based solvent, but the present invention is not limited thereto.

The aqueous solvent may be, for example, any one of water, an aqueous hydrochloric acid solution, and a aqueous sodium hydroxide solution, the alcohol-based solvent may be, for example, one or more selected from the group consisting of methanol, ethanol, isopropyl alcohol, n-propyl alcohol, and 1-methoxy-2-propanol, the ketone-based solvent may be, for example, one or more selected from the group consisting of acetone, methyl ethyl ketone, methyl isobutyl ketone, and cyclohexanone, the ether-based solvent may be, for example, one or more selected from the group consisting of dimethyl ether, diethyl ether, and tetrahydrofuran, the sulfoxide-based solvent may be, for example, dimethyl sulfoxide, and the ester-based solvent may be, for example, an alkyl ester, but the present invention is not limited thereto.

### Operation S3

Operation S3 is an operation performed to improve the yield of the light-emitting down conversion organic nano-dots by removing excess surfactant from the dispersion.

A dialysis device used in operation S3 may be, for example, a dialysis tube made of cellulose acetate, but the present invention is not limited thereto.

Drying the dispersion dialyzed in operation S3 may be concentrating the dispersion under vacuum for 10 to 12 hours, but the present invention is not limited thereto.

### Composition for Color Conversion Film

According to another aspect of the present invention, a composition for a color conversion film including the above-described light-emitting down conversion organic nano-dots and a water-soluble polymer resin is provided.

The water-soluble polymer resin may have a weight average molecular weight of 5,000 to 100,000 g/mol and a degree of hydration of 70 to 100%, and in this case, the water-soluble polymer resin may exhibit appropriate surface activity and the properties of the color conversion film may be further improved, but the present invention is not limited thereto.

The water-soluble polymer resin may be one or more selected from the group consisting of a nonionic water-soluble polymer, an anionic water-soluble polymer, and a cationic water-soluble polymer, but the present invention is not limited thereto.

The nonionic water-soluble polymer may be, for example, one or more polymers or copolymers selected from the group consisting of polyvinyl alcohol (PVA), polyethylene oxide (PEO), polyacrylamide (PAM), and polyvinylpyrrolidone (PVP), the anionic water-soluble polymer may be, for example, one or more polymers or copolymers selected from the group consisting of polyacrylic acid (PAA) and its derivatives, poly(styrene sulfonic acid) (PSSA), poly(silicic acid) (PSiA), poly(phosphoric acid) (PPA), poly(ethylenesulfinic acid) (PESA), poly[3-(vinyloxy)propane-1-sulfonic acid], poly(4-vinylphenol), poly(4-vinylphenol sulfuric acid), poly(ethylenephosphoric acid), poly(maleic acid), poly(2-methacryloxyethane-1-sulfonic acid), poly(3-methacryloyloxypropane-1-sulfonic acid) and poly(4-vinylbenzoic acid), and the cationic water-soluble polymer may be, for example, one or more polymers or copolymers selected from the group consisting of polyethyleneimine (PEI), polyamines, polyamideamine (PAMAM), poly(diallyldimethyl ammonium chloride) (PDADMAC), poly(4-vinylbenzyltrimethylammonium salt), poly[(dimethylimino)trimethylene(dimethylimino)hexamethylenedibromide], polybrene, poly(2-vinylpiperidine salt), poly(vinylamine salt), and poly(2-vinylpyridine) and derivatives thereof, but the present invention is not limited thereto.

The description of the light-emitting down conversion organic nano-dots is as described above.

The content of the light-emitting down conversion organic nano-dots may be 1 to 20 parts by weight based on 100 parts by weight of the water-soluble polymer resin, but the present invention is not limited thereto. When the content of the light-emitting down conversion organic nano-dots is too small, CCE may be lowered, and conversely, when the content of the light-emitting down conversion organic nano-dots is too large, the properties of aggregation between nano-dots may become stronger so that the size of the particles may increase, and quenching may occur.

The composition for a color conversion film may further include a crosslinking agent in order to secure high thermal stability of the color conversion film and prevent discoloration (decrease in transmittance) due to heat, but the present invention is not limited thereto.

The crosslinking agent may be, for example, one or more selected from the group consisting of glutaraldehyde, glyoxal, maleic acid, citric acid, trisodium trimetaphosphate, sodium hexametaphosphate, dianhydrides, succinic acid, suberic acid, sulfosuccinic acid, and a radical crosslinking agent, K₂S₂O₈, but the present invention is not limited thereto.

When the water-soluble polymer resin is PVA, it is preferable to use suberic acid or the radical crosslinking agent, K₂S₂O₈, as a crosslinking agent to improve thermal stability and transmittance maintenance, but the present invention is not limited thereto.

The content of the crosslinking agent may be 0.01 to 20 parts by weight based on 100 parts by weight of the water-soluble polymer resin, but the present invention is not limited thereto.

The composition for a color conversion film may further include a light scattering agent in order to generate a light scattering effect to increase light absorption efficiency, improve dispersibility, and secure high thermal stability and incombustibility, but the present invention is not limited thereto.

The light scattering agent may be, for example, one or more types of inorganic oxide particles selected from the group consisting of TiO₂, ZnO, Fe₃O₄, CeO₂, MoO₂, Ag₂O, CuO, and NiO, and may be inorganic oxide particles having an average particle size of 200 to 400 nm, but the present invention is not limited thereto.

The content of the light scattering agent may be 1 to 20 parts by weight based on 100 parts by weight of the water-soluble polymer resin, but the present invention is not limited thereto.

### Color Conversion Film

According to still another aspect of the present invention, a color conversion film manufactured using the above-described composition for a color conversion film is provided.

The color conversion film may be manufactured using the above-described composition for a color conversion film using a bar coating method, a sol-gel method, an inkjet printing method, a roll coating method, a spin coating method, a drop casting method, or the like.

For example, in the case in which the color conversion film is manufactured using a bar coating method, the above-described composition for a color conversion film may be sprayed on a glass substrate, then a film may be formed by a bar coating method, and annealing may be performed in an oven at 50 to 70° C. for several hours in order to remove the solvent to manufacture the color conversion film, but the present invention is not limited thereto.

A thickness of the color conversion film may be 200 μm or less, preferably, 180 μm or less, and more preferably, 150 m, but the present invention is not limited thereto.

### Display Device

According to yet another aspect of the present invention, a display device including the above-described color conversion film is provided.

The display device according to the present invention may include a liquid-crystal display (LCD) device, an organic light-emitting display device, a micro-LED display device, or the like.

An organic phosphor used in the display device should have a narrow FWHM for high color purity. Therefore, the second organic phosphor used in the display device may be the above-described boron compound, but the present invention is not limited thereto.

Generally, a LCD device includes two substrates. Specifically, the LCD device includes a lower substrate having a switching element including a thin film transistor, an upper substrate facing the lower substrate and having a common electrode, and liquid crystals injected between the upper and lower substrates.

In contrast, an organic LED (OLED) and a micro-LED may each be formed on a single substrate. A switching element including a thin film transistor at a lower portion thereof may be formed, and an OLED or a micro-LED turned on/off by the corresponding switching element may be formed at an upper portion of the switching element. Although the OLED or the micro-LED may be formed using a single substrate, the OLED or the micro-LED generally includes an upper substrate and is used by forming an antireflection film or the like on the corresponding upper substrate.

The display device according to the present invention may typically include an upper substrate including a base film, an antireflection film, and a color conversion film, and the color conversion film may be formed using the light-emitting organic nano-dots according to the present invention.

In the case of a LCD device, light emitted from a backlight is converted into three primary colors using a color conversion film, and in the case of a display device to which an OLED or a micro-LED is applied, a monochromatic OLED or micro-LED is applied and light is emitted in three primary colors using the color conversion film according to the present invention.

### LED Device

According to yet another aspect of the present invention, a LED device including the above-described color conversion film is provided.

The LED device is a LED that emits light by applying a voltage to a PN junction diode of a compound semiconductor, and the LED device corresponds to a LED in which energy generated when holes and electrons move between p-n and combine with each other is emitted in the form of light, and should be understood as a concept including an OLED.

An organic phosphor used in a LED device should have a wide FWHM to implement a high color rendering index (CRI). Therefore, the second organic phosphor used in the light-emitting diode device may be the above-described delayed fluorescence material, but the present invention is not limited thereto.

Generally, LED devices are divided into chip LEDs with features of high brightness, an ultra-small size, and a thin shape, top LEDs, lamp LEDs used for outdoor displays, electric signboards, or the like having ultra-high brightness, high moisture resistance, and heat resistance according to the purpose of use.

The LED device according to the present invention may include a substrate, and a LED chip disposed on the substrate. The color conversion film according to the present invention may absorb light emitted from the LED chip (or LED backlight) using the light-emitting organic nano-dots according to the present invention to convert the absorbed light into light of a different long wavelength.

Hereinafter, examples in this specification will be described in more detail. However, the following experimental results are only representative experimental results among the above examples, and cannot be interpreted as the scope and contents of the present specification are reduced or limited by the examples. Each effect of various examples in this specification that is not explicitly presented below will be described in detail in the corresponding section.

### Preparation Examples: Preparation of Organic Phosphor

### Preparation Example 1: Preparation of Compound B-23

A compound B-23 (hereinafter, referred to as “4tBuMB”) having the following structural formula was synthesized with reference to ACS Appl. Mater. Interfaces 13, pp 17882-17891 (2021).

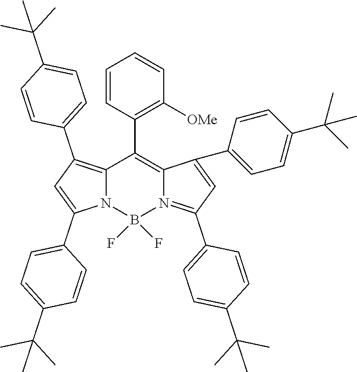

### Preparation Example 2: Preparation of Compound B-33

A compound B-33 (hereinafter, referred to as “tPhBODIPY”) having the following structural formula was synthesized with reference to Adv. Optical Mater. 8, 2000483 (2020).

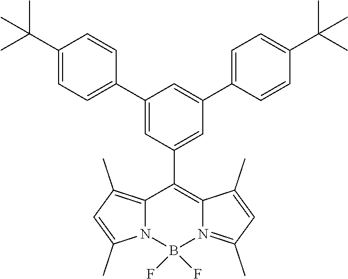

### Preparation Example 3: Preparation of Compound B-36

A compound B-36 (hereinafter, referred to as “4tBuPhBODIPY”) having the following structural formula was synthesized with reference to Luminescence. 2021, 36, 1697-1705.

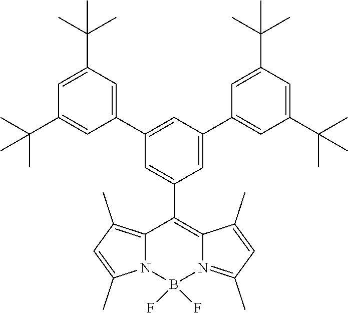

### Preparation Example 4: Preparation of Compound BPer-4

A compound BPer-4 (hereinafter, referred to as “4tBuPerylene”) having the following structural formula was synthesized with reference to Chem. Commun., 2022, 58, 8802-8805. A molar extinction coefficient (F) of the 4tBuPerylene at a wavelength of 450 nm was 1.9×10⁴ L/mol·cm.

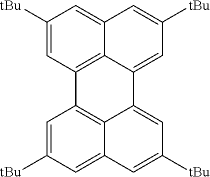 [SMILES: CC(C)(C)c1cc2cc(C(C)(C)C)cc3c4cc(C(C)(C)C)cc5cc(C(C)(C)C)cc(c(c1)c23)c54]

### Preparation Example 5: Preparation of Compound BPyr-3

A compound BPyr-3 (hereinafter, referred to as “T4tBuPhpyrene”) having the following structural formula was synthesized with reference to Chemistry Select, 2020, 5, 12465-12469. A molar extinction coefficient (F) of the T4tBuPhpyrene at a wavelength of 450 nm was 1.7×10⁴ L/mol·cm.

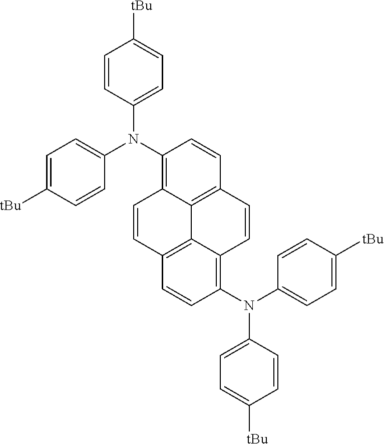 [SMILES: CC(C)(C)c1ccc(N(c2ccc(C(C)(C)C)cc2)c2ccc3ccc4c(N(c5ccc(C(C)(C)C)cc5)c5ccc(C(C)(C)C)cc5)ccc5ccc2c3c54)cc1]

### Preparation Example 6: Preparation of Compound BM-2

A compound BM-2 (hereinafter, referred to as “M-t-DAVNA”) having the following structural formula was synthesized with reference to Adv. Mater. 2022, 34, 2100161-2100179. A molar extinction coefficient (F) of the M-t-DAVNA at a wavelength of 450 nm was 1.9×10⁴ L/mol·cm.

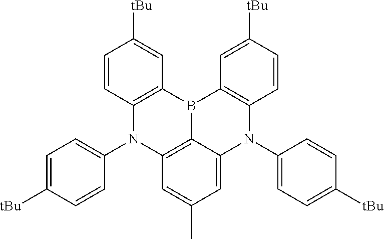 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Preparation Example 7: Preparation of Compound BD-4

A compound BD-4 (hereinafter, referred to as “4F-DAVNA”) having the following structural formula was synthesized with reference to Chemical Engineering Journal, 432, 2022, 134381. A molar extinction coefficient (F) of the 4F-DAVNA at a wavelength of 450 nm was 8.3×10⁴ L/mol·cm.

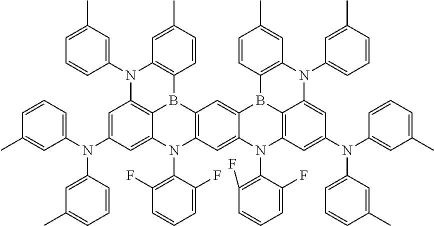

### Preparation Example 8: Preparation of Compound BB-1

A compound BB-1 (hereinafter, referred to as “AzaBoron”) having the following structural formula was synthesized with reference to Dyes and Pigments 99, 2013, 240-249. A molar extinction coefficient (F) of the AzaBoron at a wavelength of 450 nm was 5.6×10⁴ L/mol·cm.

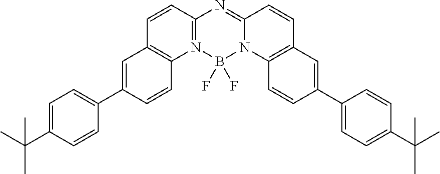

### Manufacturing Example 1: Manufacture of Light-Emitting Organic Nano-Dots (Organic Nano-Dots (ONDs))

### Manufacturing Example 1-1

An organic phosphor 4tBuMB was dissolved in tetrahydrofuran to prepare a solution (0.5 mM). In addition, a nonionic surfactant (Triton X-100) was dissolved in separate tetrahydrofuran to prepare a solution (0.1 M). The surfactant solution (0.36 mL) and tetrahydrofuran (0.14 mL) were added to the 4tBuMB solution (0.10 mL) to prepare a first mixture. The first mixture and 5.40 mL of deionized water were mixed to prepare a dispersion. The dispersion was dialyzed with a cellulose acetate tube for 12 hours to remove residual surfactant, and the solvent was concentrated under vacuum to prepare red organic nano-dots (hereinafter, referred to as “4tBuMB red organic nano-dots (RONDs)”).

### Manufacturing Example 1-2

Green organic nano-dots tPhBODIPY green organic nano-dots (GONDs) were prepared in the same manner as in Manufacturing Example 1-1, except that tPhBODIPY was used instead of 4tBuMB as an organic phosphor.

### Manufacturing Example 1-3

Green organic nano-dot 4tBuPhBODIPY GONDs were prepared in the same manner as in Manufacturing Example 1-1, except that 4tBuPhBODIPY was used instead of 4tBuMB as an organic phosphor.

### Manufacturing Example 1-4

Red down conversion organic nano-dot Per-4tBuMB (down conversion-red organic nano-dots (DC-RONDs)) were prepared in the same manner as in Manufacturing Example 1-1, except that a mixture of a blue phosphor 4tBuPerylene and 4tBuMB at a weight ratio of 9:1 was used instead of 4tBuMB alone as an organic phosphor.

### Manufacturing Example 1-5

Red down conversion organic nano-dot Per-4tBuMB DC-RONDs were prepared in the same manner as in Manufacturing Example 1-4, except that the weight ratio of 4tBuPerylene and 4tBuMB was changed to 7:3.

### Manufacturing Example 1-6

Red down conversion organic nano-dot Per-4tBuMB DC-RONDs were prepared in the same manner as in Manufacturing Example 1-4, except that the weight ratio of 4tBuPerylene and 4tBuMB was changed to 6:4.

### Manufacturing Example 1-7

Green down conversion organic nano-dot Per-tPhBODIPY down conversion-green organic nano-dots (DC-GONDs) were prepared in the same manner as in Manufacturing Example 1-2, except that a mixture of a blue phosphor 4tBuPerylene and tPhBODIPY at a weight ratio of 7:3 was used instead of tPhBODIPY alone as an organic phosphor.

### Manufacturing Example 1-8

Green down conversion organic nano-dot Per-4tPhBODIPY DC-GONDs were prepared in the same manner as in Manufacturing Example 1-7, except that the weight ratio of 4tBuPerylene and tPhBODIPY was changed to 5:5.

### Manufacturing Example 1-9

Green down conversion organic nano-dot Per-4tBuPhBODIPY DC-GONDs were prepared in the same manner as in Manufacturing Example 1-3, except that a mixture of a blue phosphor 4tBuPerylene and 4tBuPhBODIPY at a weight ratio of 7:3 was used instead of 4tBuPhBODIPY alone as an organic phosphor.

### Manufacturing Example 1-10

Green down conversion organic nano-dot Pyr-tPhBODIPY DC-GONDs were prepared in the same manner as in Manufacturing Example 1-7, except that T4tBuPhpyrene was used instead of 4tBuPerylene as a blue phosphor.

### Manufacturing Example 1-11

Green down conversion organic nano-dots MtD-tPhBODIPY DC-GONDs were prepared in the same manner as in Manufacturing Example 1-7, except that M-t-DAVNA was used instead of 4tBuPerylene as a blue phosphor.

### Manufacturing Example 1-12

Green down conversion organic nano-dots FD-tPhBODIPY DC-GONDs were prepared in the same manner as in Manufacturing Example 1-7, except that 4F-DAVNA was used instead of 4tBuPerylene as a blue phosphor.

### Manufacturing Example 1-13

Green down conversion organic nano-dots AB-tPhBODIPYDC-GONDs were prepared in the same manner as in Manufacturing Example 1-7, except that AzaBoron was used instead of 4tBuPerylene as a blue phosphor.

### Manufacturing Example 1-14

Mixed-color down conversion organic nano-dot Per-4tBuPhBODIPY-4tBuMB down conversion-green and red organic nano-dots (DC-GRONDs) were prepared in the same manner as in Manufacturing Example 1-1, except that a mixture of a blue phosphor 4tBuPerylene, a green phosphor 4tBuPhBODIPY, and a red phosphor 4tBuMB at a weight ratio of 7:2:1 was used instead of 4tBuMB alone as an organic phosphor.

### Manufacturing Example 1-15

Mixed-color down conversion organic nano-dot Per-4tBuPhBODIPY-4tBuMB DC-GRONDs were prepared in the same manner as in Manufacturing Example 1-1, except that a mixture of a blue phosphor 4tBuPerylene, a green phosphor 4tBuPhBODIPY, and a red phosphor 4tBuMB at a weight ratio of 7:2.5:0.5 was used instead of 4tBuMB alone as an organic phosphor.

### Comparative Manufacturing Example 1

Red organic nano-dots were prepared in the same manner as in Manufacturing Example 1-1, except that a surfactant solution was not mixed.

### Experimental Example 1: Particle Size of Organic Nano-Dots

The particle sizes of the organic nano-dots prepared according to Manufacturing Example 1 and Comparative Manufacturing Example 1 were measured, and results of the measurement are shown in Table 1 below.

TABLE 1

| | | Standard | | |
|---|---|---|---|---|
| | Average | deviation | Minimum | Maximum |
| | (μm) | (μm) | (μm) | (μm) |
| Manufacturing | 0.16 | 0.07 | 0.04 | 0.41 |
| Example 1-1 | | | | |
| Comparative | 17.38 | 4.25 | 10.70 | 32.34 |
| Manufacturing | | | | |
| Example 1-1 | | | | |

From Table 1, it can be seen that when no surfactant was used, the phosphor was aggregated and the average particle size become about 100 times larger than that when the surfactant was used, and thus organic particles in micro units were obtained, whereas, when the surfactant was used, nano-dots in which organic particles were much more uniform and smaller were obtained.

### Experimental Example 2: Evaluation of Optical Properties

4tBuMB was dissolved in a minimum amount of THF and dispersed in deionized water to obtain a 4tBuMB solution, and each of the 4tBuMB RONDs of Manufacturing Example 1-1 and the Per-4tBuMB DC-RONDs of Manufacturing Example 1-5 was dispersed in deionized water to obtain a 4tBuMB ROND solution and a Per-4tBuMB DC-ROND solution. Further, tPhBODIPY was dissolved in a minimum amount of THF and dispersed in deionized water to obtain a tPhBODIPY solution, each of the tPhBODIPY GONDs of Manufacturing Example 1-2 and the Per-tPhBODIPY DC-GONDs of Manufacturing Example 1-7 was dispersed in deionized water to obtain a tPhBODIPY GOND solution and a Per-tPhBODIPY DC-GOND solution.

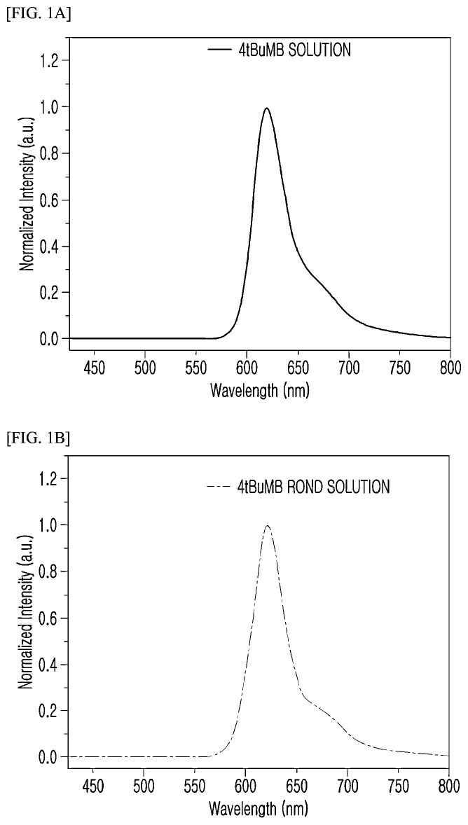

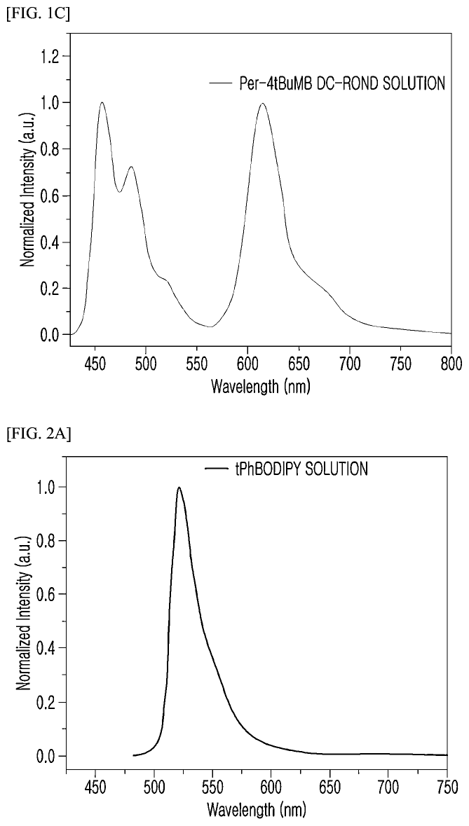

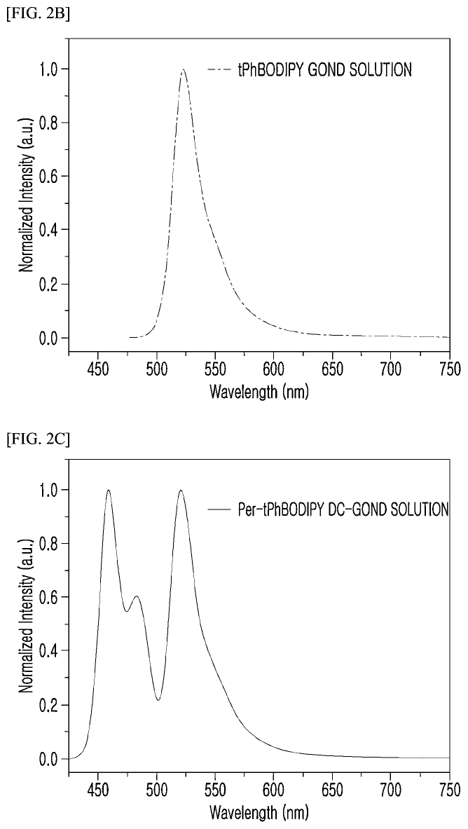

Thereafter, the optical properties of each of the solutions were measured, and results of the measurement are shown in Table 2 below and FIGS. 1 to 2. Normalized photoluminescence intensity spectra were measured using JASCO-FP 8500 equipment, and absolute PLQY values were measured using an integrating sphere built into JASCO-FP 8500 equipment for the prepared solutions.

FIGS. 1A to 1C are a graph showing normalized photoluminescence intensity spectra for a 4tBuMB solution, a 4tBuMB ROND solution, and a Per-4tBuMB DC-ROND solution, respectively, and FIGS. 2A to 2C are a graph showing normalized photoluminescence intensity spectra for a tPhBODIPY solution, a tPhBODIPY GOND solution, and a Per-tPhBODIPY DC-GOND solution, respectively.

TABLE 2

| | Maximum | | |
|---|---|---|---|
| | emission | | |
| | spectrum (nm) | FWHM (nm) | PLQY (%) |
| 4tBuMB solution | 620 | 31.2 | 95 |
| 4tBuMB ROND solution | 622 | 31.3 | 87 |
| Per-4tBuMB DC-ROND | 618 | 31.0 | 90 |
| solution | | | |
| tPhBODIPY solution | 522 | 24.0 | 95 |
| tPhBODIPY GOND solution | 523 | 25.0 | 84 |
| Per-tPhBODIPY DC-GOND | 520 | 23.0 | 86 |
| solution | | | |

Referring to Table 2 and FIGS. 1 to 2, it can be seen that the positions of peaks in emission spectra vary depending on the particle size of a phosphor and whether the phosphor is mixed with a blue phosphor. Specifically, in the case of the OND, as the particle size decreases, the emission spectrum is shifted toward a longer wavelength, and the PLQY also decreases due to aggregation. In the case of the DC-OND, compared to the OND, the maximum emission spectrum is shifted toward a shorter wavelength again, which seems to have a slight effect on blue emission because it contains a blue phosphor. Further, results are shown in which the concentration of the green or red phosphor is reduced due to the blue phosphor, thereby reducing aggregation, which reduces self-quenching, resulting in an increase in PLQY

### Manufacturing Example 2: Manufacture of Color Conversion Film (1)

### Manufacturing Example 2-1

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The 4tBuMB ROND solution (0.8 wt % aqueous solution dispersion, 0.53 ml) of Manufacturing Example 1-1 and a TiO₂ solution (6.0 wt % aqueous solution, 0.07 ml) were mixed in 0.80 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried at 120° C. for 2 hours to manufacture a color conversion film.

### Manufacturing Example 2-2

A color conversion film was manufactured in the same manner as in Manufacturing Example 2-1, except that the Per-4tBuMB DC-ROND solution of Manufacturing Example 1-5 was used instead of the 4tBuMB ROND solution.

### Manufacturing Example 2-3

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The tPhBODIPY GOND solution (1.0 wt % aqueous solution dispersion, 0.6 ml) of Manufacturing Example 1-2 and a TiO₂ solution (15.0 wt % aqueous solution, 0.04 ml) were mixed in 0.80 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 2-4

A color conversion film was manufactured in the same manner as in Manufacturing Example 2-1, except that the Per-tPhBODIPY DC-GOND solution of Manufacturing Example 1-7 was used instead of the tPhBODIPY GOND solution.

### Experimental Example 3: Evaluation of Optical Properties

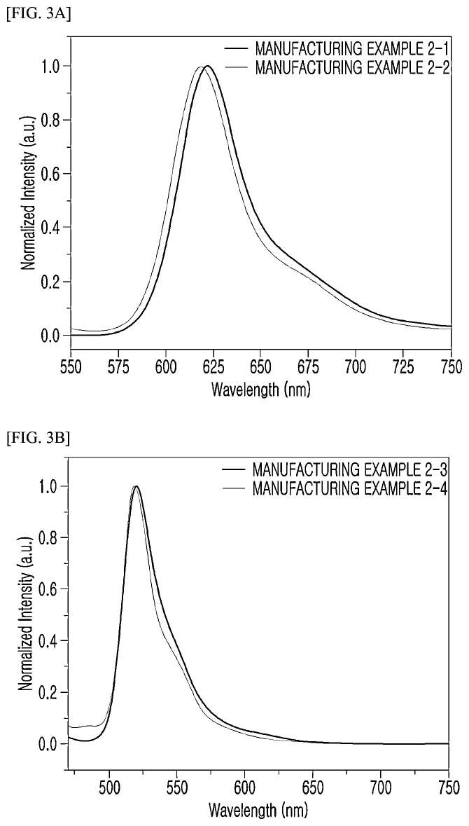

The optical properties of the color conversion films according to Manufacturing Examples 2-1 to 2-4 were measured, and results of the measurement are shown in Table 3 blow and FIGS. 3 to 5.

FIG. 3A is a graph showing normalized photoluminescence intensity spectra of color conversion films according to Manufacturing Examples 2-1 and 2-2, and FIG. 3B is a graph showing normalized photoluminescence intensity spectra of color conversion films according to Manufacturing Examples 2-3 and 2-4.

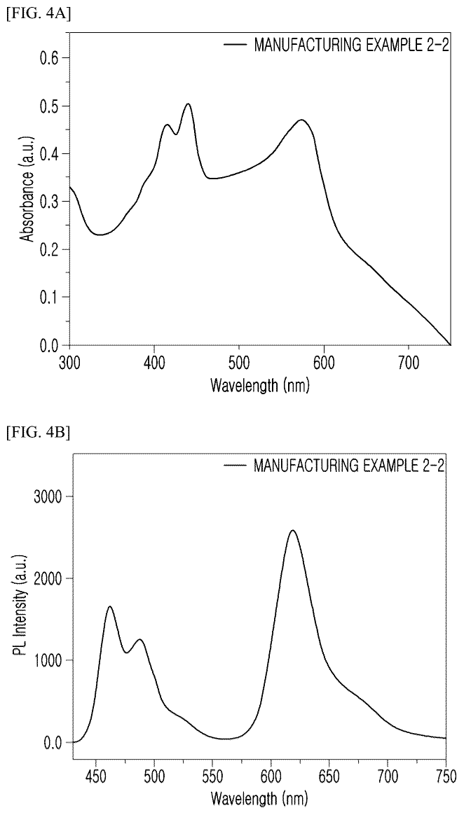

FIG. 4A is a graph showing an absorption spectrum of the color conversion film according to Manufacturing Example 2-2, and FIG. 4B is a graph showing a photoluminescence intensity spectrum of the color conversion film according to Manufacturing Example 2-2.

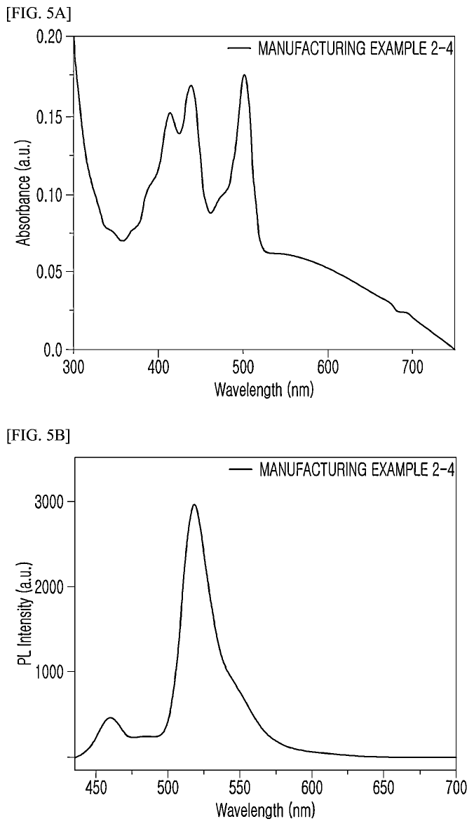

FIG. 5A is a graph showing an absorption spectrum of the color conversion film according to Manufacturing Example 2-4, and FIG. 5B is a graph showing a photoluminescence intensity spectrum of the color conversion film according to Manufacturing Example 2-4.

TABLE 3

| | | | | | | Blue |
|---|---|---|---|---|---|---|
| | Organic | | Maximum | | | light |
| | nano- | | emission | | | reduc- |
| | dots | TiO₂ | spectrum | FWHM | CCE | tion |
| | (wt %) | (wt %) | (nm) | (nm) | (%) | rate (%) |
| Manufacturing | 2.5 | 2.5 | 622 | 35.0 | 36.17 | 34.04 |
| Example 2-1 | | | | | | |
| Manufacturing | 2.5 | 2.5 | 620 | 35.0 | 63.80 | 47.92 |
| Example 2-2 | | | | | | |
| Manufacturing | 3.95 | 3.95 | 520 | 26.0 | 34.00 | 74.19 |
| Example 2-3 | | | | | | |
| Manufacturing | 3.95 | 3.95 | 519 | 25.0 | 90.00 | 42.43 |
| Example 2-4 | | | | | | |

Referring to Table 3 and FIGS. 3 to 5, it can be seen that the position of peak in an emission spectrum of the DC-OND film compared to the OND film is slightly shifted toward a shorter wavelength, and this is because aggregation of the second organic phosphor is reduced due to the influence of the first organic phosphor. Further, the CCE of the DC-OND film compared to the OND film increases by 1.76 times in the case of the DC-ROND film and by 2.65 times in the case of the DC-GOND film, and this is because the absorption of LED light increases as the first organic phosphor is used. It can be seen that the spectral overlap of the DC-GOND film is larger than that of the DC-ROND film and thus has a higher increase rate.

### Manufacturing Example 3: Manufacture of Color Conversion Film (2)

### Manufacturing Example 3-1

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The Per-4tBuMB DC-ROND solution (0.8 wt % aqueous solution dispersion, 0.37 ml) of Manufacturing Example 1-5 and a TiO₂ solution (6.0 wt % aqueous solution, 0.05 ml) were mixed in 0.80 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 3-2

A color conversion film was manufactured in the same manner as in Manufacturing Example 3-1, except that no TiO₂ solution was used.

### Manufacturing Example 3-3

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The Per-tPhBODIPY DC-GOND solution (1.0 wt % aqueous solution dispersion, 0.3 ml) of Manufacturing Example 1-7 and a TiO₂ solution (15.0 wt % aqueous solution, 0.02 ml) were mixed in 0.70 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 3-4

A color conversion film was manufactured in the same manner as in Manufacturing Example 3-3, except that no TiO₂ solution was used.

### Experimental Example 4: Evaluation of Optical Properties

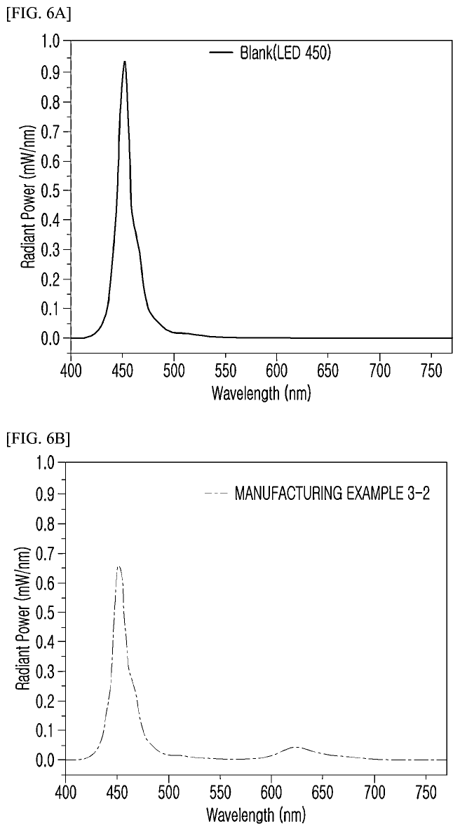

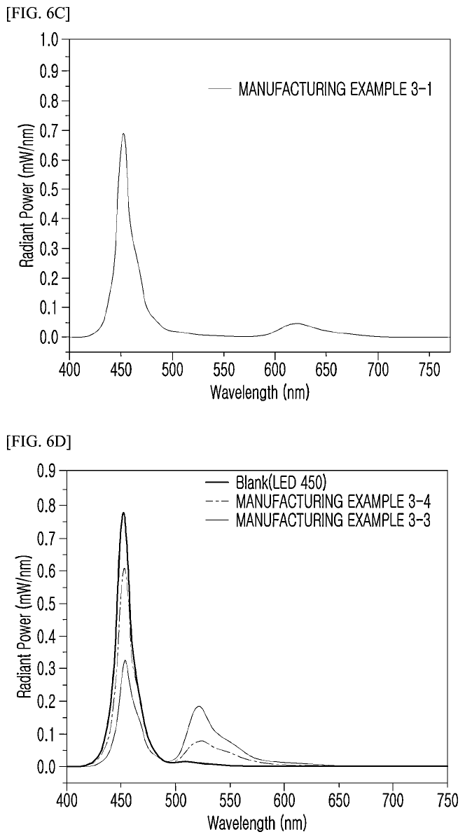

The optical properties of the color conversion films according to Manufacturing Examples 3-1 to 3-4 were measured, and results of the measurement are shown in Table 4 below and FIGS. 6A to 6D.

FIGS. 6A to 6C are a graph showing the radiant power of color conversion films according to Manufacturing Examples 3-1 and 3-2, and FIG. 6D is a graph showing the radiant power of color conversion films according to Manufacturing Examples 3-3 and 3-4.

TABLE 4

| | | | Maximum | | |
|---|---|---|---|---|---|
| | Organic | | emission | | Blue light |
| | nano-dots | TiO₂ | spectrum | CCE | reduction rate |
| | (wt %) | (wt %) | (nm) | (%) | (%) |
| Manufacturing | 1.73 | 1.92 | 620 | 63.50 | 26.22 |
| Example 3-1 | | | | | |
| Manufacturing | 1.73 | — | 620 | 48.82 | 29.25 |
| Example 3-2 | | | | | |
| Manufacturing | 2.00 | 1.54 | 519 | 84.81 | 58.00 |
| Example 3-3 | | | | | |
| Manufacturing | 2.00 | — | 519 | 93.70 | 21.83 |
| Example 3-4 | | | | | |

Referring to Table 4 and FIGS. 6A to 6D, results are shown in which the blue light reduction rate in the case of the color conversion film manufactured by mixing TiO₂ with the DC-RONDs is almost the same as that in the case in which no TiO₂ is used, but the CCE is increased by 1.3 times. Meanwhile, results are shown in which the blue light reduction rate in the case of the color conversion film manufactured by mixing TiO₂ with the DC-GONDs is 2.7 times higher than that in the case in which no TiO₂ is used, and the CCE is reduced slightly but still high at 84.8%.

### Manufacturing Example 4: Manufacture of Color Conversion Film (3)

### Manufacturing Example 4-1

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The Per-4tBuMB DC-ROND solution (1.4 wt % aqueous solution dispersion, 0.19 ml) of Manufacturing Example 1-5 and a TiO₂ solution (15.0 wt % aqueous solution, 0.018 ml) were mixed in 0.80 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 4-2

A color conversion film was manufactured in the same manner as in Manufacturing Example 4-1, except that the content of the Per-4tBuMB DC-ROND solution (1.4 wt % aqueous solution dispersion) was adjusted to 0.23 mL.

### Manufacturing Example 4-3

A color conversion film was manufactured in the same manner as in Manufacturing Example 4-1, except that the content of the TiO₂ solution (15.0 wt % aqueous solution) was adjusted to 0.044 mL.

### Manufacturing Example 4-4

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The Per-tBuPhBODIPY DC-GOND solution (2.13 wt % aqueous solution dispersion, 0.10 ml) of Manufacturing Example 1-9 and a TiO₂ solution (15.0 wt % aqueous solution, 0.01 ml) were mixed in 0.51 ml of the PVA-SA aqueous solution prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 4-5

A color conversion film was manufactured in the same manner as in Manufacturing Example 4-4, except that the content of the Per-tBuPhBODIPY DC-GOND solution (2.13 wt % aqueous solution dispersion) was adjusted to 0.16 mL and the content of the TiO₂ solution (15.0 wt % aqueous solution) was adjusted to 0.033 mL.

### Manufacturing Example 4-6

A color conversion film was manufactured in the same manner as in Manufacturing Example 4-5, except that the content of the TiO₂ solution (15.0 wt % aqueous solution) was adjusted to 0.06 mL.

### Experimental Example 5: Evaluation of Optical Properties

The optical properties of the color conversion films according to Manufacturing Examples 4-1 to 4-6 were measured, and results of the measurement are shown in Table 5 below.

TABLE 5

| | | | Maximum | | |
|---|---|---|---|---|---|
| | Organic | | emission | | Blue light |
| | nano-dots | TiO₂ | spectrum | CCE | reduction rate |
| | (wt %) | (wt %) | (nm) | (%) | (%) |
| Manufacturing | 2.50 | 2.50 | 620 | 63.80 | 47.92 |
| Example 4-1 | | | | | |
| Manufacturing | 4.00 | 2.50 | 620 | 66.40 | 48.34 |
| Example 4-2 | | | | | |
| Manufacturing | 2.50 | 6.00 | 620 | 54.02 | 62.17 |
| Example 4-3 | | | | | |
| Manufacturing | 2.00 | 1.42 | 520 | 92.00 | 39.34 |
| Example 4-4 | | | | | |
| Manufacturing | 3.08 | 4.48 | 520 | 78.00 | 59.67 |
| Example 4-5 | | | | | |
| Manufacturing | 3.08 | 8.00 | 520 | 76.30 | 74.40 |
| Example 4-6 | | | | | |

Referring to Table 5, results are shown in which when the content of the DC-RONDs is increased while the content of TiO₂ is fixed, the CCE and the blue light reduction rate remain similar, whereas, when the content of TiO₂ is increased, the blue light reduction rate is increased by 1.3 times. It can be seen that even in the case of the DC-GOND, the blue light reduction rate is increased when the content of TiO₂ is increased. Further, it can be seen that the CCE and the blue light reduction rate of the DC-GONDs which overlap more with the emission spectrum of the first organic phosphor are better than those of the DC-ROND. For reference, since the OLED is a self-luminous device, the use of a color conversion film with a higher blue light reduction rate is required.

### Manufacturing Example 5: Manufacture of Color Conversion Film (4)

### Manufacturing Example 5-1

A color conversion film was manufactured in the same manner as in Manufacturing Example 2-4, except that the Pyr-tPhBODIPY DC-GONDs of Manufacturing Example 1-10 was used instead of the Per-tPhBODIPY DC-GONDs of Manufacturing Example 1-7.

### Manufacturing Example 5-2

A color conversion film was manufactured in the same manner as in Manufacturing Example 2-4, except that the MtD-tPhBODIPY DC-GONDs of Manufacturing Example 1-11 was used instead of the Per-tPhBODIPY DC-GONDs of Manufacturing Example 1-7.

### Manufacturing Example 5-3

A color conversion film was manufactured in the same manner as in Manufacturing Example 2-4, except that the FD-tPhBODIPY DC-GONDs of Manufacturing Example 1-12 was used instead of the Per-tPhBODIPY DC-GONDs of Manufacturing Example 1-7.

### Manufacturing Example 5-4

A color conversion film was manufactured in the same manner as in Manufacturing Example 2-4, except that the AB-tPhBODIPY DC-GONDs of Manufacturing Example 1-13 was used instead of the Per-tPhBODIPY DC-GONDs of Manufacturing Example 1-7.

### Experimental Example 6: Evaluation of Optical Properties

The light emission spectra and radiant power of the color conversion films according to Manufacturing Examples 2-4 and 5-1 to 5-6 were measured and R_{O} was calculated, and results of the measurement and calculation are shown in Table 6.

TABLE 6

| | Ro (nm) | DC- | | | Blue light |
|---|---|---|---|---|---|
| | calculated | GONDs | TiO₂ | CCE | reduction rate |
| | value | (wt %) | (wt %) | (%) | (%) |
| Manufacturing | 4.36 | 3.95 | 3.95 | 90.00 | 42.43 |
| Example 2-4 | | | | | |
| Manufacturing | 4.17 | 3.95 | 3.95 | 73.45 | 40.10 |
| Example 5-1 | | | | | |
| Manufacturing | 4.03 | 3.95 | 3.95 | 81.76 | 39.17 |
| Example 5-2 | | | | | |
| Manufacturing | 3.80 | 3.95 | 3.95 | 61.87 | 35.19 |
| Example 5-3 | | | | | |
| Manufacturing | 3.89 | 3.95 | 3.95 | 69.70 | 38.90 |
| Example 5-4 | | | | | |

Referring to Table 6, it can be seen that, even when the content of DC-GONDs and TiO₂ are the same, the blue light reduction rate and the CCE are different depending on the type of first organic phosphor. This is because the molar extinction coefficient of each first organic phosphor, the degree of overlap between the LED light and the absorption spectrum of the first organic phosphor, the PLQY, the degree of overlap between the emission spectrum of the first organic phosphor and the absorption spectrum of the second organic phosphor, the R_{O} between the first organic phosphor and the second organic phosphor, and the like are different, and the dispersibility of the first organic phosphor in water is also different. As already described in Experimental Example 5, since the blue light reduction rate and the CCE may vary depending on the content of DC-GONDs and TiO₂, it is possible to manufacture and apply an optimized color conversion film according to the required properties of application fields such as LEDs, OLEDs, and micro-LEDs by adjusting the content of DC-GONDs and TiO₂, the type of first organic phosphor, and the like.

### Manufacturing Example 6: Manufacture of Color Conversion Film (5)

### Manufacturing Example 6-1

0.49 g of polyvinyl alcohol (PVA, weight average molecular weight of 13,000 to 23,000 g/mol and degree of hydration of 87 to 89%) and 0.01 g of suberic acid (SA) were mixed in 5.0 mL of deionized water and then heated at 80° C. for 3 hours to prepare a 20 wt % PVA-SA aqueous solution. The Per-4tBuPhBODIPY-4tBuMB DC-GROND solution (2.26 wt % aqueous solution dispersion, 0.29 ml) of Manufacturing Example 1-14 and a TiO₂ solution (15.0 wt % aqueous solution, 0.043 ml) were mixed in 0.80 ml of the PVA-SA aqueous solution to prepare a mixed solution. The mixed solution was sprayed on a glass substrate and then a film was formed by a bar coating method. In order to remove the solvent, the formed film was kept in an oven at 60° C. for 4 hours, and a crosslinking reaction was carried out at 120° C. for 2 hours to manufacture a color conversion film.

### Manufacturing Example 6-2

A color conversion film was manufactured in the same manner as in Manufacturing Example 6-1, except that the Per-4tBuPhBODIPY-4tBuMB DC-GRONDs (2.26 wt % aqueous solution dispersion, 0.29 ml) of Manufacturing Example 1-15 was used instead of the Per-4tBuPhBODIPY-4tBuMB DC-GRONDs of Manufacturing Example 6-1.

### Manufacturing Example 6-3

A color conversion film was manufactured in the same manner as in Manufacturing Example 6-1, except that the content of the Per-4tBuPhBODIPY-4tBuMB DC-GROND solution (2.26 wt % aqueous solution dispersion) was adjusted to 0.4 ml and the content of the TiO₂ solution (15.0 wt % aqueous solution) was adjusted to 0.11 mL.

### Manufacturing Example 6-4

A color conversion film was manufactured in the same manner as in Manufacturing Example 6-2, except that the content of the Per-4tBuPhBODIPY-4tBuMB DC-GROND solution (2.26 wt % aqueous solution dispersion) was adjusted to 0.4 ml and the content of the TiO₂ solution (15.0 wt % the aqueous solution) was adjusted to 0.11 mL.

### Experimental Example 7: Evaluation of Optical Properties

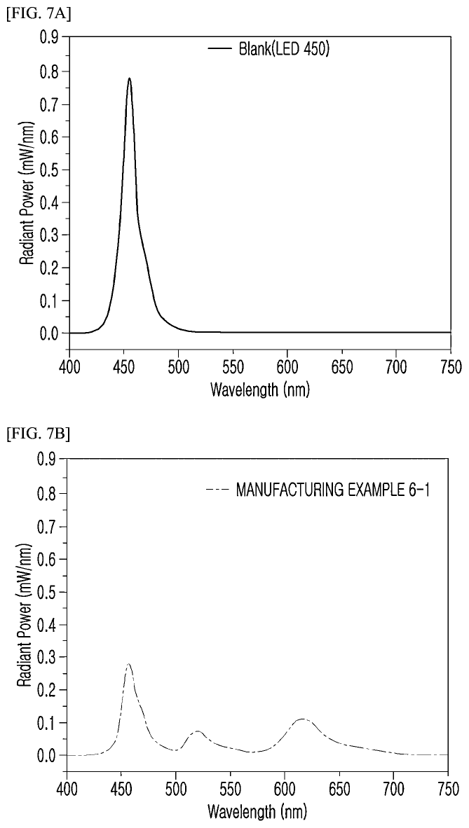

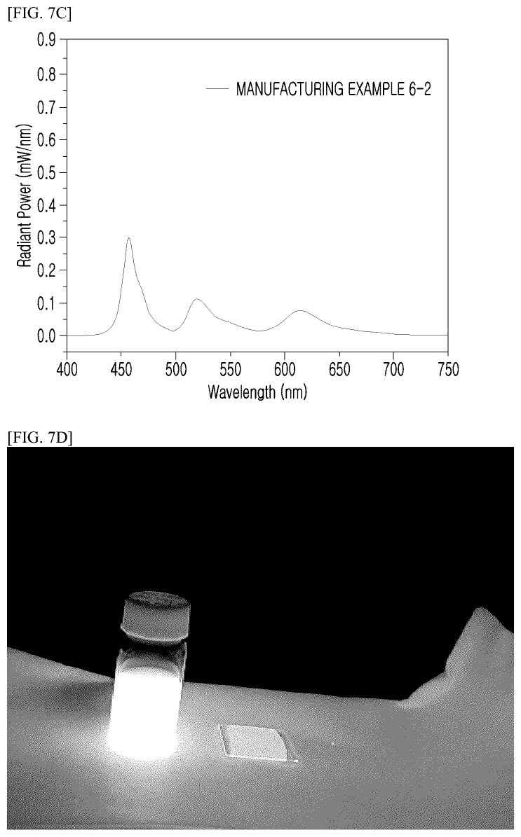

The optical properties of the color conversion films according to Manufacturing Examples 6-1 to 6-4 were measured, and results of the measurement are shown in Table 7 below and FIGS. 7A to 7D.

FIGS. 7A to 7C are a graph showing the radiant power of color conversion films according to Manufacturing Examples 6-1 and 6-2.

Further, FIG. 7D is a photograph obtained by observing a photoluminescence and DC-GROND color conversion film of a DC-GROND solution according to Manufacturing Example 6-1 in an ultraviolet (UV) lamp.

TABLE 7

| | Organic | | | Blue light |
|---|---|---|---|---|
| | nano-dots | TiO₂ | CCE | reduction rate |
| | (wt %) | (wt %) | (%) | (%) |
| Manufacturing | 3.07 | 3.03 | 83.90 | 64.27 |
| Example 6-1 | | | | |
| Manufacturing | 3.07 | 3.06 | 83.26 | 62.10 |
| Example 6-2 | | | | |
| Manufacturing | 4.00 | 7.31 | 75.50 | 75.74 |
| Example 6-3 | | | | |
| Manufacturing | 4.00 | 7.31 | 67.00 | 73.22 |
| Example 6-4 | | | | |

Referring to Table 7 and FIGS. 7A to 7D, it can be seen that the DC-GRONDs emit all of red, green, and blue light to show white light. The blue light reduction rate exceeds 60% in all the examples, and the CCE is also high. In the case of using 70% of the first organic phosphor, the blue light reduction rate may be adjusted by the content of DC-GRONDs and the content of TiO₂ rather than the ratio of the green phosphor and the red phosphor, and when the blue light reduction rate is high, the CCE tends to decrease. Since the green and red emission intensity may be adjusted by changing the content of the green and red light-emitting materials, it is possible to prepare DC-GRONDs with the content of blue/green/red phosphors adjusted according to the required properties.

According to the present invention, it is possible to provide a color conversion film having excellent photochemical stability, high CCE, high heat resistance, high film hardness, high uniformity, and long-lasting performance using light-emitting down conversion organic nano-dots. In particular, light-emitting down conversion organic nano-dots that do not use quantum dots are used in the color conversion film of the present invention, and thus environmental pollution problems can be prevented.

Effects of the present invention are not limited to the above-described effects, and it should be understood that all possible effects deduced from the configuration of the present invention described in detailed descriptions and the claims are included.

The above description of this specification is only exemplary, and it will be understood by those skilled in the art to which one aspect of this specification pertains that various modifications can be made without departing from the technical scope of the present invention and without changing essential features described in this specification. Therefore, the above-described embodiments should be considered in a descriptive sense only and not for purposes of limitation. For example, each component described as a single type may be implemented in a distributed manner, and similarly, components that are described as being distributed may be implemented in a coupled manner.

The scope of the present invention is defined not by the detailed description but by the appended claims and encompasses all modifications or alterations derived from meanings, the scope, and equivalents of the appended claims.

What is claimed is:

1. Light-emitting down conversion organic nano-dots containing a first organic phosphor and a second organic phosphor,
wherein the first organic phosphor has a molar extinction coefficient (E) of 10,000 L/mol·cm or more at a wavelength of 450 nm, and
an emission spectrum of the first organic phosphor overlaps an absorption spectrum of the second organic phosphor.

2. The light-emitting down conversion organic nano-dots of claim 1, wherein a Forster radius (R_{O}) between the first and second organic phosphors is 7.0 nm or less.

3. The light-emitting down conversion organic nano-dots of claim 1, wherein a weight ratio of the first and second organic phosphors ranges from 5.0:5.0 to 9.5:0.5.

4. The light-emitting down conversion organic nano-dots of claim 1, wherein the light-emitting down conversion organic nano-dots have an average particle size of 100 to 170 nm, and a standard deviation of the particle sizes of 500 nm or less.

5. The light-emitting down conversion organic nano-dots of claim 1, wherein the light-emitting down conversion organic nano-dots have a core-shell structure in which the first and second organic phosphors are surrounded by a surfactant.

6. The light-emitting down conversion organic nano-dots of claim 5, wherein the surfactant is one or more selected from the group consisting of an anionic surfactant, a cationic surfactant, an amphoteric surfactant, and a nonionic surfactant.

7. The light-emitting down conversion organic nano-dots of claim 1, wherein a photoluminescence quantum yield (PLQY) of the first organic phosphor is 50% or more.

8. The light-emitting down conversion organic nano-dots of claim 1, wherein the first organic phosphor is one or more selected from the group consisting of compounds BB-1 to BB-11, BD-1 to BD-9, BM-1 to BM-12, BPer-1 to BPer-20, and BPyr-1 to BPyr-11 below:

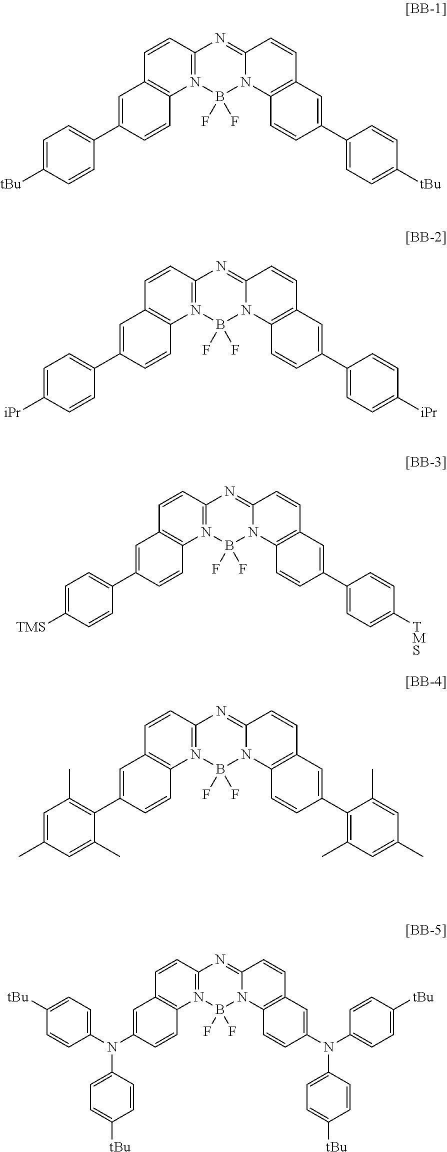

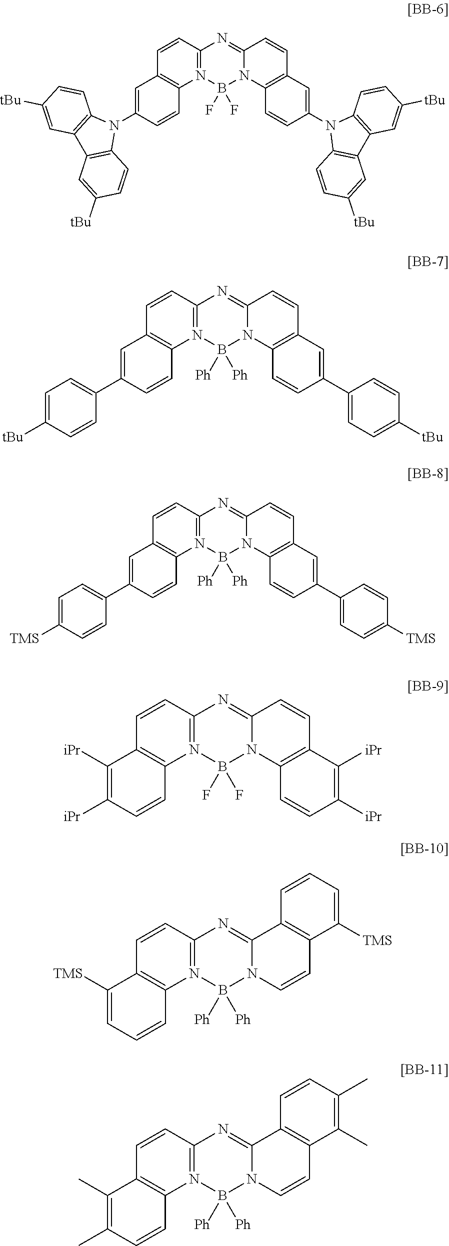

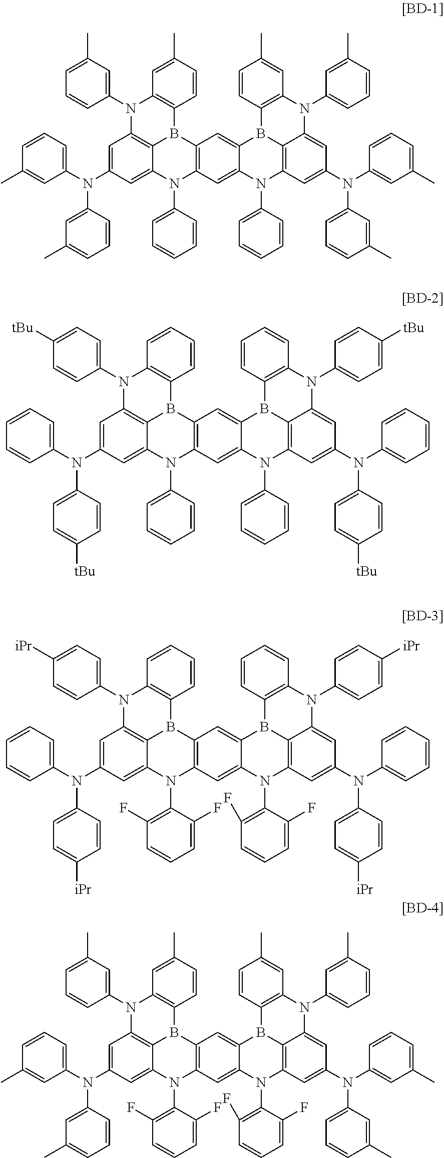

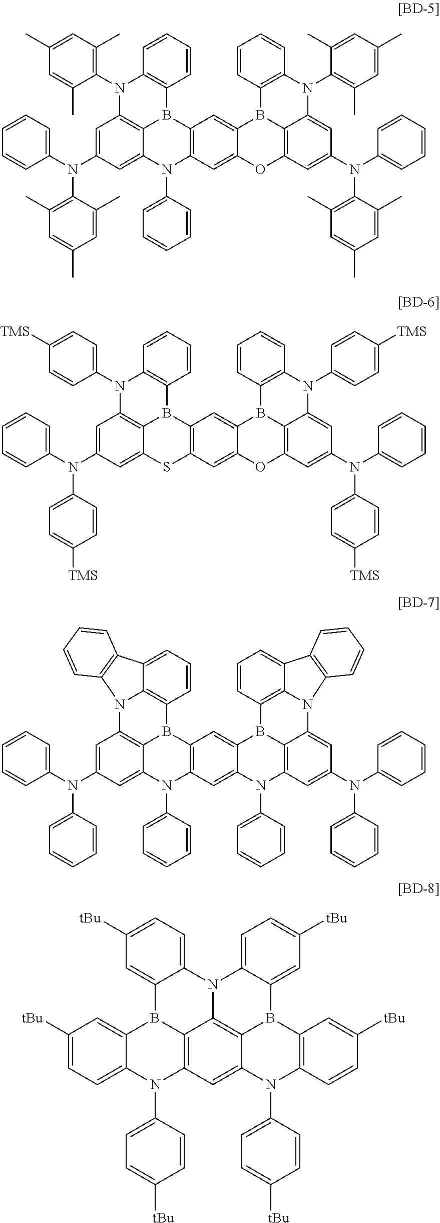

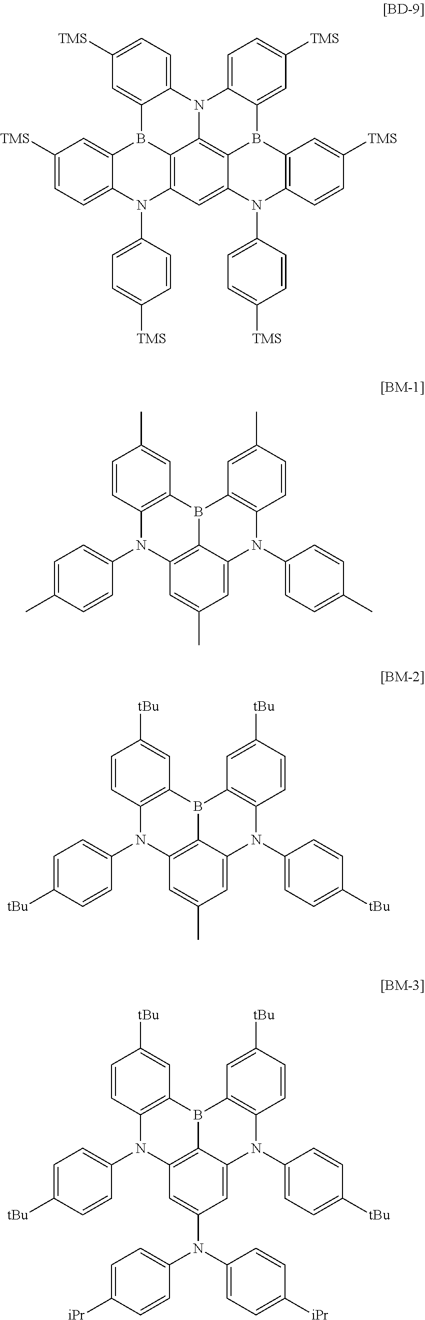

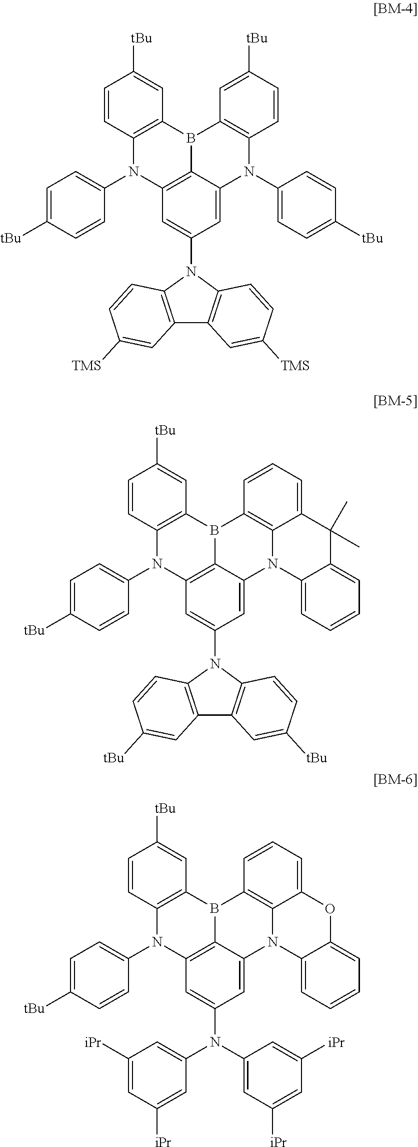 [SMILES: CC(C)(C)c1ccc(N2c3ccc(C(C)(C)C)cc3B3c4cc(C(C)(C)C)ccc4N(c4ccc(C(C)(C)C)cc4)c4cc(-n5c6ccc([Si](C)(C)C)cc6c6cc([Si](C)(C)C)ccc65)cc2c43)cc1 ; CC(C)(C)c1ccc(N2c3ccc(C(C)(C)C)cc3B3c4cccc5c4N(c4ccccc4C5(C)C)c4cc(-n5c6ccc(C(C)(C)C)cc6c6cc(C(C)(C)C)ccc65)cc2c43)cc1 ; CC(C)c1cc(C(C)C)cc(N(c2cc(C(C)C)cc(C(C)C)c2)c2cc3c4c(c2)N2c5ccccc5Oc5cccc(c52)B4c2cc(C(C)(C)C)ccc2N3c2ccc(C(C)(C)C)cc2)c1]

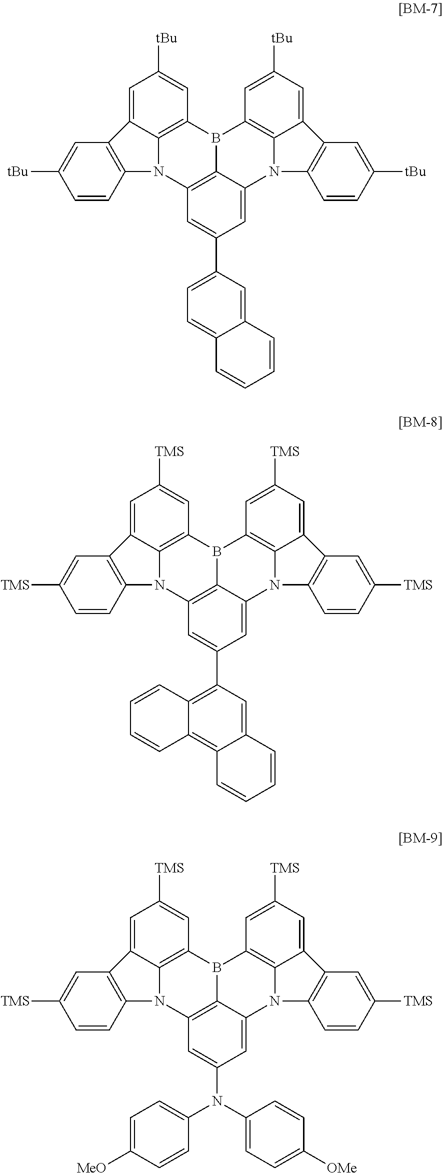 [SMILES: CC(C)(C)c1ccc2c(c1)c1cc(C(C)(C)C)cc3c1n2-c1cc(-c2ccc4ccccc4c2)cc2c1B3c1cc(C(C)(C)C)cc3c4cc(C(C)(C)C)ccc4n-2c13 ; C[Si](C)(C)c1ccc2c(c1)c1cc([Si](C)(C)C)cc3c1n2-c1cc(-c2cc4ccccc4c4ccccc24)cc2c1B3c1cc([Si](C)(C)C)cc3c4cc([Si](C)(C)C)ccc4n-2c13 ; COc1ccc(N(c2ccc(OC)cc2)c2cc3c4c(c2)-n2c5ccc([Si](C)(C)C)cc5c5cc([Si](C)(C)C)cc(c52)B4c2cc([Si](C)(C)C)cc4c5cc([Si](C)(C)C)ccc5n-3c24)cc1]

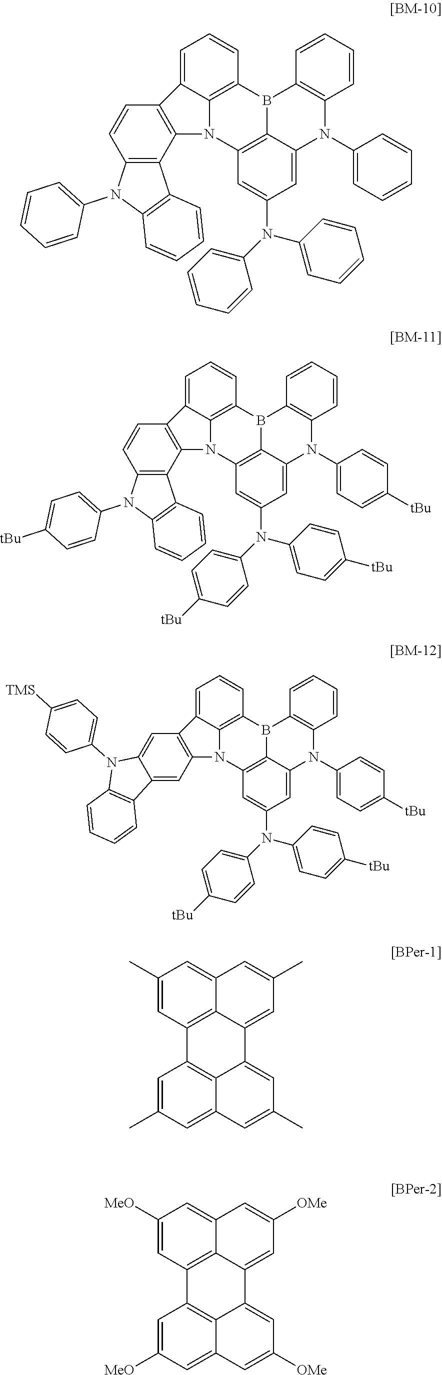

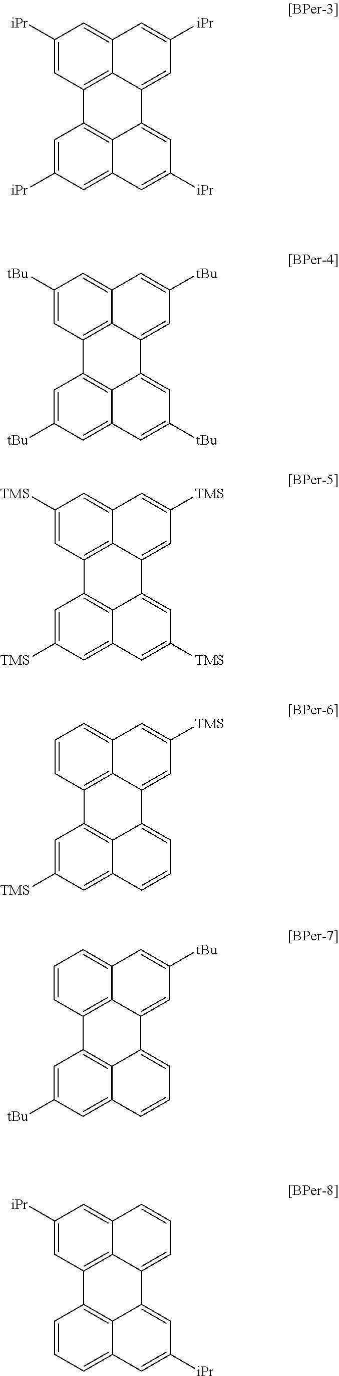

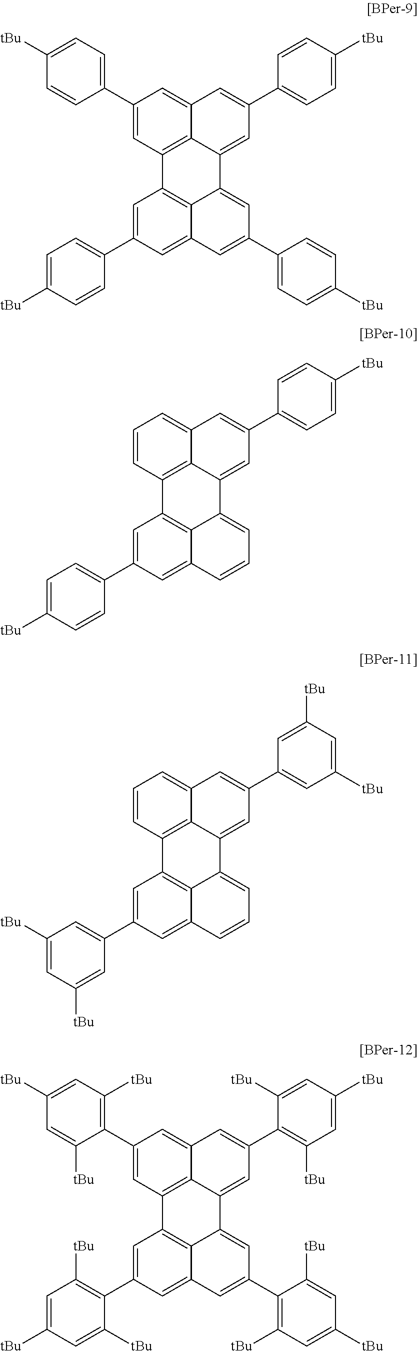

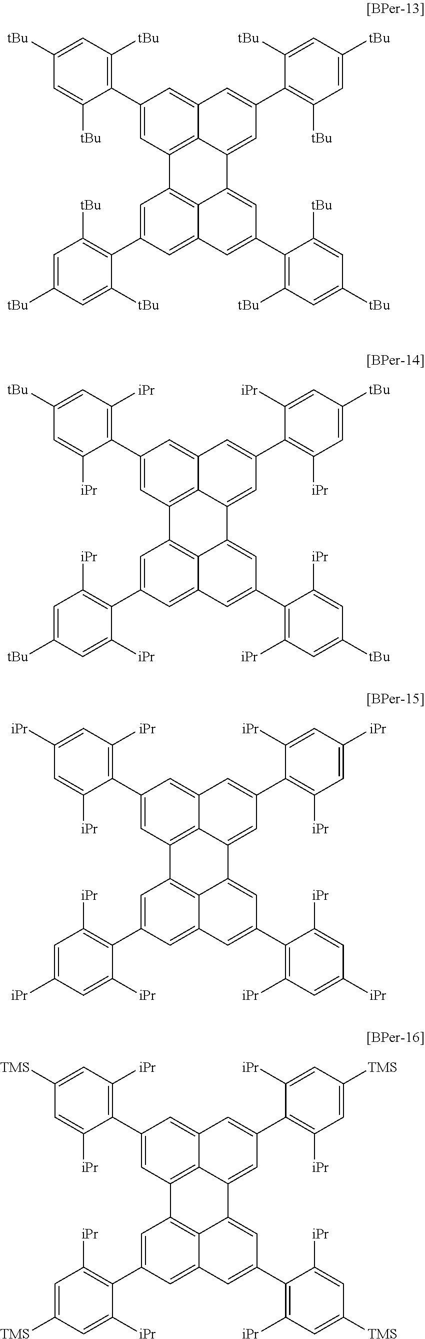

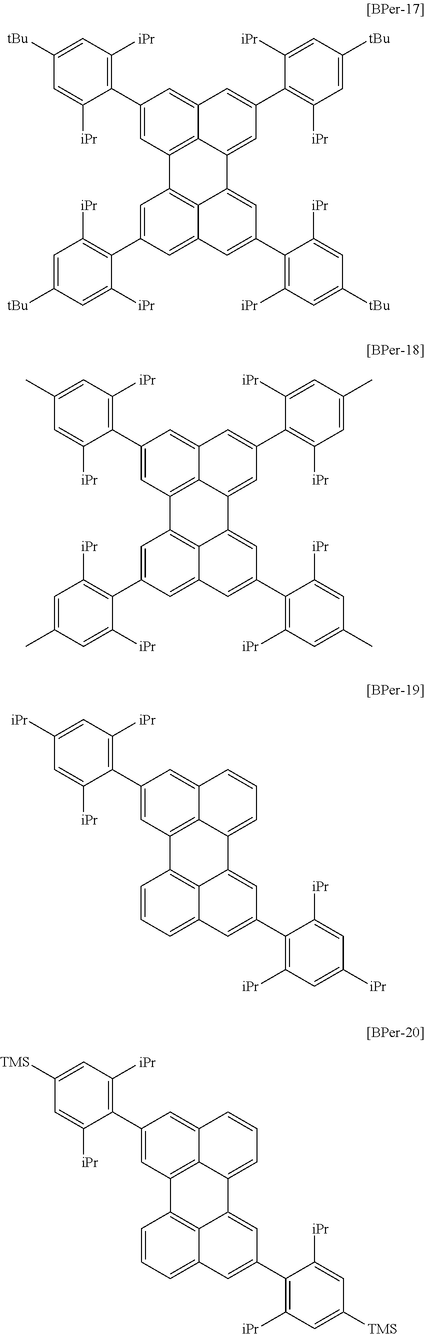

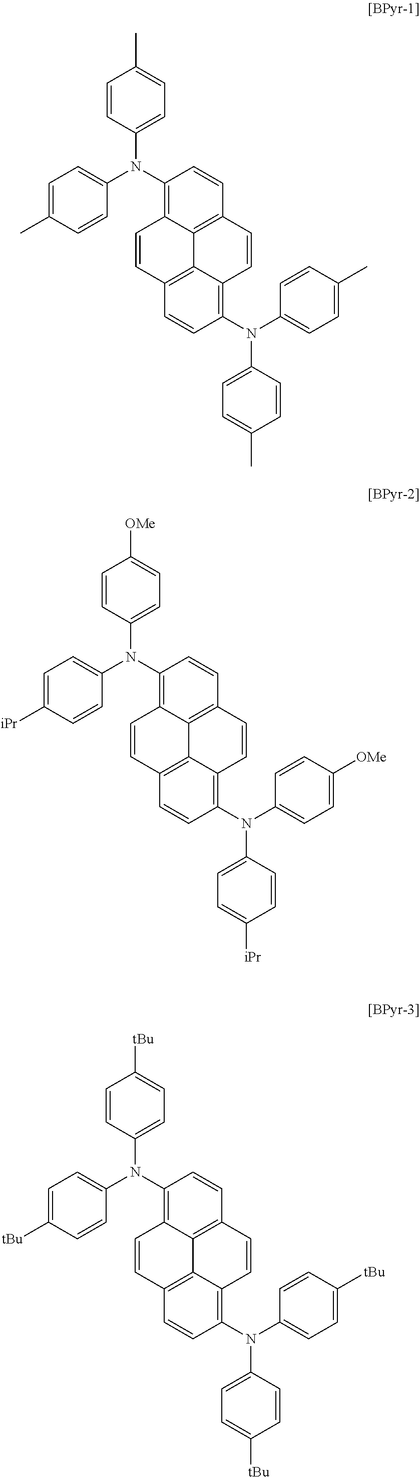

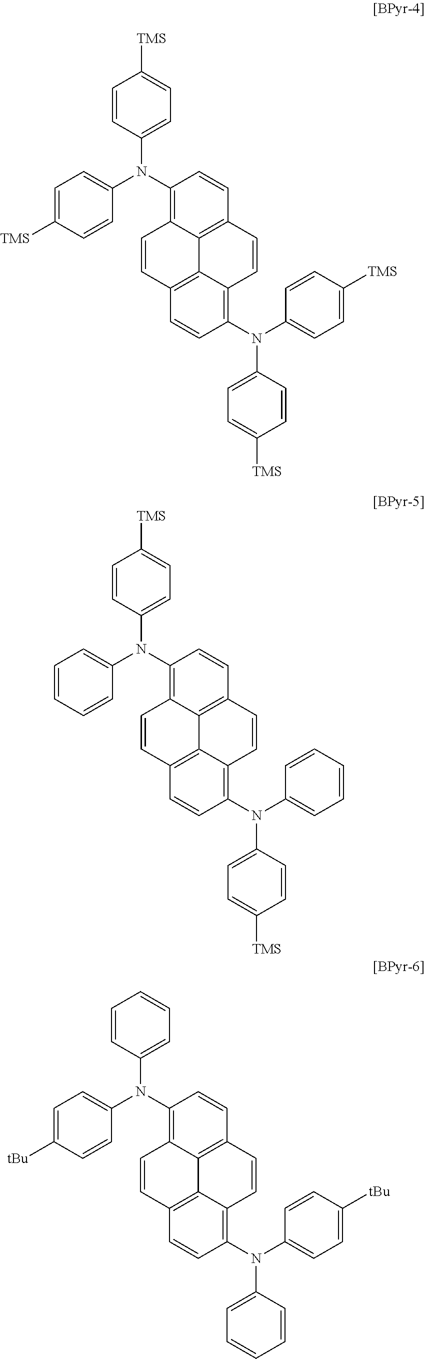 [SMILES: C[Si](C)(C)c1ccc(N(c2ccc([Si](C)(C)C)cc2)c2ccc3ccc4c(N(c5ccc([Si](C)(C)C)cc5)c5ccc([Si](C)(C)C)cc5)ccc5ccc2c3c54)cc1 ; C[Si](C)(C)c1ccc(N(c2ccccc2)c2ccc3ccc4c(N(c5ccccc5)c5ccc([Si](C)(C)C)cc5)ccc5ccc2c3c54)cc1 ; CC(C)(C)c1ccc(N(c2ccccc2)c2ccc3ccc4c(N(c5ccccc5)c5ccc(C(C)(C)C)cc5)ccc5ccc2c3c54)cc1]

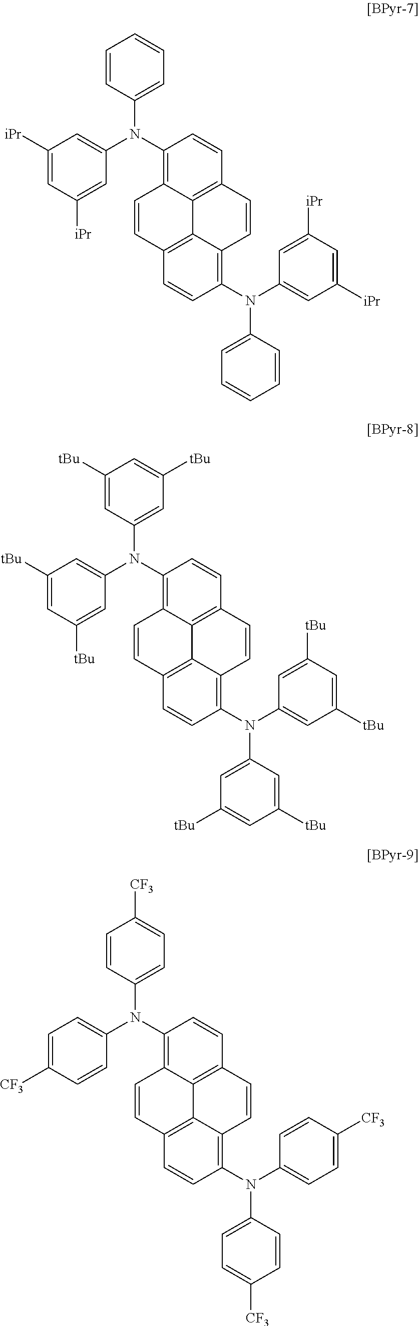 [SMILES: CC(C)c1cc(C(C)C)cc(N(c2ccccc2)c2ccc3ccc4c(N(c5ccccc5)c5cc(C(C)C)cc(C(C)C)c5)ccc5ccc2c3c54)c1 ; CC(C)(C)c1cc(N(c2cc(C(C)(C)C)cc(C(C)(C)C)c2)c2ccc3ccc4c(N(c5cc(C(C)(C)C)cc(C(C)(C)C)c5)c5cc(C(C)(C)C)cc(C(C)(C)C)c5)ccc5ccc2c3c54)cc(C(C)(C)C)c1 ; FC(F)(F)c1ccc(N(c2ccc(C(F)(F)F)cc2)c2ccc3ccc4c(N(c5ccc(C(F)(F)F)cc5)c5ccc(C(F)(F)F)cc5)ccc5ccc2c3c54)cc1]

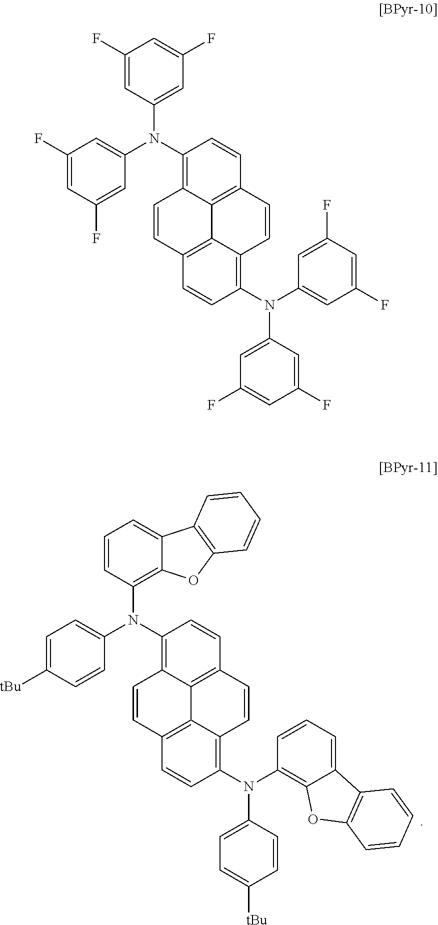 [SMILES: Fc1cc(F)cc(N(c2cc(F)cc(F)c2)c2ccc3ccc4c(N(c5cc(F)cc(F)c5)c5cc(F)cc(F)c5)ccc5ccc2c3c54)c1 ; CC(C)(C)c1ccc(N(c2ccc3ccc4c(N(c5ccc(C(C)(C)C)cc5)c5cccc6c5oc5ccccc56)ccc5ccc2c3c54)c2cccc3c2oc2ccccc23)cc1]

9. The light-emitting down conversion organic nano-dots of claim 1, wherein the second organic phosphor is a delayed fluorescence material.

10. The light-emitting down conversion organic nano-dots of claim 9, wherein the delayed fluorescence material includes a compound represented by Chemical Formula 1 below: 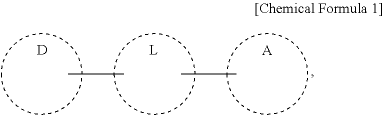
in Chemical Formula 1 above,
L is any one selected from the group consisting of an aryl group, an arylene group, and a carbon-nitrogen single bond,
when L is an aryl group, A is a cyano group mono- or di-substituted on the aryl group, and D is a substituent tetra- or penta-substituted on the aryl group, wherein each substituent is independently a heteroaryl group containing a nitrogen atom substituted or unsubstituted with a heteroaryl group having 1 to 10 carbon atoms,
when L is an arylene group, A is a substituted or unsubstituted triazine group, and D is a substituted or unsubstituted multi-fused ring, including a conjugated or non-conjugated five-membered or six-membered ring containing a nitrogen atom bonded to the arylene group, wherein the multi-fused ring may further comprise 1 to 9 nitrogen atoms or one Group 16 element as ring-forming elements, in addition to the nitrogen atom boned to the arylene group,
when L is a carbon-nitrogen single bond, D is a fused ring having 10 to 40 carbon atoms, including a conjugated or non-conjugated five-membered or six-membered ring containing the nitrogen atom of the L, wherein the conjugated or non-conjugated five-membered or six-membered ring is a substituted or unsubstituted ring, does not contain or contains a Group 16 element as ring-forming elements, and contains 1 or 2 nitrogen atoms as ring-forming elements, and A is a heterocyclic ring having 10 to 40 carbon atoms, including an aryl group containing a carbon atom bonded to the L, wherein the heterocyclic ring includes a ring structure forming a fused ring with the aryl group containing a carbon atom bonded to the L, and wherein the ring structure is a ring structure containing a boron atom and an oxygen atom as ring-forming elements, or is a five-membered or six-membered ring structure containing two conjugated nitrogen atoms.

11. The light-emitting down conversion organic nano-dots of claim 10, wherein the compound represented by Chemical Formula 1 above is one or more selected from the group consisting of compounds T-1 to T-28 below:

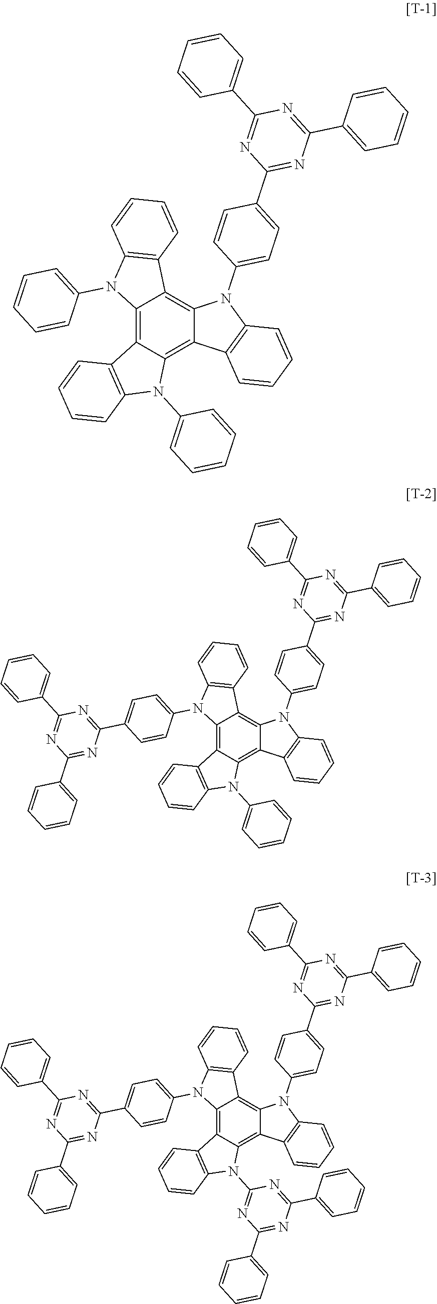 [SMILES: c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1 ; c1ccc(-c2nc(-c3ccccc3)nc(-c3ccc(-n4c5ccccc5c5c6c(c7ccccc7n6-c6ccccc6)c6c(c7ccccc7n6-c6ccc(-c7nc(-c8ccccc8)nc(-c8ccccc8)n7)cc6)c54)cc3)n2)cc1 ; c1ccc(-c2nc(-c3ccccc3)nc(-c3ccc(-n4c5ccccc5c5c4c4c6ccccc6n(-c6nc(-c7ccccc7)nc(-c7ccccc7)n6)c4c4c6ccccc6n(-c6ccc(-c7nc(-c8ccccc8)nc(-c8ccccc8)n7)cc6)c54)cc3)n2)cc1]

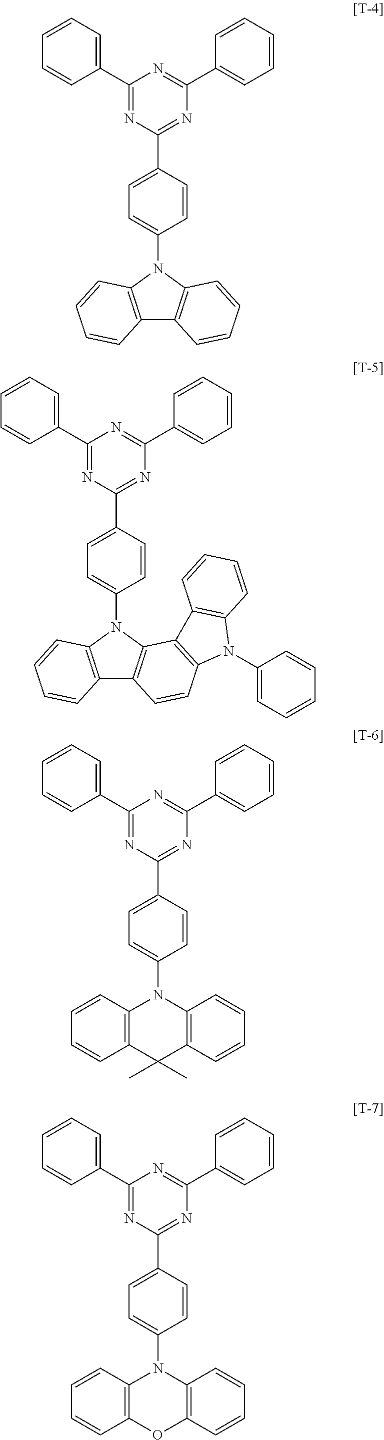

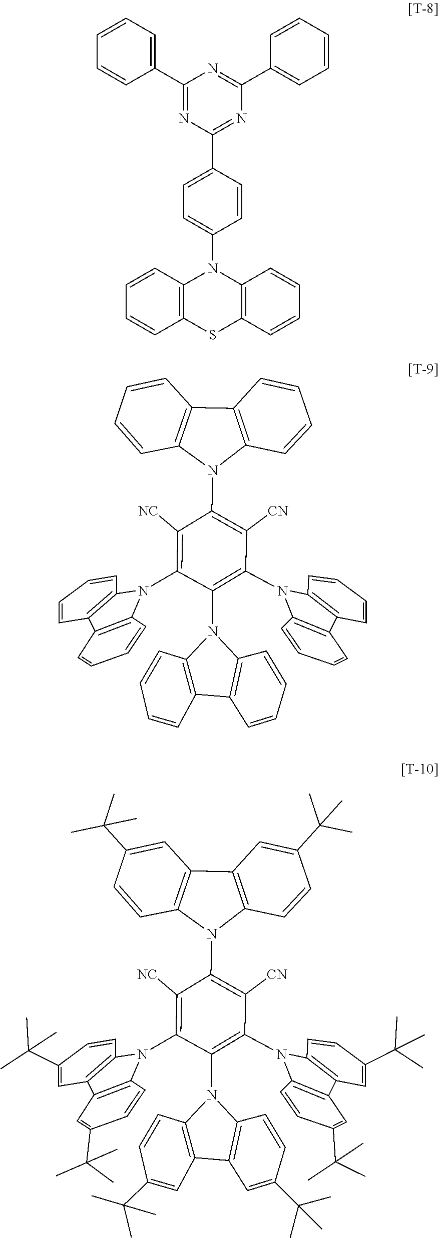

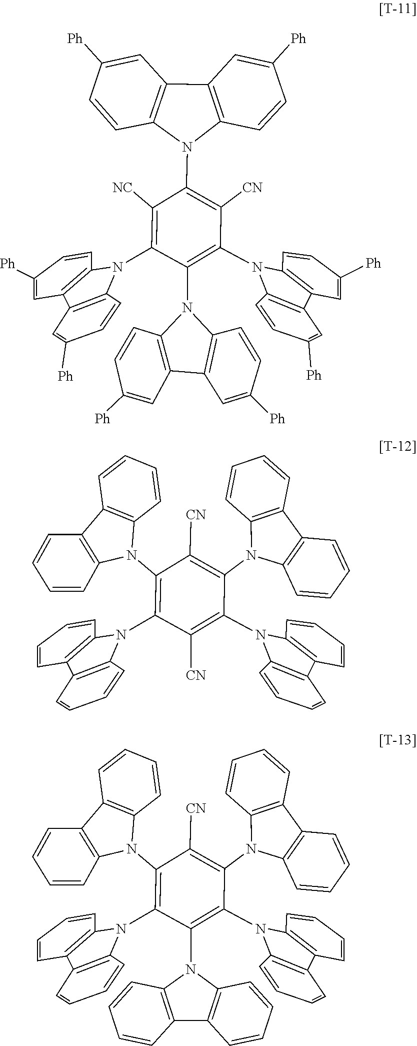

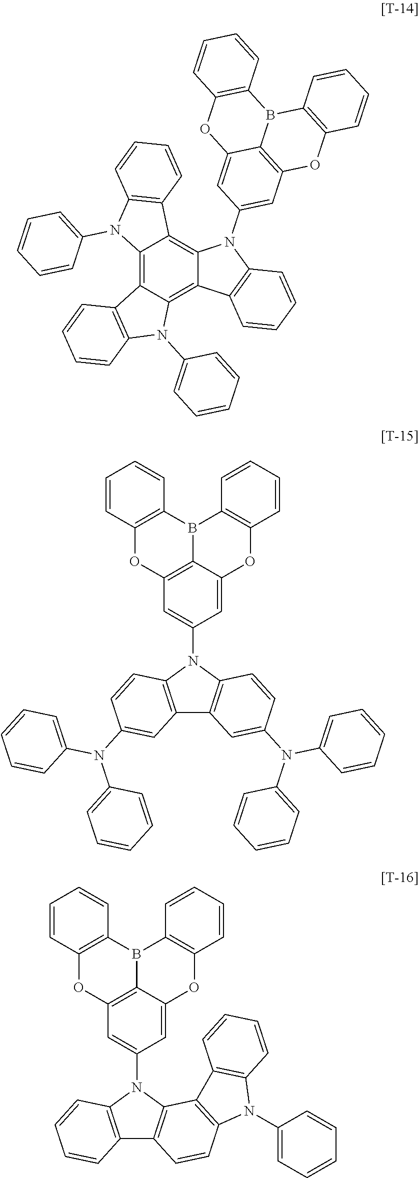 [SMILES: c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1 ; c1ccc(N(c2ccccc2)c2ccc3c(c2)c2cc(N(c4ccccc4)c4ccccc4)ccc2n3-c2cc3c4c(c2)Oc2ccccc2B4c2ccccc2O3)cc1 ; c1ccc(-n2c3ccccc3c3c2ccc2c4ccccc4n(-c4cc5c6c(c4)Oc4ccccc4B6c4ccccc4O5)c23)cc1]

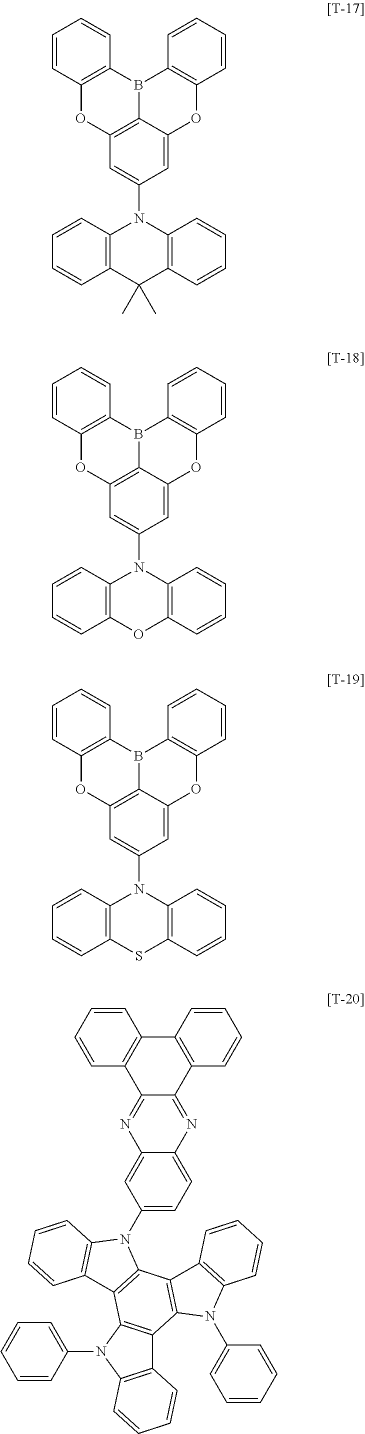 [SMILES: CC1(C)c2ccccc2N(c2cc3c4c(c2)Oc2ccccc2B4c2ccccc2O3)c2ccccc21 ; c1ccc2c(c1)Oc1cc(N3c4ccccc4Oc4ccccc43)cc3c1B2c1ccccc1O3 ; c1ccc2c(c1)Oc1cc(N3c4ccccc4Sc4ccccc43)cc3c1B2c1ccccc1O3 ; c1ccc(-n2c3ccccc3c3c2c2c4ccccc4n(-c4ccc5nc6c7ccccc7c7ccccc7c6nc5c4)c2c2c4ccccc4n(-c4ccccc4)c32)cc1]

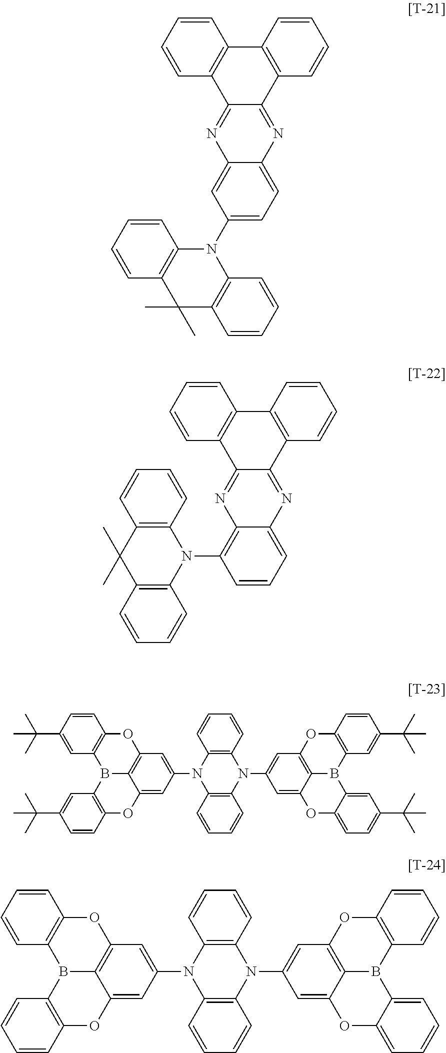 [SMILES: CC1(C)c2ccccc2N(c2ccc3nc4c5ccccc5c5ccccc5c4nc3c2)c2ccccc21 ; CC1(C)c2ccccc2N(c2cccc3nc4c5ccccc5c5ccccc5c4nc23)c2ccccc21 ; CC(C)(C)c1ccc2c(c1)B1c3cc(C(C)(C)C)ccc3Oc3cc(N4c5ccccc5N(c5cc6c7c(c5)Oc5ccc(C(C)(C)C)cc5B7c5cc(C(C)(C)C)ccc5O6)c5ccccc54)cc(c31)O2 ; c1ccc2c(c1)Oc1cc(N3c4ccccc4N(c4cc5c6c(c4)Oc4ccccc4B6c4ccccc4O5)c4ccccc43)cc3c1B2c1ccccc1O3]

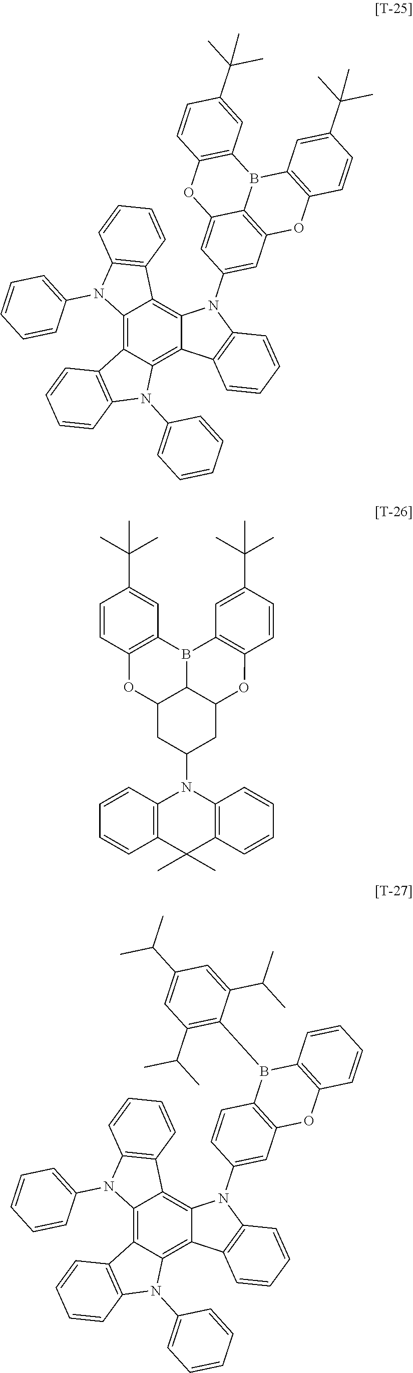

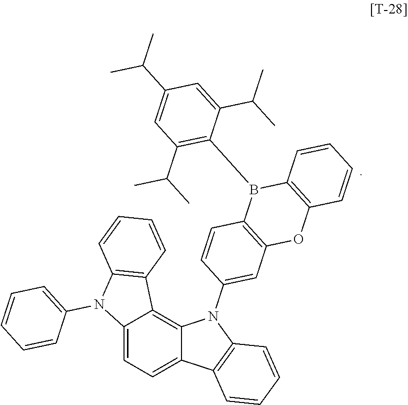 [SMILES: CC(C)c1cc(C(C)C)c(CB2c3ccccc3Oc3cc(-n4c5ccccc5c5ccc6c(c7ccccc7n6-c6ccccc6)c54)ccc32)c(C(C)C)c1]

12. The light-emitting down conversion organic nano-dots of claim 1, wherein the second organic phosphor includes a boron compound represented by Chemical Formula 2 below: 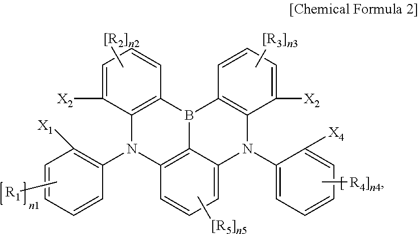
in Chemical Formula 2 above, R₁ to R₅ each independently correspond to at least one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,
X₁ to X₄ are each independently hydrogen, hydroxyl group or a substituted or unsubstituted alkyl group,
n1 and n4 are each independently an integer of 1 to 4,
n2, n3 and n5 are each independently an integer of 1 to 3,
if n1 to n5 are 2 or more, the structures in the brackets, are the same or different, respectively,
R₁ to R₅ and X₁ to X₄ may bond to adjacent substituents to form a substituted or unsubstituted ring.

13. The light-emitting down conversion organic nano-dots of claim 12, wherein the boron compound represented by Chemical Formula 2 above is one or more selected from the group consisting of compounds D-1 to D-30 below:

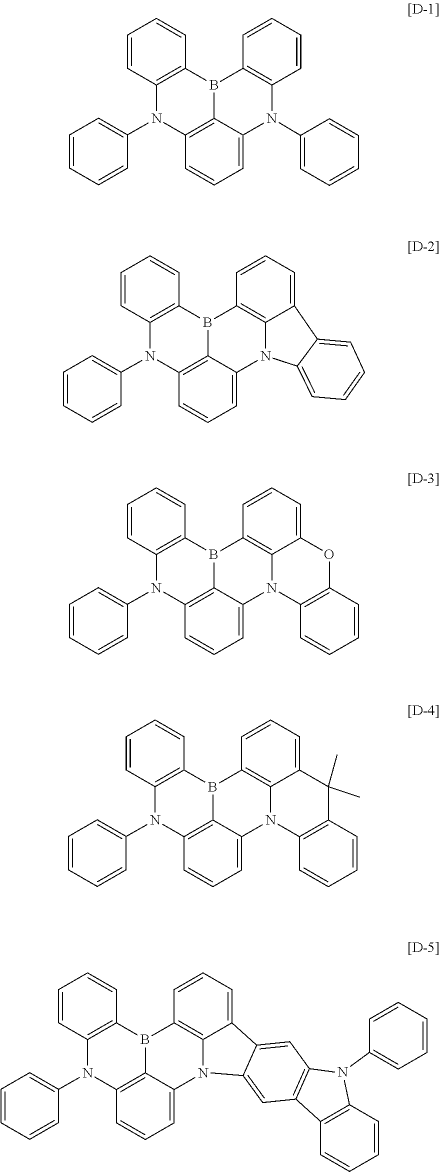 [SMILES: c1ccc(N2c3ccccc3B3c4ccccc4N(c4ccccc4)c4cccc2c43)cc1 ; c1ccc(N2c3ccccc3B3c4c2cccc4-n2c4ccccc4c4cccc3c42)cc1 ; c1ccc(N2c3ccccc3B3c4cccc5c4N(c4ccccc4O5)c4cccc2c43)cc1 ; CC1(C)c2ccccc2N2c3cccc4c3B(c3ccccc3N4c3ccccc3)c3cccc1c32 ; c1ccc(N2c3ccccc3B3c4c2cccc4-n2c4cc5c6ccccc6n(-c6ccccc6)c5cc4c4cccc3c42)cc1]

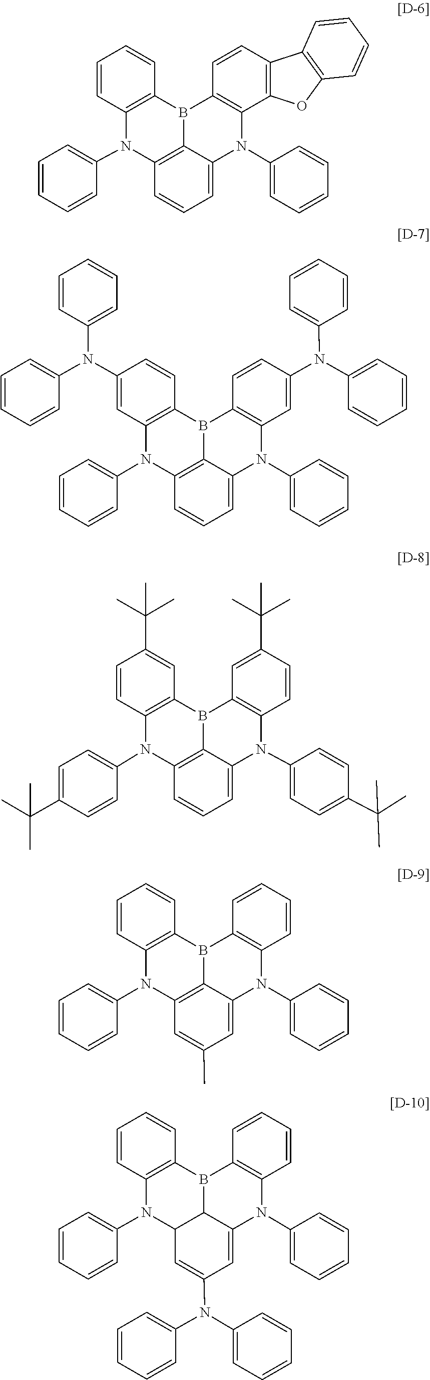 [SMILES: c1ccc(N2c3ccccc3B3c4ccc5c(oc6ccccc65)c4N(c4ccccc4)c4cccc2c43)cc1 ; c1ccc(N(c2ccccc2)c2ccc3c(c2)N(c2ccccc2)c2cccc4c2B3c2ccc(N(c3ccccc3)c3ccccc3)cc2N4c2ccccc2)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1 ; Cc1cc2c3c(c1)N(c1ccccc1)c1ccccc1B3c1ccccc1N2c1ccccc1 ; C1=C(N(c2ccccc2)c2ccccc2)C=C2C3B(c4ccccc4N2c2ccccc2)c2ccccc2N(c2ccccc2)C13]

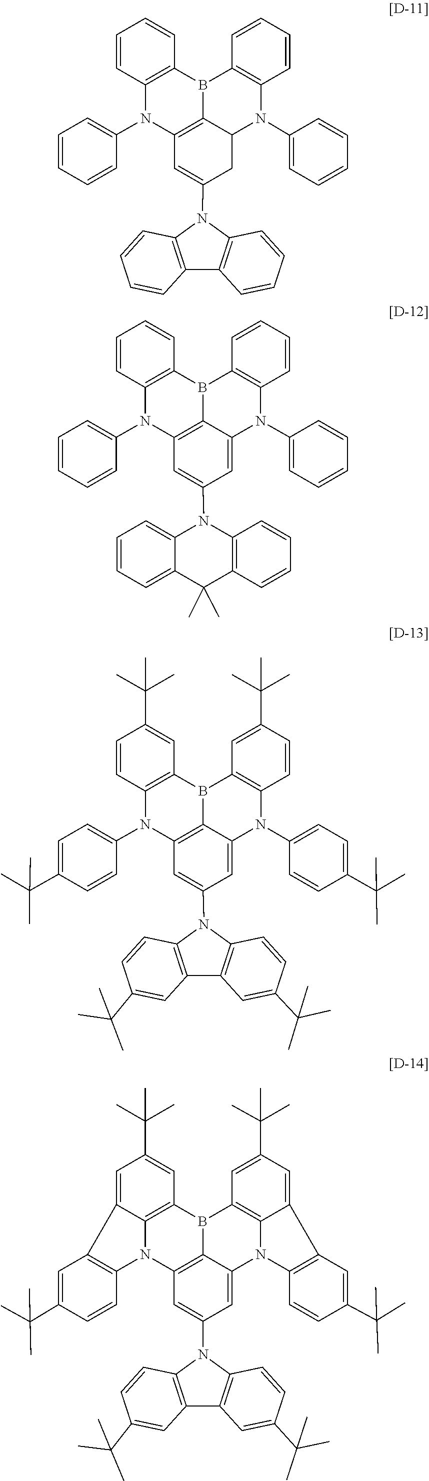

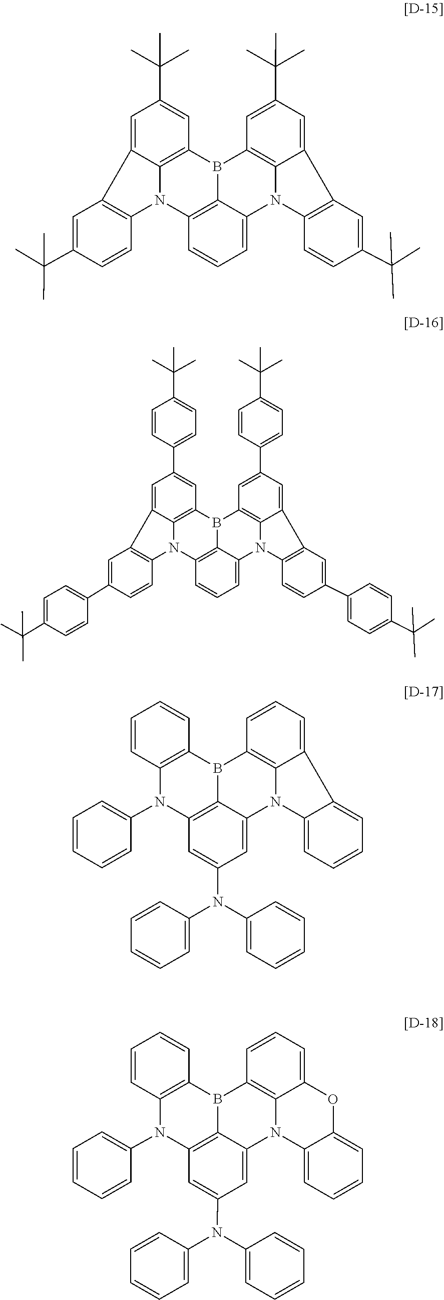

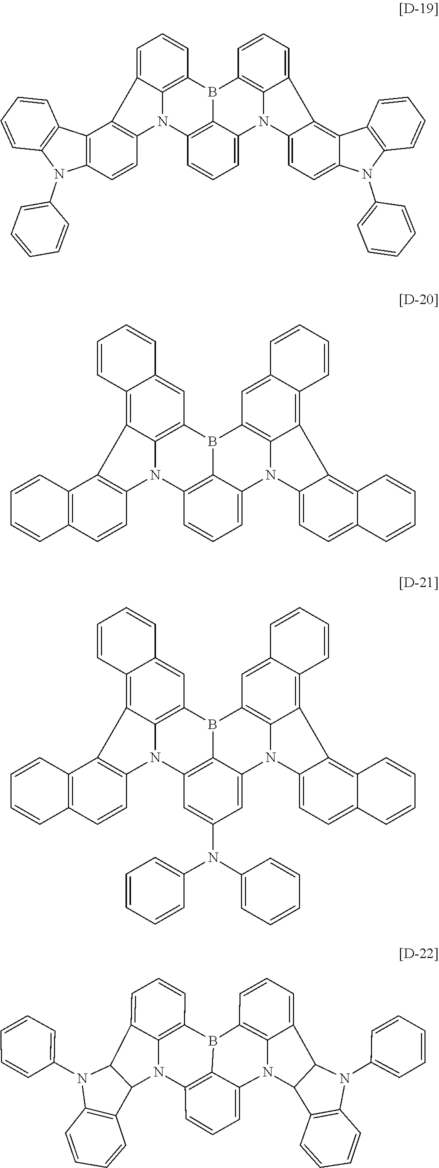 [SMILES: c1ccc(-n2c3ccccc3c3c4c5cccc6c5n(c4ccc32)-c2cccc3c2B6c2cccc4c5c6c7ccccc7n(-c7ccccc7)c6ccc5n-3c24)cc1 ; c1cc2c3c(c1)-n1c4ccc5ccccc5c4c4c5ccccc5cc(c41)B3c1cc3ccccc3c3c4c5ccccc5ccc4n-2c13 ; c1ccc(N(c2ccccc2)c2cc3c4c(c2)-n2c5ccc6ccccc6c5c5c6ccccc6cc(c52)B4c2cc4ccccc4c4c5c6ccccc6ccc5n-3c24)cc1 ; c1ccc(N2c3ccccc3C3C2c2cccc4c2N3c2cccc3c2B4c2cccc4c2N3C2c3ccccc3N(c3ccccc3)C42)cc1]

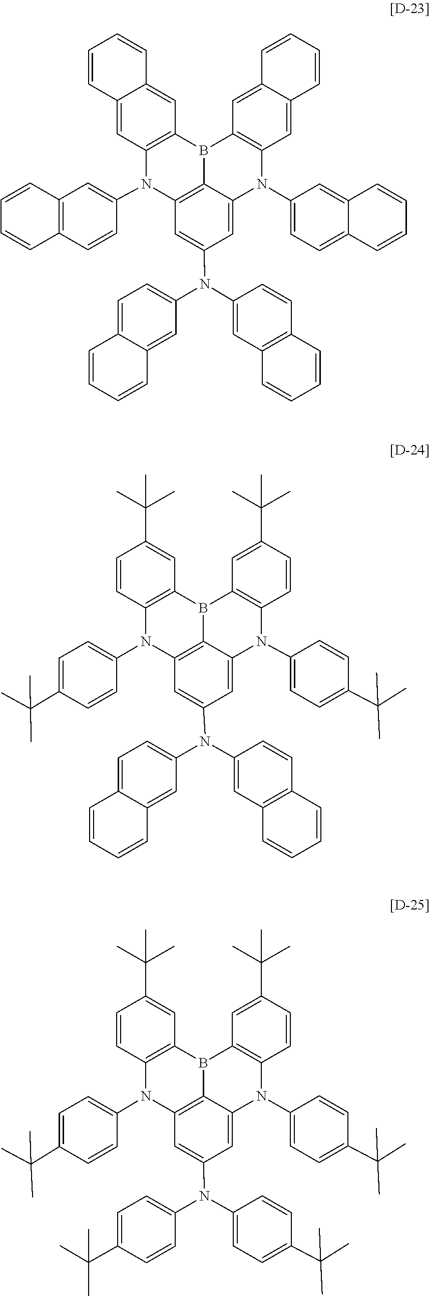

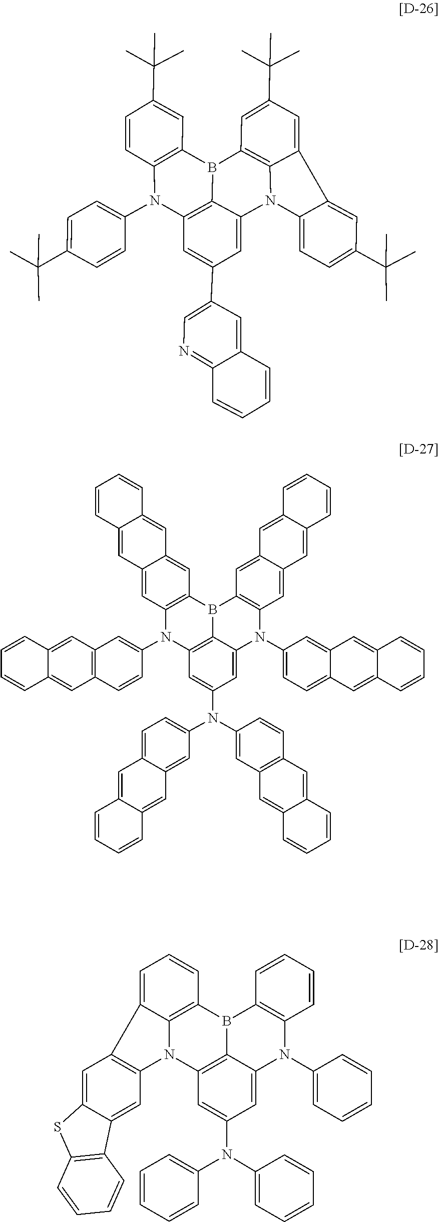 [SMILES: CC(C)(C)c1ccc(N2c3ccc(C(C)(C)C)cc3B3c4c2cc(-c2cnc5ccccc5c2)cc4-n2c4ccc(C(C)(C)C)cc4c4cc(C(C)(C)C)cc3c42)cc1 ; c1ccc2cc3cc(N(c4cc5c6c(c4)N(c4ccc7cc8ccccc8cc7c4)c4cc7cc8ccccc8cc7cc4B6c4cc6cc7ccccc7cc6cc4N5c4ccc5cc6ccccc6cc5c4)c4ccc5cc6ccccc6cc5c4)ccc3cc2c1 ; c1ccc(N(c2ccccc2)c2cc3c4c(c2)-n2c5cc6c(cc5c5cccc(c52)B4c2ccccc2N3c2ccccc2)sc2ccccc26)cc1]

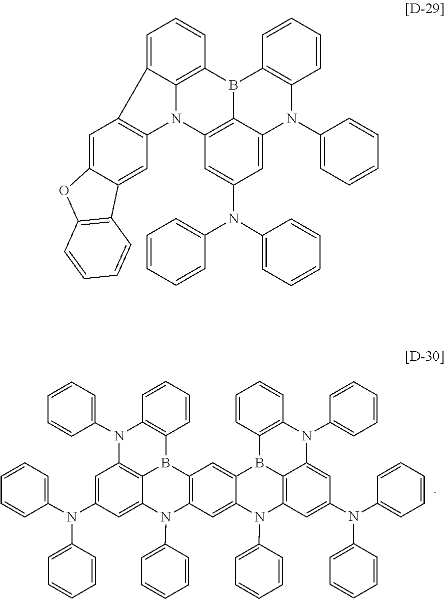 [SMILES: c1ccc(N(c2ccccc2)c2cc3c4c(c2)-n2c5cc6c(cc5c5cccc(c52)B4c2ccccc2N3c2ccccc2)oc2ccccc26)cc1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1]

14. The light-emitting down conversion organic nano-dots of claim 1, wherein the second organic phosphor includes a boron compound represented by Chemical Formula 3 below: 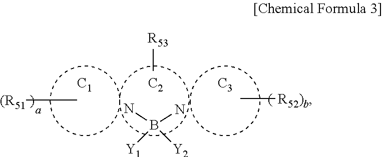
in Chemical Formula 3 above,
C₁ to C₃ each have a five-membered or six-membered ring structure,
R₅₁ and R₅₂ each independently correspond to at least any one selected from the group consisting of hydrogen, deuterium, a halogen group, a hydroxyl group, a cyano group, a nitro group, a substituted or unsubstituted amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted thioether group, a substituted or unsubstituted cycloalkyl group, a substituted or unsubstituted cycloalkenyl group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group,
R₅₃ corresponds to any one selected from the group consisting of hydrogen, deuterium, a halogen group, a hydroxyl group, a cyano group, a nitro group, an amino group, an amidino group, a hydrazino group, a hydrazono group, a substituted or unsubstituted alkyl group, a substituted or unsubstituted alkenyl group, a substituted or unsubstituted alkynyl group, a substituted or unsubstituted alkoxy group, a substituted or unsubstituted cycloalkyl group, a substituted or unsubstituted cycloalkenyl group, a substituted or unsubstituted thioether group, a substituted or unsubstituted heterocycloalkyl group, a substituted or unsubstituted heterocycloalkenyl group, a substituted or unsubstituted aryl group, a substituted or unsubstituted aryloxy group, a substituted or unsubstituted heteroaryl group, and a substituted or unsubstituted heteroaryloxy group,
Y₁ and Y₂ are each independently a fluorine group or an alkoxy group,
a and b are each independently an integer of 1 to 4,
if a and b are 2 or more, the structures in the brackets, are the same or different, respectively,
R₅₁ and R₅₂ may bond to adjacent substituents to form a substituted or unsubstituted ring.

15. The light-emitting down conversion organic nano-dots of claim 14, wherein the boron compound represented by Chemical Formula 3 above is one or more selected from the group consisting of compounds B-1 to B-51 below:

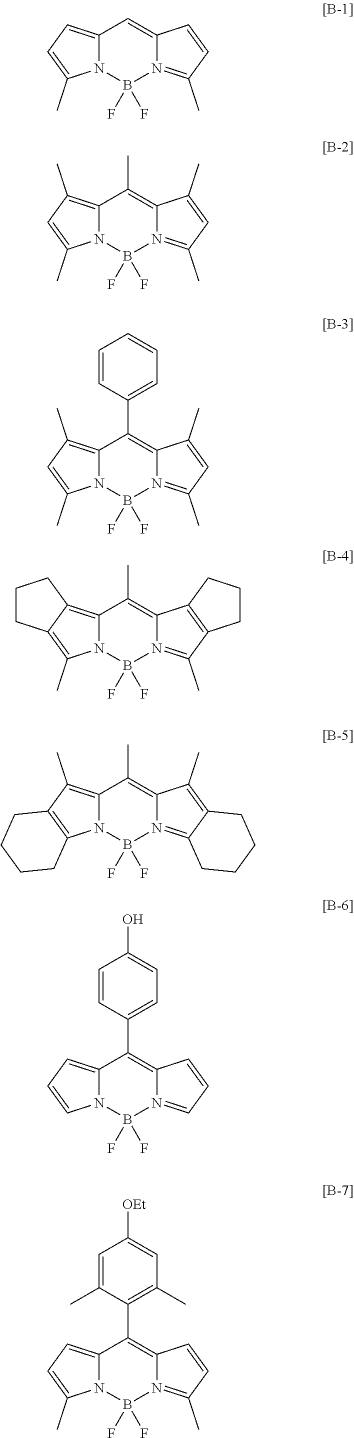

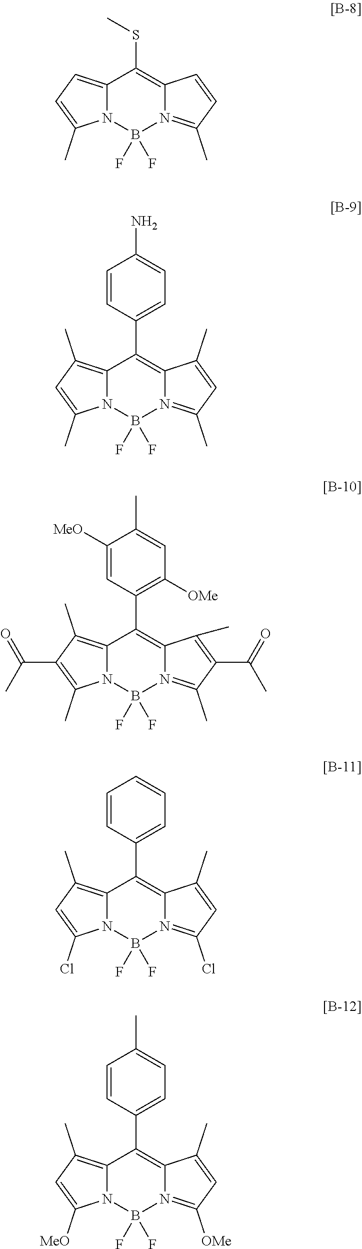

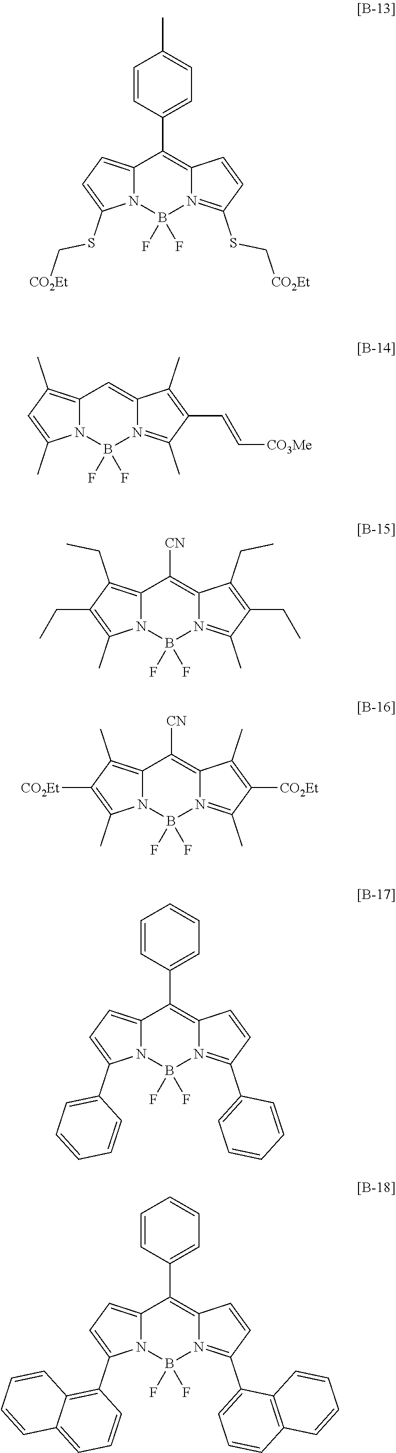

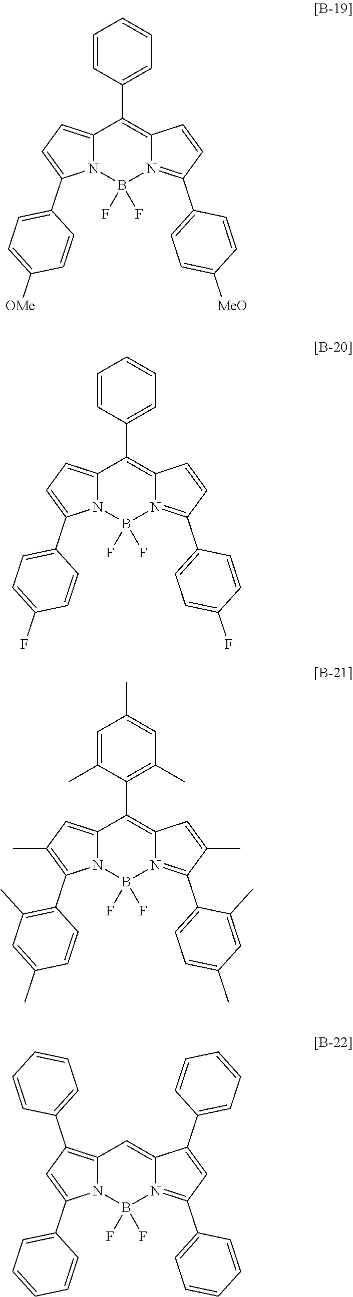

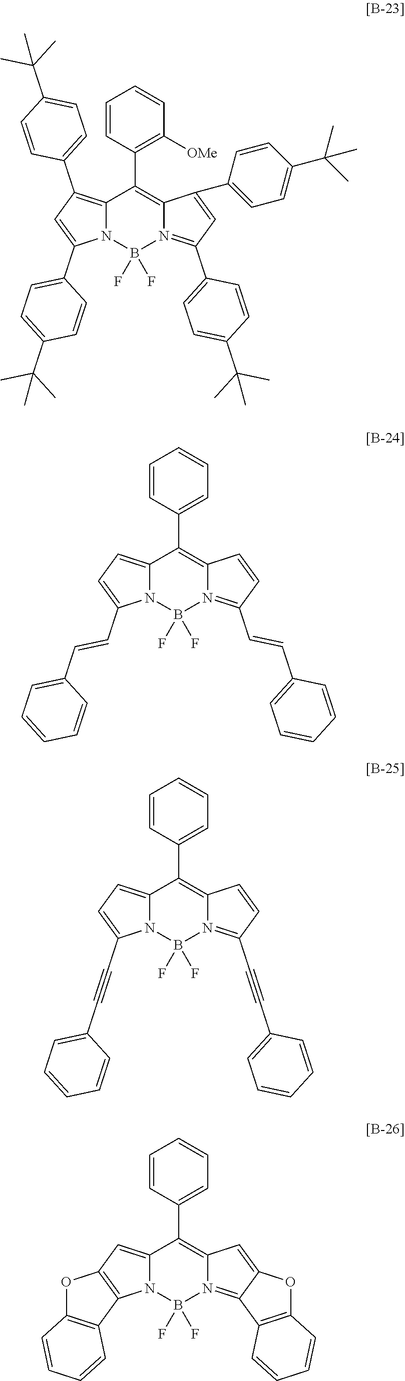

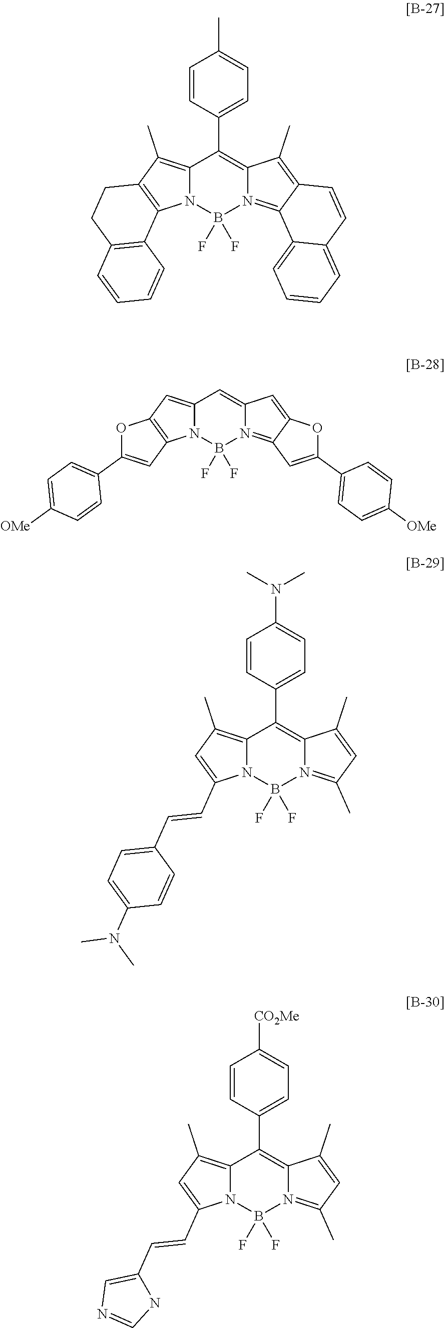

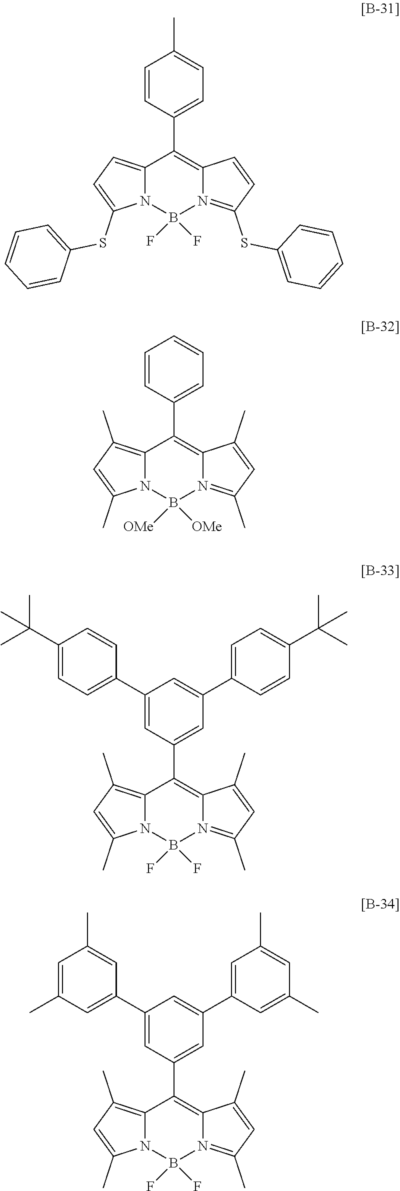

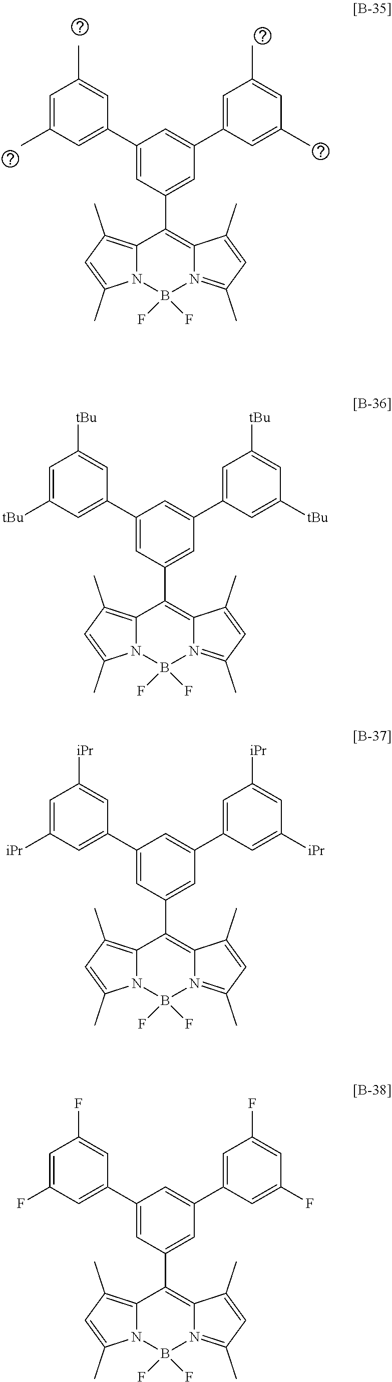

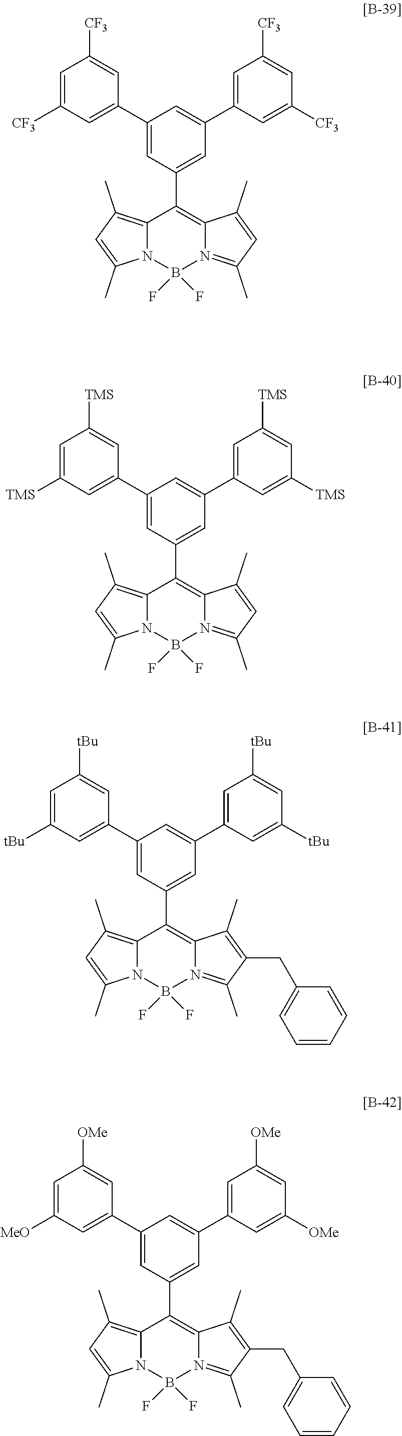

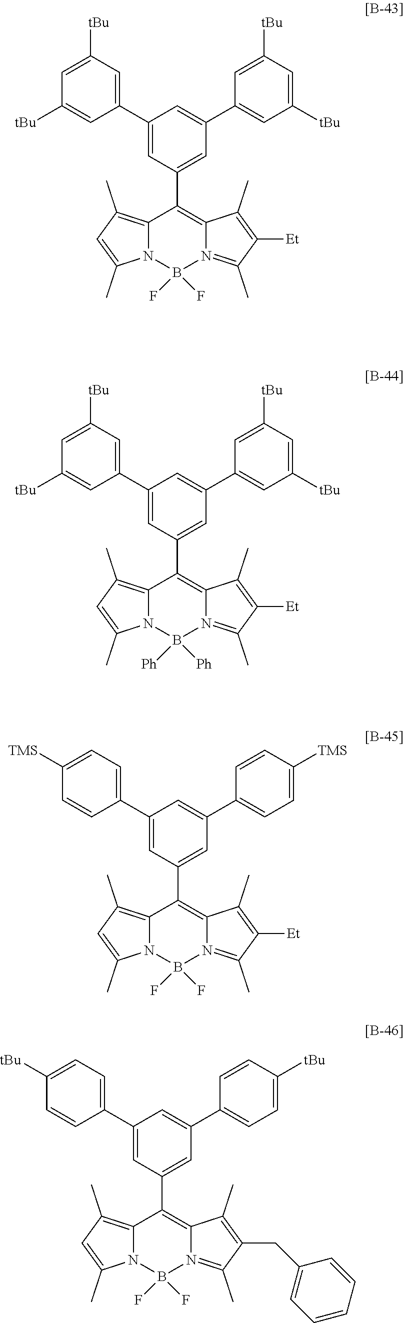

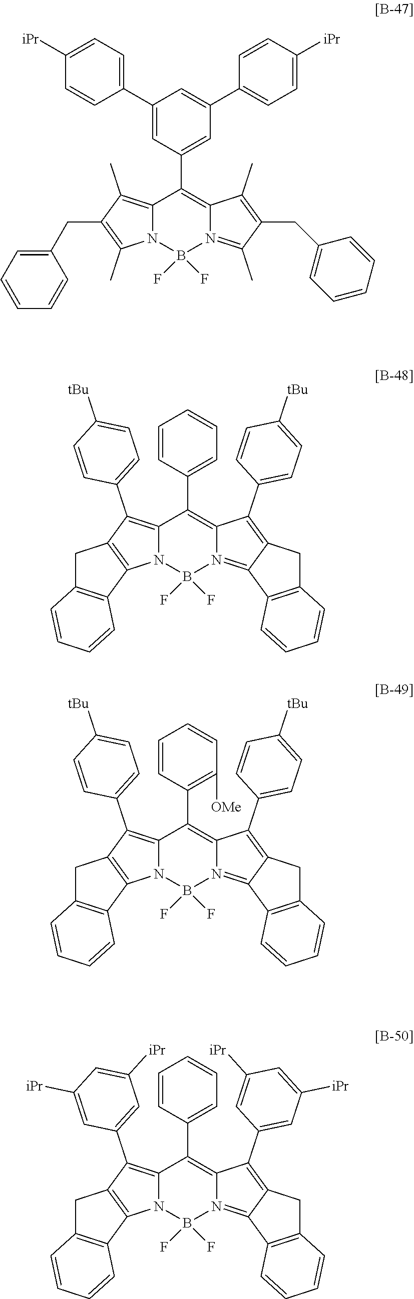

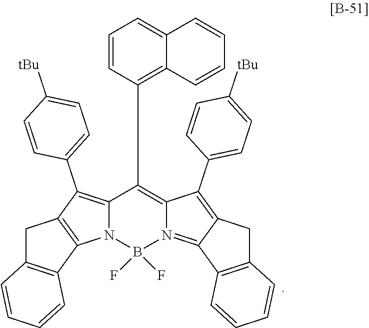

16. A composition for a color conversion film, comprising the light-emitting down conversion organic nano-dots according to claim 1 and a water-soluble polymer resin.

17. The composition of claim 16, comprising 1 to 20 parts by weight of the light-emitting down conversion organic nano-dots based on 100 parts by weight of the water-soluble polymer resin.

18. A color conversion film manufactured using the composition for a color conversion film according to claim 16.

19. A display device comprising the color conversion film according to claim 18.

20. A light-emitting diode device comprising the color conversion film according to claim 18.
